(19) United States
(12) Patent Application Publication
(10) Pub. No.: US 2014/0316136 A1
(43) Pub. Date: Oct. 23, 2014

(54) NOVEL ORGANIC ELECTROLUMINESCENCE COMPOUNDS AND ORGANIC ELECTROLUMINESCENCE DEVICE COMPRISING SAME

(71) Applicant: Rohm and Haas Electronic Materials Korea Ltd., Chungcheongnam-do (KR)

(72) Inventors: Soo-Jin Yang, Gyeonggi-do (KR); Kyoung-Jin Park, Gyeonggi-do (KR); Jong-Seok Ku, Gyeonggi-do (KR); Hyuck-Joo Kwon, Seoul (KR)

(21) Appl. No.: 14/359,300

(22) PCT Filed: Nov. 15, 2012
(86) PCT No.: PCT/KR2012/009654

§ 371 Date: May 19, 2014

(30) Foreign Application Priority Data
Nov. 18, 2011 (KR) 10-2011-0120860

(51) Int. Cl. H01L 51/00

(52) U.S. Cl. CPC H01L 51/0067; H01L 51/0072
USPC 544/333

(57) ABSTRACT

The present invention relates to novel organic electroluminescence compounds and an organic electroluminescence device comprising the same. The organic electroluminescence compound according to the present invention has an advantage of manufacturing an OLED device having long operating lifespan due to its high luminous efficiency compared with conventional materials, and having reduced power consumption induced by improved power efficiency.

### TECHNICAL FIELD

The present invention relates to novel organic electroluminescence compounds and organic electroluminescence device comprising the same.

### BACKGROUND ART

An electroluminescent (EL) device is a self-light-emitting device which has advantages over other types of display devices in that it provides a wider viewing angle, a greater contrast ratio, and a faster response time. An organic EL device was first developed by Eastman Kodak, by using small aromatic diamine molecules, and aluminum complexes as materials for forming a light-emitting layer [Appl. Phys. Lett. 51, 913, 1987].

The most important factor determining luminous efficiency in an organic EL device is the light-emitting material. Until now, fluorescent materials have been widely used as a light-emitting material. However, in view of electroluminescent mechanisms, developing phosphorescent materials is one of the best methods to theoretically enhance luminous efficiency by four (4) times. Iridium(III) complexes have been widely known as phosphorescent materials, including bis(2-(2′-benzothienyl)-pyridinato-N,C-3′)iridium(acetylacetonate) ((acac)Ir(btp)₂), tris(2-phenylpyridine)iridium (Ir(ppy)₃) and bis(4,6-difluorophenylpyridinato-N,C2)picolinate iridium (Firpic) as red, green and blue materials, respectively. Especially, many phosphorescent materials are recently researched in Japan, Europe and U.S.A.

Until now, 4,4′-N,N′-dicarbazol-biphenyl (CBP) was the most widely known host material for phosphorescent substances. Further, an organic EL device using bathocuproine (BCP) and aluminum(III)bis(2-methyl-8-quinolinate)(4-phenylphenolate) (BAIq) for a hole blocking layer is also known, and Pioneer (Japan) et al. developed a high performance organic EL device employing a derivative of BAIq as a host material.

Though these materials provide good light-emitting characteristics, they have the following disadvantages. Due to their low glass transition temperature and poor thermal stability, degradation may occur during a high-temperature deposition process in a vacuum. The power efficiency of an organic EL device is given by [(π/voltage)×current efficiency], and power efficiency is inversely proportional to voltage, and thus in order to lower power consumption, power efficiency should be raised. Although an organic EL device comprising phosphorescent materials provides a much higher current efficiency (cd/A) than one comprising fluorescent materials, an organic EL device using conventional phosphorescent materials such as BAIq or CBP has a higher driving voltage than those using fluorescent materials. Thus, the EL device using conventional phosphorescent materials has no advantage in terms of power efficiency (Im/W). Further, the operating lifespan of the organic EL device is short.

Korean Patent Application Laying-Open No. 2011-0014752 discloses a carbazole-based compound and an organic EL device using the carbazole compound. The compounds have three aryl groups as a substituent on the carbazole structure, and the device showed green emission.

### DISCLOSURE OF INVENTION

### Technical Problem

The objective of the present invention is to provide an organic electroluminescence compound having high luminous efficiency and long operating lifespan compared with the conventional materials in order to overcome said disadvantages; and an organic electroluminescence device having high efficiency and a long lifespan, using said compound as a light-emitting material.

### Solution to Problem

The present inventors found that the objective above is achievable by a compound represented by the following formula 1:

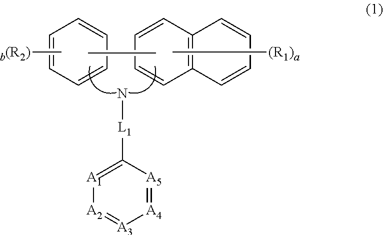

wherein

L₁ represents a single bond, a substituted or unsubstituted (C6-C30)arylene group, or a substituted or unsubstituted 3- to 30-membered heteroarylene group;

Ar₁ to Ar₅ each independently represent CR₁₀, C-L₂-(L₃)ₘ-Ar₁ or N, proviso that at least one of Ar₁ to Ar₅ is C-L₂-(L₃)ₘ-Ar₁;

L₂ and L₃ each independently represent a substituted or unsubstituted (C6-C30)arylene group, or a substituted or unsubstituted 3- to 30-membered heteroarylene group;

R₁, R₂, R₁₀ and Ar₁ each independently represent hydrogen, deuterium, a halogen, a substituted or unsubstituted (C1-C30)alkyl group, a substituted or unsubstituted (C3-C30)cycloalkyl group, a substituted or unsubstituted 5- to 7-membered heterocycloalkyl group, a substituted or unsubstituted (C2-C30)alkenyl group, a substituted or unsubstituted (C2-C30)alkynyl group, a substituted or unsubstituted (C6-C30)aryl group, a substituted or unsubstituted 3- to 30-membered heteroaryl group, —NR₁₁R₁₂, —SiR₁₃R₁₄R₁₅, —SR₁₆, —OR₁₇, a cyano group or a nitro group;

R₁₁ to R₁₇ each independently represent hydrogen, deuterium, a halogen, a substituted or unsubstituted (C1-C30)alkyl group, a substituted or unsubstituted (C6-C30)aryl group, or a substituted or unsubstituted 3- to 30-membered heteroaryl group;

a represents an integer of 1 to 6; where a is an integer of 2 or more, each of R₁ is the same or different;

b represents an integer of 1 to 4; where b is an integer of 2 or more, each of R₂ is the same or different;

m represents an integer of 1 or 2; where m is an integer of 2 or more, each of L₃ is the same or different;

the heteroarylene group, the heterocycloalkyl group and the heteroaryl group contain at least one hetero atom selected from the group consisting of B, N, O, S, P(═O), Si and P;

proviso that R₂ is not 2-carbazole group or 3-carbazole group.

### Advantageous Effects of Invention

The organic electroluminescence compounds according to the present invention have high luminous efficiency and long operating lifespan compared with the conventional material. Therefore, they can produce an organic electroluminescence device having enhanced power consumption efficiency by increasing the power efficiency, as well as superior operating lifespan.

### MODE FOR THE INVENTION

Hereinafter, the present invention will be described in detail. However, the following description is intended to explain the invention, and is not meant in any way to restrict the scope of the invention.

The present invention relates to an organic electroluminescence compound represented by the above formula 1, an organic electroluminescence material comprising the organic electroluminescence compound, and an organic electroluminescence device comprising the material.

Herein, “(C1-C30)alkyl(ene)” is meant to be a linear or branched alkyl(ene) having 1 to 30 carbon atoms, in which the number of carbon atoms is preferably 1 to 20, more preferably 1 to 10, and includes methyl, ethyl, n-propyl, isopropyl, n-butyl, isobutyl, tert-butyl, etc.; “(C2-C30) alkenyl” is meant to be a linear or branched alkenyl having 2 to 30 carbon atoms, in which the number of carbon atoms is preferably 2 to 20, more preferably 2 to 10, and includes vinyl, 1-propenyl, 2-propenyl, 1-butenyl, 2-butenyl, 3-butenyl, 2-methylbut-2-enyl, etc.; “(C2-C30)alkynyl” is a linear or branched alkynyl having 2 to 30 carbon atoms, in which the number of carbon atoms is preferably 2 to 20, more preferably 2 to 10, and includes ethynyl, 1-propynyl, 2-propynyl, 1-butynyl, 2-butynyl, 3-butynyl, 1-methylpent-2-ynyl, etc.; “(C3-C30)cycloalkyl” is a mono- or polycyclic hydrocarbon having 3 to 30 carbon atoms, in which the number of carbon atoms is preferably 3 to 20, more preferably 3 to 7, and includes cyclopropyl, cyclobutyl, cyclopentyl, cyclohexyl, etc.; “5- to 7-membered heterocycloalkyl” is a cycloalkyl having at least one heteroatom selected from the group consisting of B, N, O, S, P(═O), Si and P, preferably O, S and N, and 5 to 7 ring backbone atoms, and includes tetrahydrofurane, pyrrolidine, thiolan, tetrahydropyran, etc.; “(C6-C30)aryl(ene)” is a monocyclic or fused ring derived from an aromatic hydrocarbon having 6 to 30 carbon atoms, in which the number of carbon atoms is preferably 6 to 20, more preferably 6 to 15, and includes phenyl, biphenyl, terphenyl, naphthyl, fluorenyl, phenanthrenyl, anthracenyl, indenyl, triphenylenyl, pyrenyl, tetracenyl, perylenyl, chrysenyl, naphthacenyl, fluoranthenyl, etc.; “3- to 30-membered heteroaryl(ene)” is an aryl group having at least one, preferably 1 to 4 heteroatom selected from the group consisting of B, N, O, S, P(═O), Si and P, and 3 to 30 ring backbone atoms; is a monocyclic ring, or a fused ring condensed with at least one benzene ring; has preferably 5 to 20, more preferably 5 to 15 ring backbone atoms; may be partially saturated; may be one formed by linking at least one heteroaryl or aryl group to a heteroaryl group via a single bond(s); and includes a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, benzoimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, benzodioxolyl, etc. Further, “Halogen” includes F, Cl, Br and I.

Herein, “substituted” in the expression “substituted or unsubstituted” means that a hydrogen atom in a certain functional group is replaced with another atom or group, i.e., a substituent.

Substituents of the substituted alkyl group, the substituted alkenyl group, the substituted alkynyl group, the substituted aryl(ene) group, the substituted heteroaryl(ene) group, the substituted cycloalkyl(ene) group and the substituted heterocycloalkyl group in L₁, L₂, L₃, R₁, R₂, R₁₀, Ar₁ and R₁₁ to R₁₇ groups of formula 1, each independently are at least one selected from the group consisting of deuterium; a halogen; a (C1-C30)alkyl group; a halo(C1-C30)alkyl group; a (C1-C30)alkoxy group; a (C6-C30)aryloxy group; a (C6-C30)aryl group; a 3- to 30-membered heteroaryl group; a 3- to 30-membered heteroaryl group substituted with a (C6-C30)aryl group; a 3- to 30-membered heteroaryl group substituted with a (C1-C30)alkyl and a (C6-C30)aryl; a (C3-C30)cycloalkyl group; a 5- to 7-membered heterocycloalkyl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a (C2-C30)alkenyl group; a (C2-C30)alkynyl group; a cyano group; a (C1-C30)alkylthio group; a (C6-C30)arylthio group; an N-carbazolyl group; a mono- or di(C1-C30)alkylamino group; a mono- or di(C6-C30)arylamino group; a (C1-C30)alkyl(C6-C30)arylamino group; a di(C6-C30)arylboronyl group; a di(C1-C30)alkylboronyl group; a (C1-C30)alkyl(C6-C30)arylboronyl group; a (C6-C30)aryl(C1-C30)alkyl group; a (C1-C30)alkyl(C6-C30)aryl group; a carboxyl group; a nitro group; and a hydroxyl group.

The organic electroluminescence compound according to the present invention is represented by the following formulae 2 to 4:

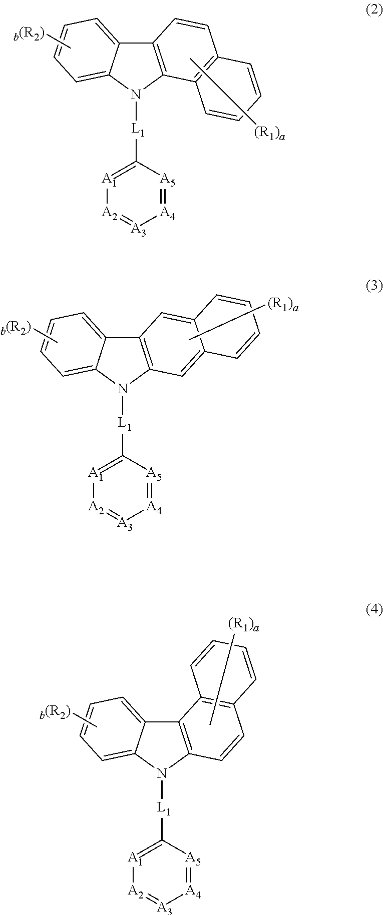

wherein

R₁, R₂, a, b, L₁ and A₁ to A₅ are as defined in formula 1 above.

Specifically, the L₁ is a single bond or a (C6-C30)arylene group; and

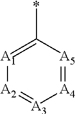

is selected from the following groups:

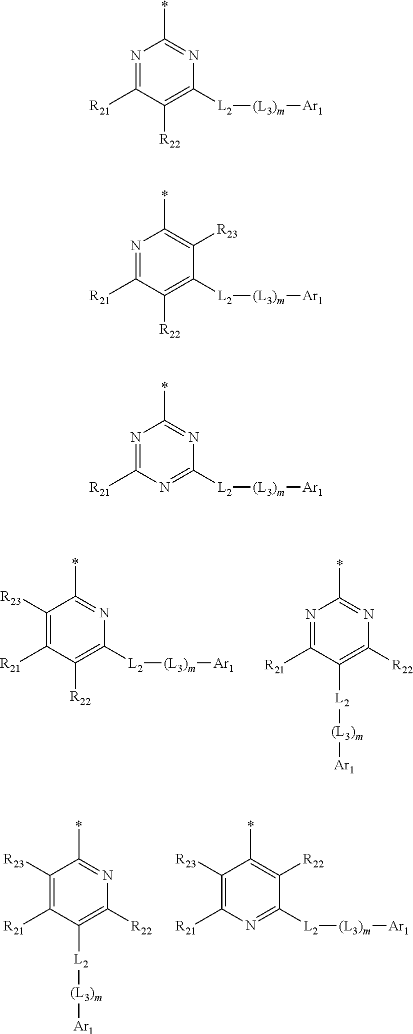

wherein

L₂ and L₃ each independently represent a (C6-C30)arylene group or a 3- to 30-membered heteroarylene group;

R₁ and R₂ each independently represent hydrogen, deuterium, a halogen, a (C1-C30)alkyl group, a (C6-C30)aryl group or a 3- to 30-membered heteroaryl group;

R₁₀ and Ar₁ each independently represent hydrogen, deuterium, a halogen, a (C1-C30)alkyl group, a (C3-C30)cycloalkyl group, a (C6-C30)aryl group, a 3- to 30-membered heteroaryl group or —SiR₁₃R₁₄R₁₅;

R₁₃ to R₁₅ each independently represent a (C1-C30)alkyl group or a (C6-C30)aryl group;

a represents an integer of 0 to 6;

b represents an integer of 0 to 4;

m represents an integer of 1 or 2; and

the arylene group in L₁, the arylene and heteroarylene groups in L₂ and L₃, the alkyl, aryl and heteroaryl groups in R₁ and R₂, the alkyl, cycloalkyl, aryl and heteroaryl groups in R₁₀ and Ar₁, and the alkyl and aryl groups in R₁₃ to R₁₅ each independently can be further substituted with at least one selected from the group consisting of deuterium, a halogen, a (C1-C30)alkyl group, a halo(C1-C30)alkyl group, a (C1-C30)alkoxy group, a (C6-C30)aryloxy group, a (C6-C30)aryl group, a 3- to 30-membered heteroaryl group; a 3- to 30-membered heteroaryl group substituted with a (C6-C30)aryl group; a 3- to 30-membered heteroaryl group substituted with a (C6-C30)aryl group and a (C1-C30)alkyl group; a (C3-C30)cycloalkyl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a cyano group; a (C1-C30)alkylthio group; a (C6-C30)arylthio group; a (C6-C30)aryl(C1-C30)alkyl group; and a (C1-C30)alkyl(C6-C30)aryl group.

More specifically, L₂ represents phenylene, pyridinylene, fluorenylene, carbazolylene, dibenzofuranylene or dibenzothiophenylene; L₃ represents phenylene, biphenylene, terphenylene, naphthylene, pyridinylene, pyrimidinylene, fluorenylene, dibenzofuranylene, dibenzothiophenylene, carbazolylene, 5H-pyrido[3,2-b]indolylene or 5H-indeno[1,2-b]pyridinylene; Ar₁ represents hydrogen, a halogen, a (C1-C30)alkyl group, a (C3-C30)cycloalkyl group, a (C6-C30)aryl group, a 3- to 30-membered heteroaryl group or —SiR₁₃R₁₄R₁₅; R₁₀ represents hydrogen or a (C6-C30)aryl group; R₁ and R₂ each independently represent hydrogen, a halogen, a (C1-C30)alkyl group, a (C6-C30)aryl group or a 3- to 30-membered heteroaryl group; the phenylene, pyridinylene, fluorenylene, carbazolylene, dibenzofuranylene and dibenzothiophenylene in L₂, the phenylene, biphenylene, terphenylene, naphthylene, pyridinylene, pyrimidinylene, fluorenylene, dibenzofuranylene, dibenzothiophenylene, carbazolylene, 5H-pyrido[3,2-b]indolylene and 5H-indeno[1,2-b]pyridinylene in L₃, the alkyl, cycloalkyl, aryl and heteroaryl in Ar₁, the aryl in R₁₀, and the alkyl, aryl and heteroaryl in R₁ and R₂ each independently can be further substituted with at least one selected from the group consisting of deuterium, a halogen, a (C1-C30)alkyl group, a halo(C1-C30)alkyl group, a (C1-C30)alkoxy group, a (C6-C30)aryloxy group, a (C6-C30)aryl group, a 3- to 30-membered heteroaryl group; a 3- to 30-membered heteroaryl group substituted with a (C6-C30)aryl group; a (C1-C30)alkylthio group; a (C6-C30)arylthio group; a (C6-C30)aryl(C1-C30)alkyl group; and a (C1-C30)alkyl(C6-C30)aryl group.

Further, L₁ represents a single bond, phenylene, naphthylene, biphenylene, terphenylene, anthrylene, indenylene, 9,9-dimethylfluorenylene, phenanthrylene, triphenylenylene, pyrenylene, perylenylene, crysenylene, naphthacenylene, fluoranthenylene, phenylene-naphthylene, furylene, thiophenylene, pyrrolylene, imidazolylene, pyrazolylene, thiazolylene, thiadiazolylene, isothiazolylene, isoxazolylene, oxazolylene, oxadiazolylene, triazinylene, tetrazinylene, triazolylene, furazanylene, pyridylene, pyrazinylene, pyrimidinylene, pyridazinylene, benzofuranylene, benzothiophenylene, isobenzofuranylene, benzoimidazolylene, benzothiazolylene, benzoisothiazolylene, benzoisoxazolylene, benzoxazolylene, isoindolylene, indolylene, indazolylene, benzothiadiazolylene, quinolylene, isoquinolylene, cinolynylene, quinazolinylene, quinoxalynylene, phenanthrydinylene, benzodioxolylene, dibenzofuranylene and dibenzocyophenylene.

Further, R₁ and R₂ each independently represent hydrogen, a halogen, a (C1-C30)alkyl, or a group selected from the following:

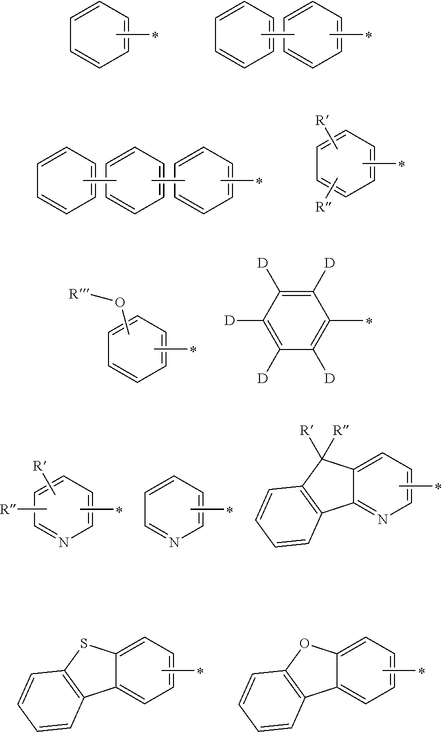

wherein R′, R″ and R′″ each independently represent a (C1-C30)alkyl group or a (C6-C30)aryl group.

Further, Ar₁ represents hydrogen, a halogen, a (C1-C30)alkyl group, or a group selected from the following:

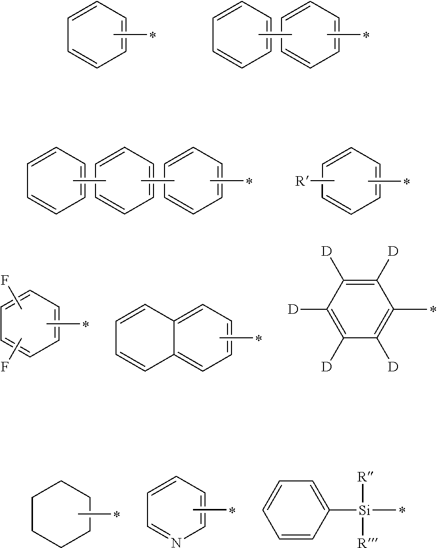

wherein R′ represents a halogen or a (C1-C30)alkyl group; and R″ and R′″ each independently represent a (C1-C30)alkyl group or a (C6-C30)aryl group.

The organic electroluminescence compounds of the present invention include the following compounds:

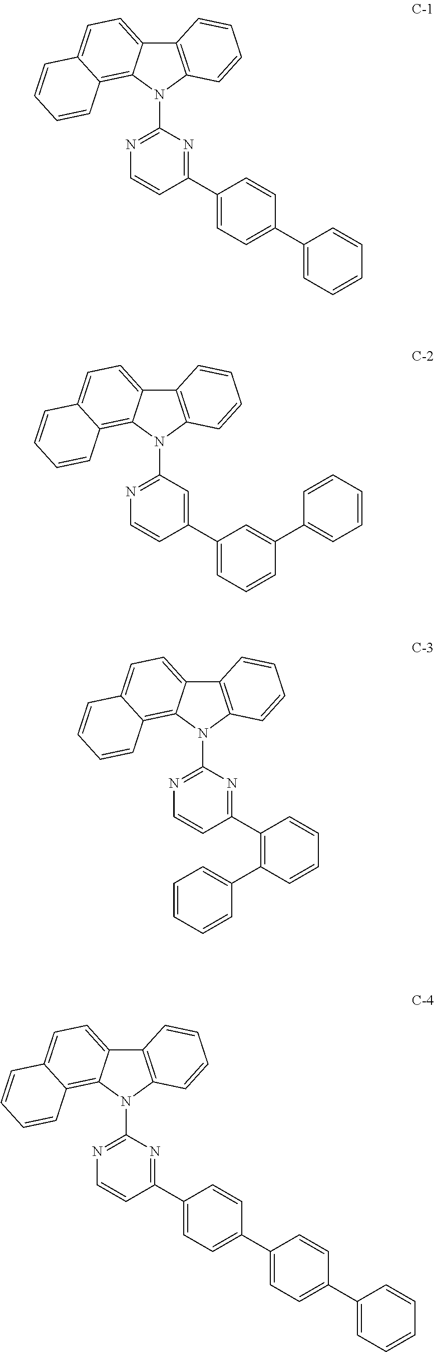 [SMILES: c1ccc(-c2ccc(-c3ccnc(-n4c5ccccc5c5ccc6ccccc6c54)n3)cc2)cc1 ; c1ccc(-c2cccc(-c3ccnc(-n4c5ccccc5c5ccc6ccccc6c54)c3)c2)cc1 ; c1ccc(-c2ccccc2-c2ccnc(-n3c4ccccc4c4ccc5ccccc5c43)n2)cc1 ; c1ccc(-c2ccc(-c3ccc(-c4ccnc(-n5c6ccccc6c6ccc7ccccc7c65)n4)cc3)cc2)cc1]

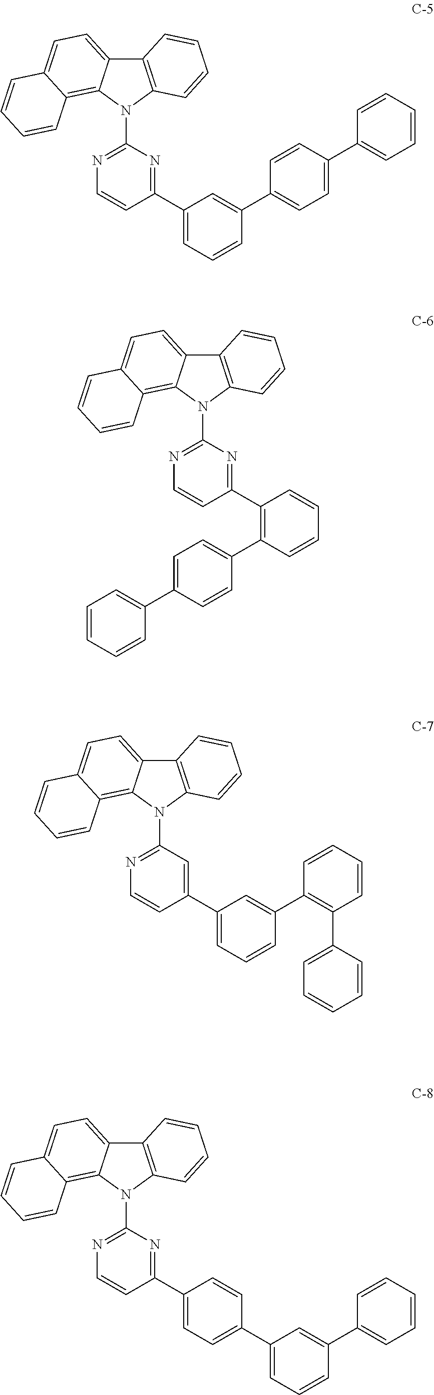 [SMILES: c1ccc(-c2ccc(-c3cccc(-c4ccnc(-n5c6ccccc6c6ccc7ccccc7c65)n4)c3)cc2)cc1 ; c1ccc(-c2ccc(-c3ccccc3-c3ccnc(-n4c5ccccc5c5ccc6ccccc6c54)n3)cc2)cc1 ; c1ccc(-c2ccccc2-c2cccc(-c3ccnc(-n4c5ccccc5c5ccc6ccccc6c54)c3)c2)cc1 ; c1ccc(-c2cccc(-c3ccc(-c4ccnc(-n5c6ccccc6c6ccc7ccccc7c65)n4)cc3)c2)cc1]

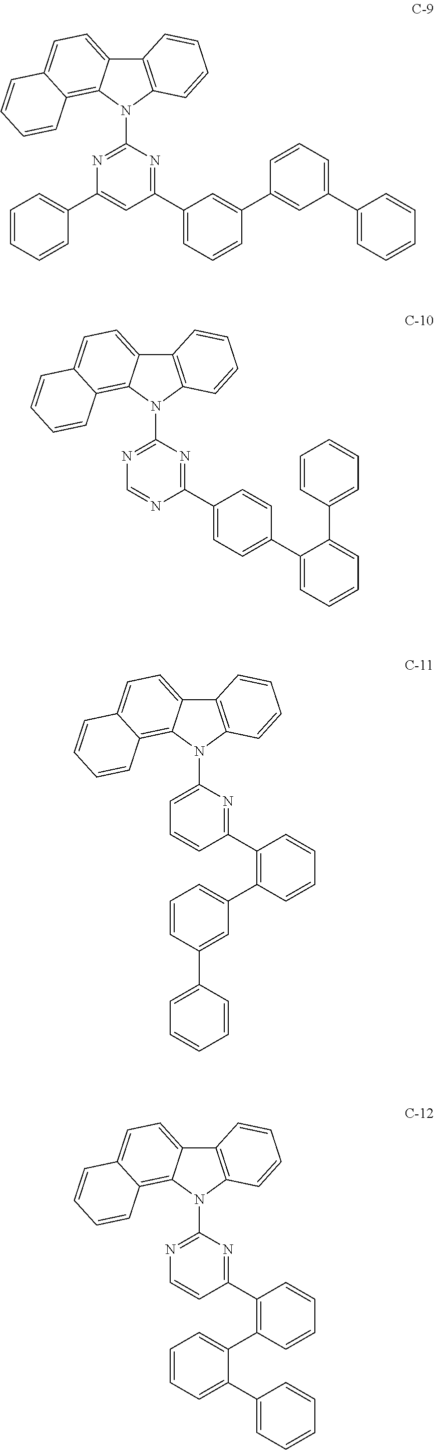 [SMILES: c1ccc(-c2cccc(-c3cccc(-c4cc(-c5ccccc5)nc(-n5c6ccccc6c6ccc7ccccc7c65)n4)c3)c2)cc1 ; c1ccc(-c2ccccc2-c2ccc(-c3ncnc(-n4c5ccccc5c5ccc6ccccc6c54)n3)cc2)cc1 ; c1ccc(-c2cccc(-c3ccccc3-c3cccc(-n4c5ccccc5c5ccc6ccccc6c54)n3)c2)cc1 ; c1ccc(-c2ccccc2-c2ccccc2-c2ccnc(-n3c4ccccc4c4ccc5ccccc5c43)n2)cc1]

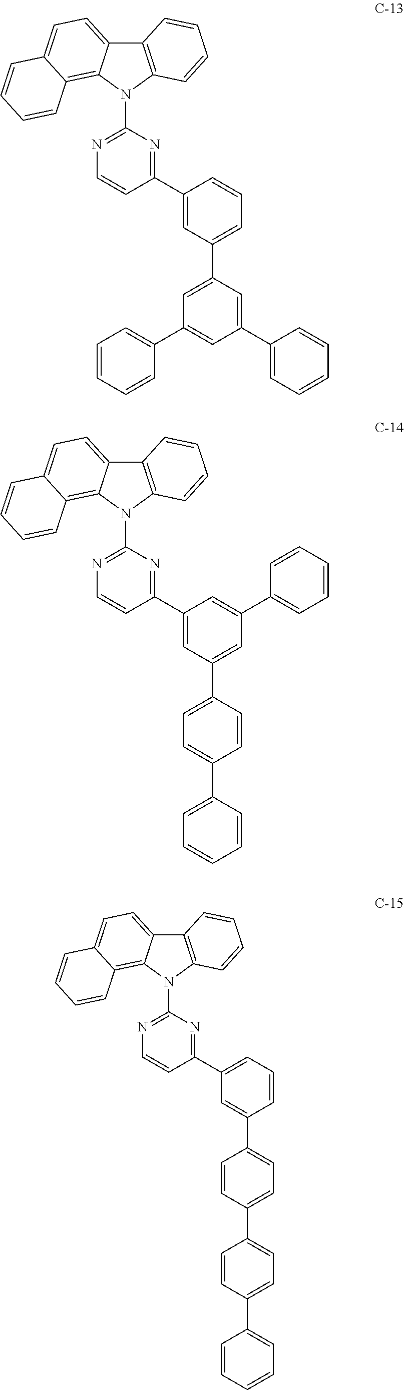 [SMILES: c1ccc(-c2cc(-c3ccccc3)cc(-c3cccc(-c4ccnc(-n5c6ccccc6c6ccc7ccccc7c65)n4)c3)c2)cc1 ; c1ccc(-c2ccc(-c3cc(-c4ccccc4)cc(-c4ccnc(-n5c6ccccc6c6ccc7ccccc7c65)n4)c3)cc2)cc1 ; c1ccc(-c2ccc(-c3ccc(-c4cccc(-c5ccnc(-n6c7ccccc7c7ccc8ccccc8c76)n5)c4)cc3)cc2)cc1]

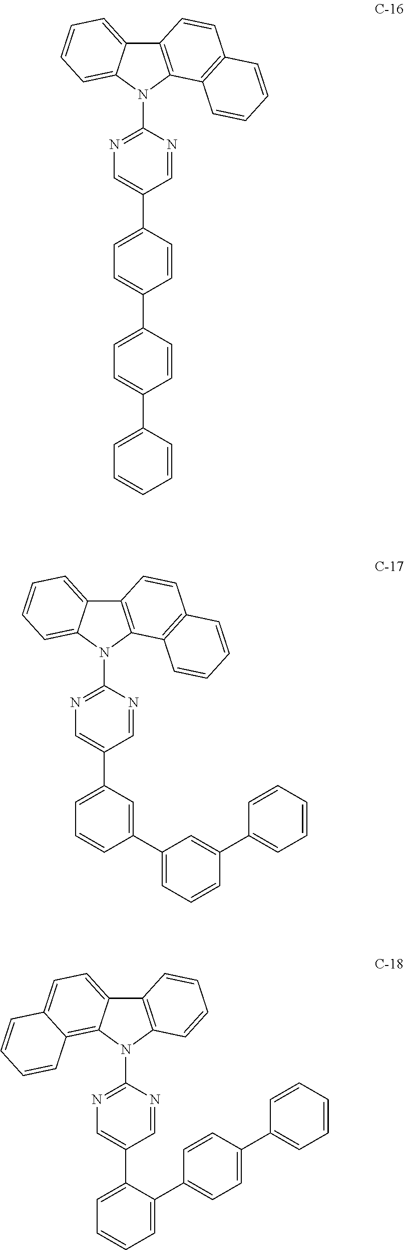 [SMILES: c1ccc(-c2ccc(-c3ccc(-c4cnc(-n5c6ccccc6c6ccc7ccccc7c65)nc4)cc3)cc2)cc1 ; c1ccc(-c2cccc(-c3cccc(-c4cnc(-n5c6ccccc6c6ccc7ccccc7c65)nc4)c3)c2)cc1 ; c1ccc(-c2ccc(-c3ccccc3-c3cnc(-n4c5ccccc5c5ccc6ccccc6c54)nc3)cc2)cc1]

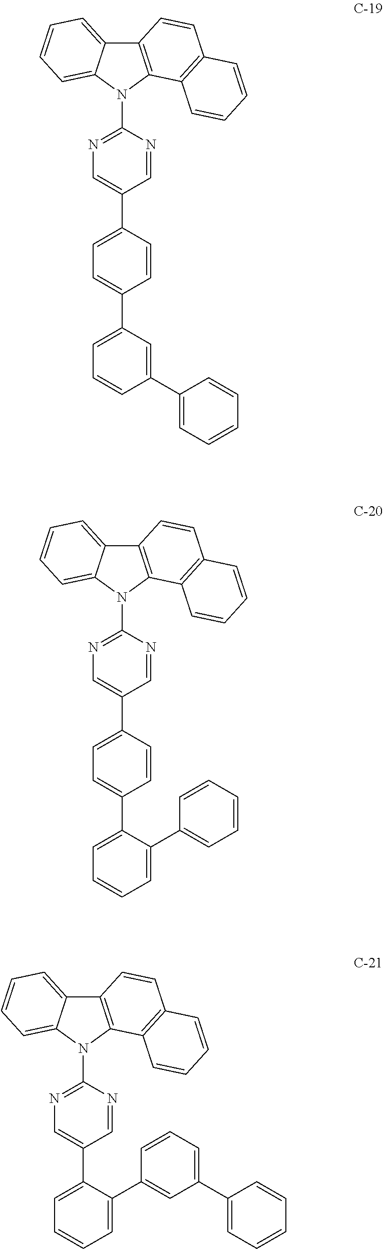 [SMILES: c1ccc(-c2cccc(-c3ccc(-c4cnc(-n5c6ccccc6c6ccc7ccccc7c65)nc4)cc3)c2)cc1 ; c1ccc(-c2ccccc2-c2ccc(-c3cnc(-n4c5ccccc5c5ccc6ccccc6c54)nc3)cc2)cc1 ; c1ccc(-c2cccc(-c3ccccc3-c3cnc(-n4c5ccccc5c5ccc6ccccc6c54)nc3)c2)cc1]

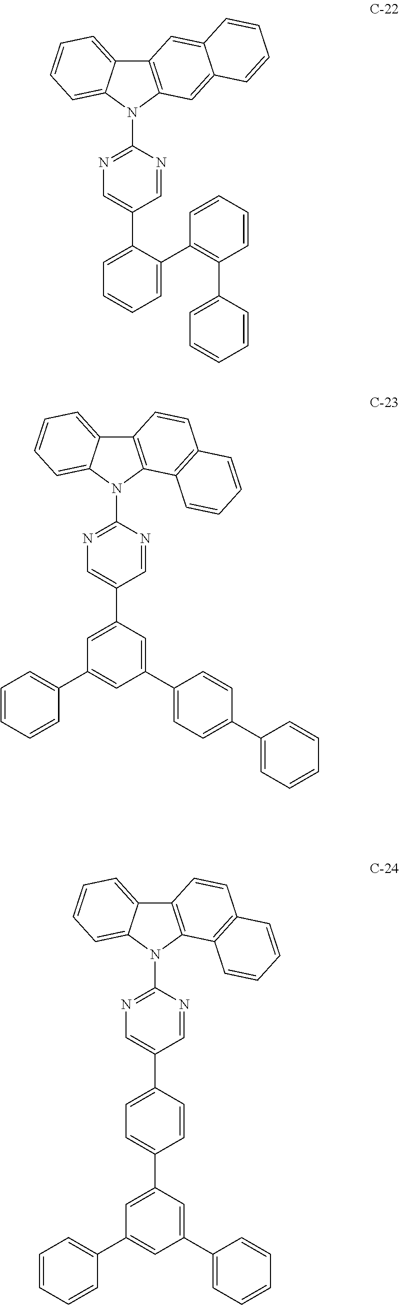 [SMILES: c1ccc(-c2ccccc2-c2ccccc2-c2cnc(-n3c4ccccc4c4cc5ccccc5cc43)nc2)cc1 ; c1ccc(-c2ccc(-c3cc(-c4ccccc4)cc(-c4cnc(-n5c6ccccc6c6ccc7ccccc7c65)nc4)c3)cc2)cc1 ; c1ccc(-c2cc(-c3ccccc3)cc(-c3ccc(-c4cnc(-n5c6ccccc6c6ccc7ccccc7c65)nc4)cc3)c2)cc1]

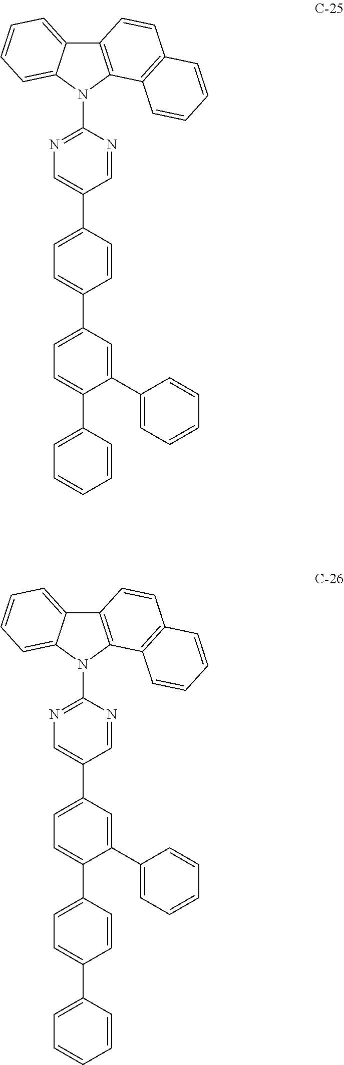 [SMILES: c1ccc(-c2ccc(-c3ccc(-c4cnc(-n5c6ccccc6c6ccc7ccccc7c65)nc4)cc3)cc2-c2ccccc2)cc1 ; c1ccc(-c2ccc(-c3ccc(-c4cnc(-n5c6ccccc6c6ccc7ccccc7c65)nc4)cc3-c3ccccc3)cc2)cc1]

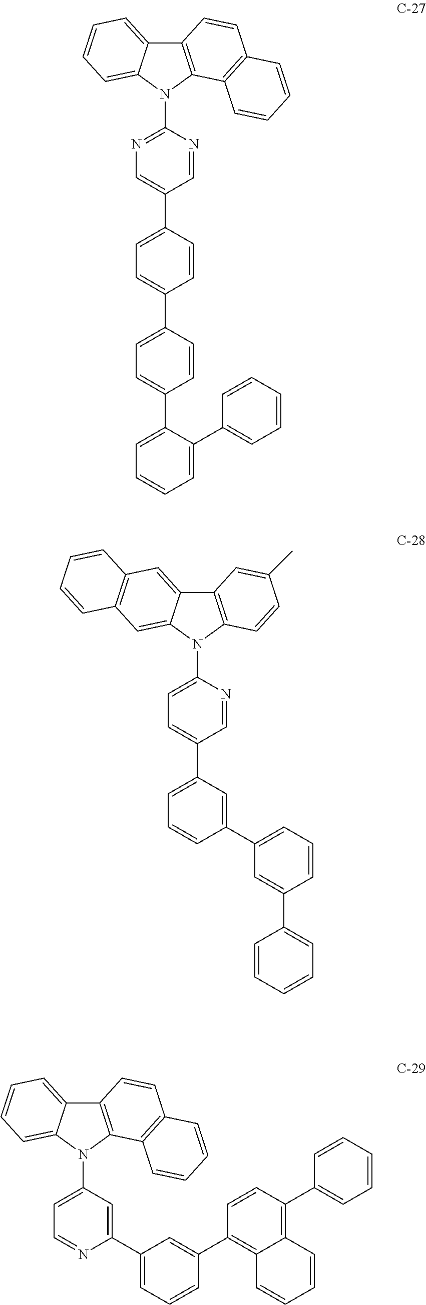 [SMILES: c1ccc(-c2ccccc2-c2ccc(-c3ccc(-c4cnc(-n5c6ccccc6c6ccc7ccccc7c65)nc4)cc3)cc2)cc1 ; Cc1ccc2c(c1)c1cc3ccccc3cc1n2-c1ccc(-c2cccc(-c3cccc(-c4ccccc4)c3)c2)cn1 ; c1ccc(-c2ccc(-c3cccc(-c4cc(-n5c6ccccc6c6ccc7ccccc7c65)ccn4)c3)c3ccccc23)cc1]

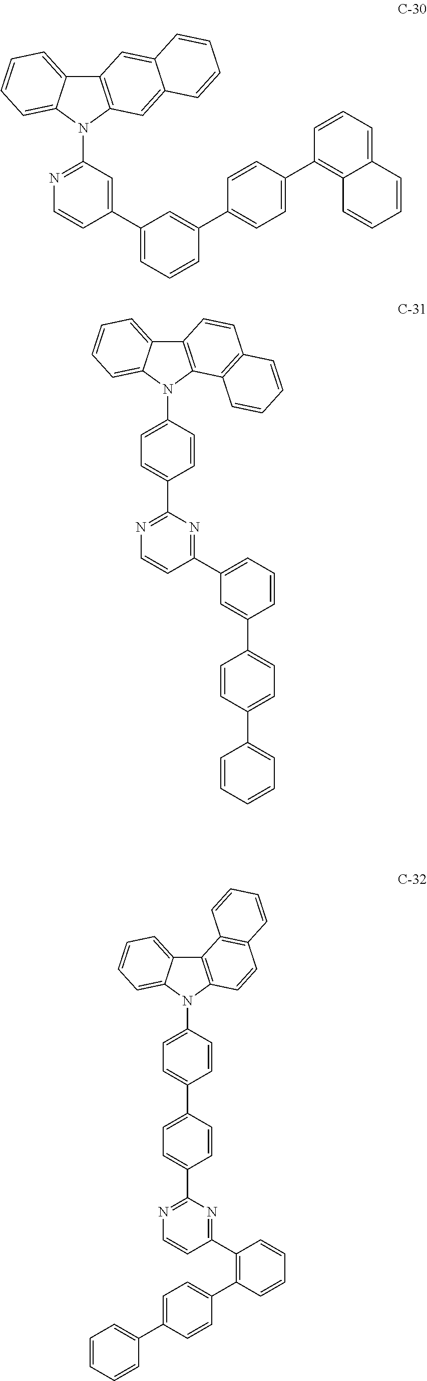 [SMILES: c1cc(-c2ccc(-c3cccc4ccccc34)cc2)cc(-c2ccnc(-n3c4ccccc4c4cc5ccccc5cc43)c2)c1 ; c1ccc(-c2ccc(-c3cccc(-c4ccnc(-c5ccc(-n6c7ccccc7c7ccc8ccccc8c76)cc5)n4)c3)cc2)cc1 ; c1ccc(-c2ccc(-c3ccccc3-c3ccnc(-c4ccc(-c5ccc(-n6c7ccccc7c7c8ccccc8ccc76)cc5)cc4)n3)cc2)cc1]

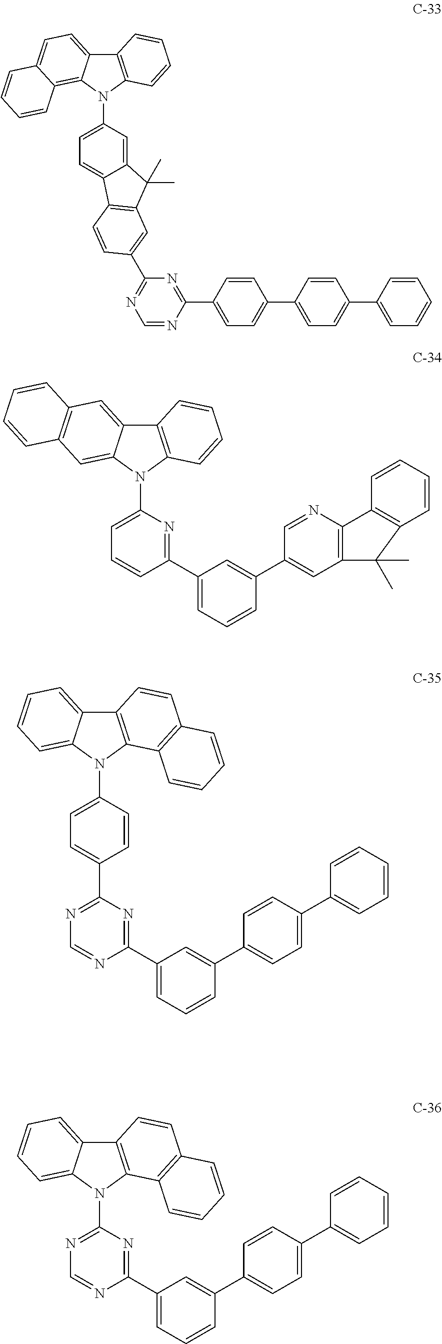 [SMILES: CC1(C)c2cc(-c3ncnc(-c4ccc(-c5ccc(-c6ccccc6)cc5)cc4)n3)ccc2-c2ccc(-n3c4ccccc4c4ccc5ccccc5c43)cc21 ; CC1(C)c2ccccc2-c2ncc(-c3cccc(-c4cccc(-n5c6ccccc6c6cc7ccccc7cc65)n4)c3)cc21 ; c1ccc(-c2ccc(-c3cccc(-c4ncnc(-c5ccc(-n6c7ccccc7c7ccc8ccccc8c76)cc5)n4)c3)cc2)cc1 ; c1ccc(-c2ccc(-c3cccc(-c4ncnc(-n5c6ccccc6c6ccc7ccccc7c65)n4)c3)cc2)cc1]

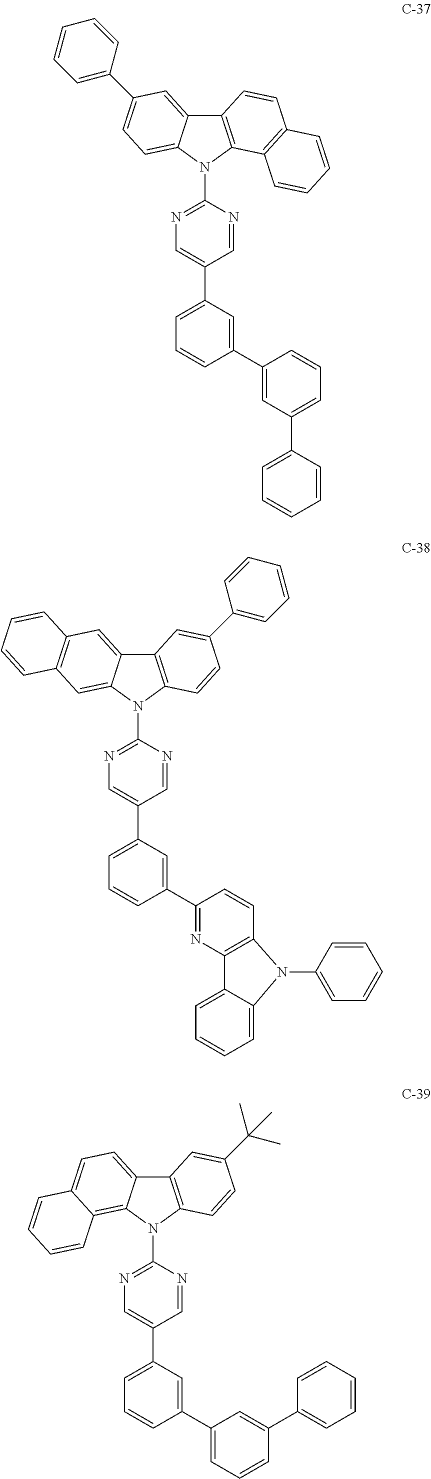 [SMILES: c1ccc(-c2cccc(-c3cccc(-c4cnc(-n5c6ccc(-c7ccccc7)cc6c6ccc7ccccc7c65)nc4)c3)c2)cc1 ; c1ccc(-c2ccc3c(c2)c2cc4ccccc4cc2n3-c2ncc(-c3cccc(-c4ccc5c(n4)c4ccccc4n5-c4ccccc4)c3)cn2)cc1 ; CC(C)(C)c1ccc2c(c1)c1ccc3ccccc3c1n2-c1ncc(-c2cccc(-c3cccc(-c4ccccc4)c3)c2)cn1]

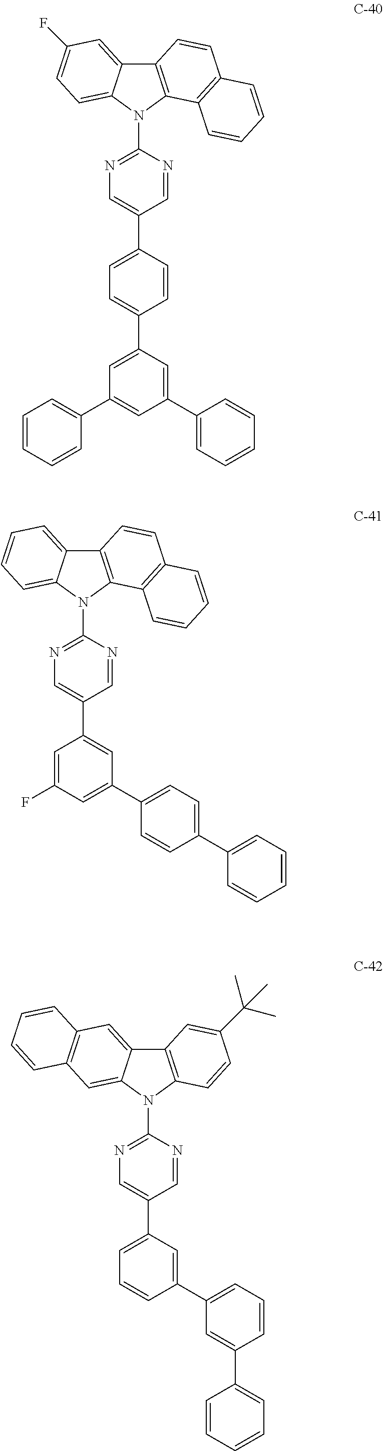 [SMILES: Fc1ccc2c(c1)c1ccc3ccccc3c1n2-c1ncc(-c2ccc(-c3cc(-c4ccccc4)cc(-c4ccccc4)c3)cc2)cn1 ; Fc1cc(-c2ccc(-c3ccccc3)cc2)cc(-c2cnc(-n3c4ccccc4c4ccc5ccccc5c43)nc2)c1 ; CC(C)(C)c1ccc2c(c1)c1cc3ccccc3cc1n2-c1ncc(-c2cccc(-c3cccc(-c4ccccc4)c3)c2)cn1]

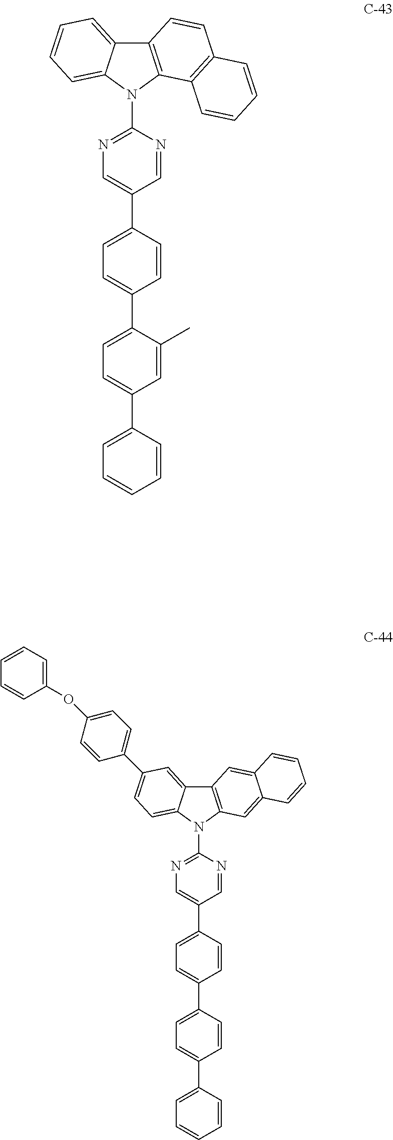 [SMILES: Cc1cc(-c2ccccc2)ccc1-c1ccc(-c2cnc(-n3c4ccccc4c4ccc5ccccc5c43)nc2)cc1 ; c1ccc(Oc2ccc(-c3ccc4c(c3)c3cc5ccccc5cc3n4-c3ncc(-c4ccc(-c5ccc(-c6ccccc6)cc5)cc4)cn3)cc2)cc1]

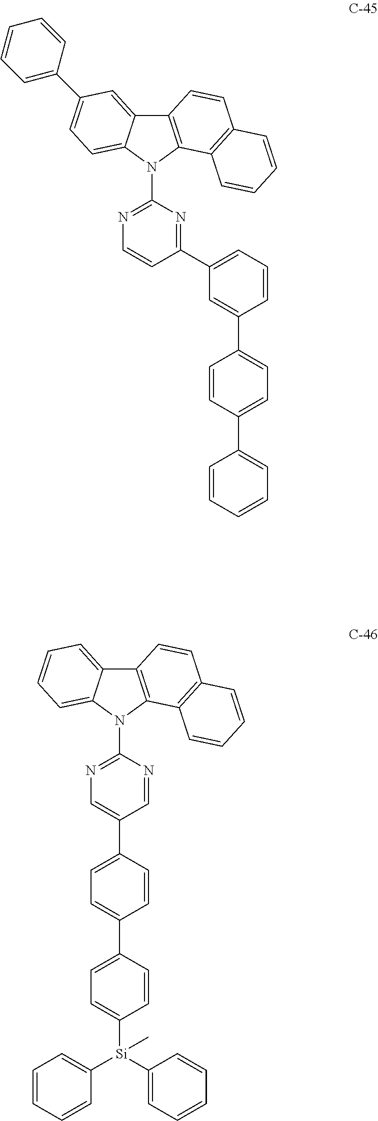 [SMILES: c1ccc(-c2ccc(-c3cccc(-c4ccnc(-n5c6ccc(-c7ccccc7)cc6c6ccc7ccccc7c65)n4)c3)cc2)cc1 ; C[Si](c1ccccc1)(c1ccccc1)c1ccc(-c2ccc(-c3cnc(-n4c5ccccc5c5ccc6ccccc6c54)nc3)cc2)cc1]

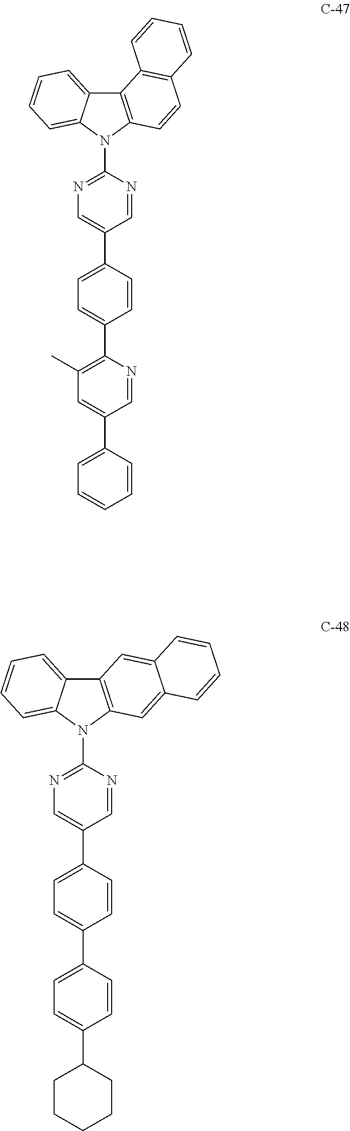 [SMILES: Cc1cc(-c2ccccc2)cnc1-c1ccc(-c2cnc(-n3c4ccccc4c4c5ccccc5ccc43)nc2)cc1 ; c1ccc2cc3c(cc2c1)c1ccccc1n3-c1ncc(-c2ccc(-c3ccc(C4CCCCC4)cc3)cc2)cn1]

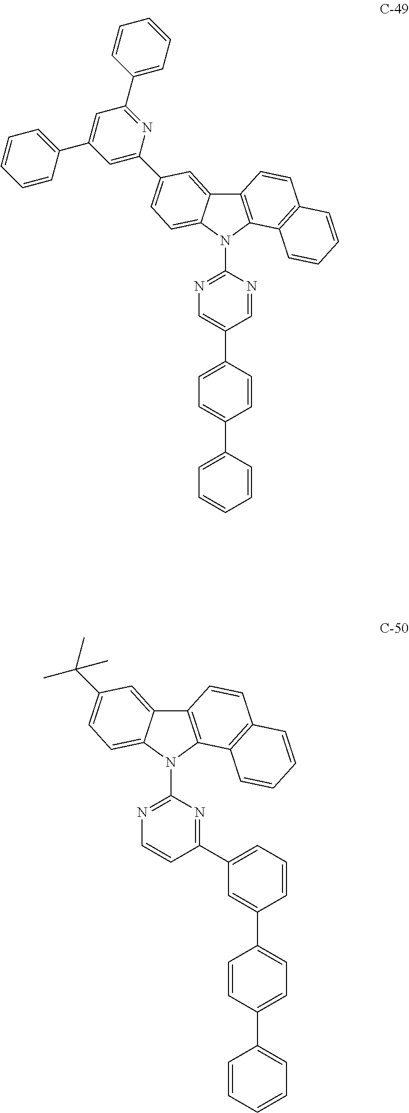 [SMILES: c1ccc(-c2ccc(-c3cnc(-n4c5ccc(-c6cc(-c7ccccc7)cc(-c7ccccc7)n6)cc5c5ccc6ccccc6c54)nc3)cc2)cc1 ; CC(C)(C)c1ccc2c(c1)c1ccc3ccccc3c1n2-c1nccc(-c2cccc(-c3ccc(-c4ccccc4)cc3)c2)n1]

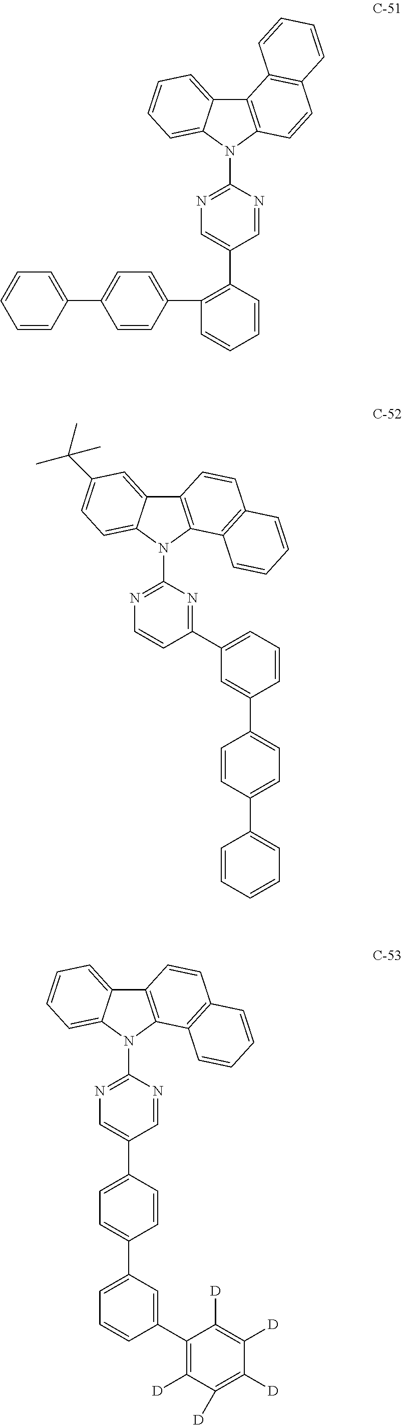 [SMILES: c1ccc(-c2ccc(-c3ccccc3-c3cnc(-n4c5ccccc5c5c6ccccc6ccc54)nc3)cc2)cc1 ; CC(C)(C)c1ccc2c(c1)c1ccc3ccccc3c1n2-c1nccc(-c2cccc(-c3ccc(-c4ccccc4)cc3)c2)n1 ; [2H]c1c([2H])c([2H])c(-c2cccc(-c3ccc(-c4cnc(-n5c6ccccc6c6ccc7ccccc7c65)nc4)cc3)c2)c([2H])c1[2H]]

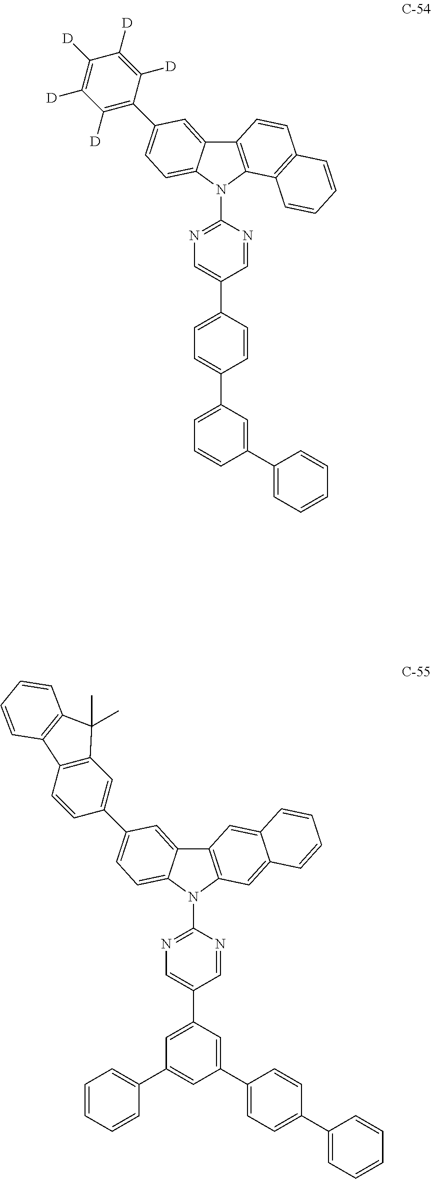 [SMILES: [2H]c1c([2H])c([2H])c(-c2ccc3c(c2)c2ccc4ccccc4c2n3-c2ncc(-c3ccc(-c4cccc(-c5ccccc5)c4)cc3)cn2)c([2H])c1[2H] ; CC1(C)c2ccccc2-c2ccc(-c3ccc4c(c3)c3cc5ccccc5cc3n4-c3ncc(-c4cc(-c5ccccc5)cc(-c5ccc(-c6ccccc6)cc5)c4)cn3)cc21]

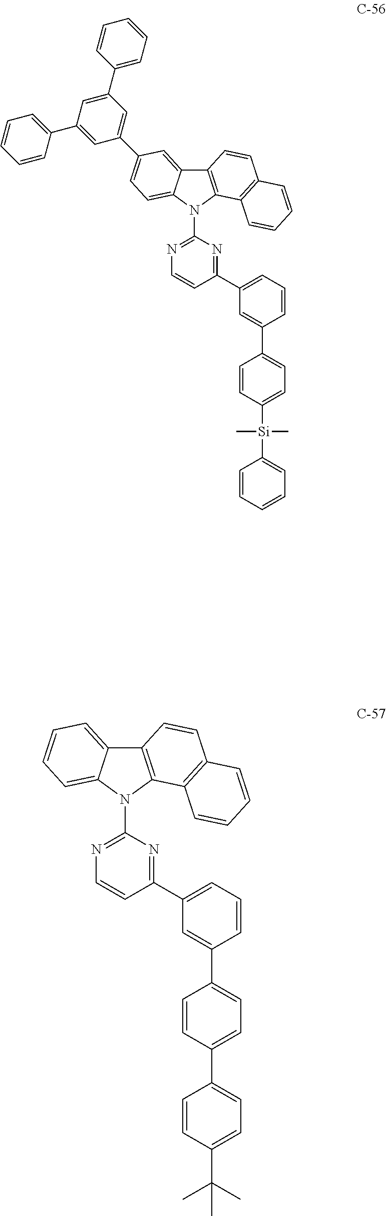 [SMILES: C[Si](C)(c1ccccc1)c1ccc(-c2cccc(-c3ccnc(-n4c5ccc(-c6cc(-c7ccccc7)cc(-c7ccccc7)c6)cc5c5ccc6ccccc6c54)n3)c2)cc1 ; CC(C)(C)c1ccc(-c2ccc(-c3cccc(-c4ccnc(-n5c6ccccc6c6ccc7ccccc7c65)n4)c3)cc2)cc1]

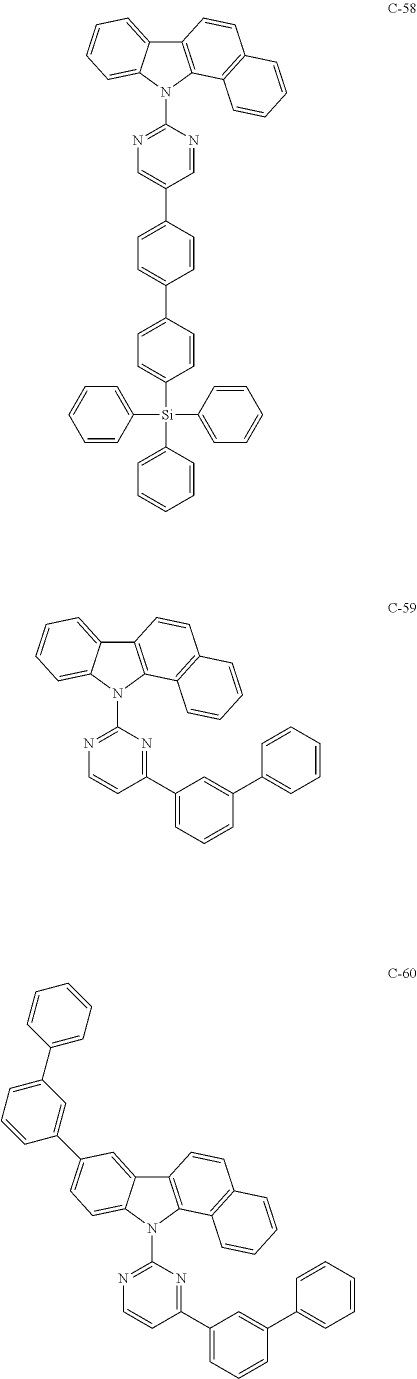 [SMILES: c1ccc([Si](c2ccccc2)(c2ccccc2)c2ccc(-c3ccc(-c4cnc(-n5c6ccccc6c6ccc7ccccc7c65)nc4)cc3)cc2)cc1 ; c1ccc(-c2cccc(-c3ccnc(-n4c5ccccc5c5ccc6ccccc6c54)n3)c2)cc1 ; c1ccc(-c2cccc(-c3ccc4c(c3)c3ccc5ccccc5c3n4-c3nccc(-c4cccc(-c5ccccc5)c4)n3)c2)cc1]

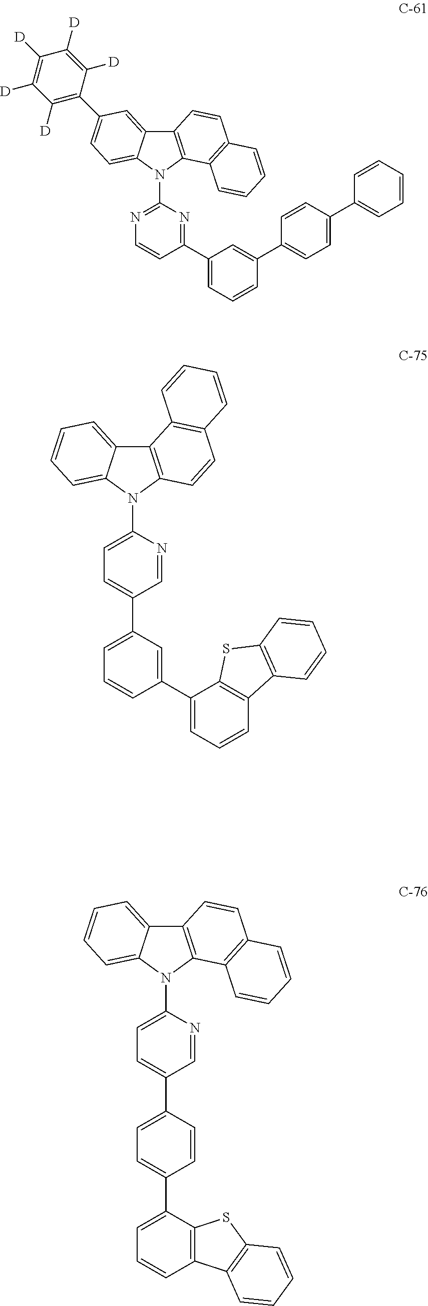 [SMILES: [2H]c1c([2H])c([2H])c(-c2ccc3c(c2)c2ccc4ccccc4c2n3-c2nccc(-c3cccc(-c4ccc(-c5ccccc5)cc4)c3)n2)c([2H])c1[2H] ; c1cc(-c2ccc(-n3c4ccccc4c4c5ccccc5ccc43)nc2)cc(-c2cccc3c2sc2ccccc23)c1 ; c1ccc2c(c1)ccc1c3ccccc3n(-c3ccc(-c4ccc(-c5cccc6c5sc5ccccc56)cc4)cn3)c21]

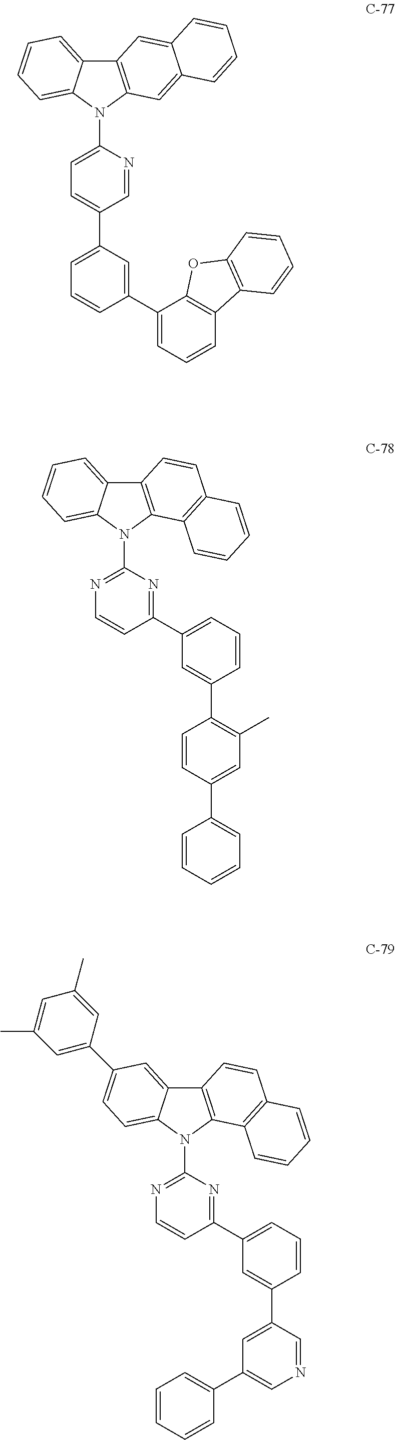

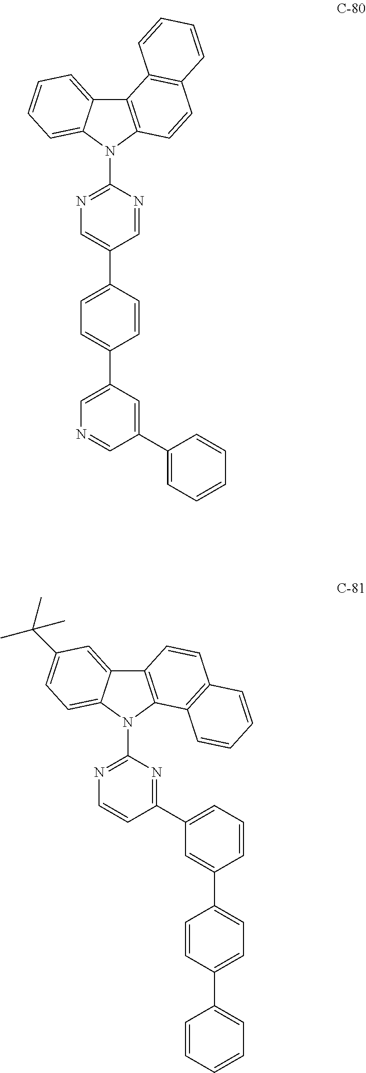 [SMILES: c1ccc(-c2cncc(-c3ccc(-c4cnc(-n5c6ccccc6c6c7ccccc7ccc65)nc4)cc3)c2)cc1 ; CC(C)(C)c1ccc2c(c1)c1ccc3ccccc3c1n2-c1nccc(-c2cccc(-c3ccc(-c4ccccc4)cc3)c2)n1]

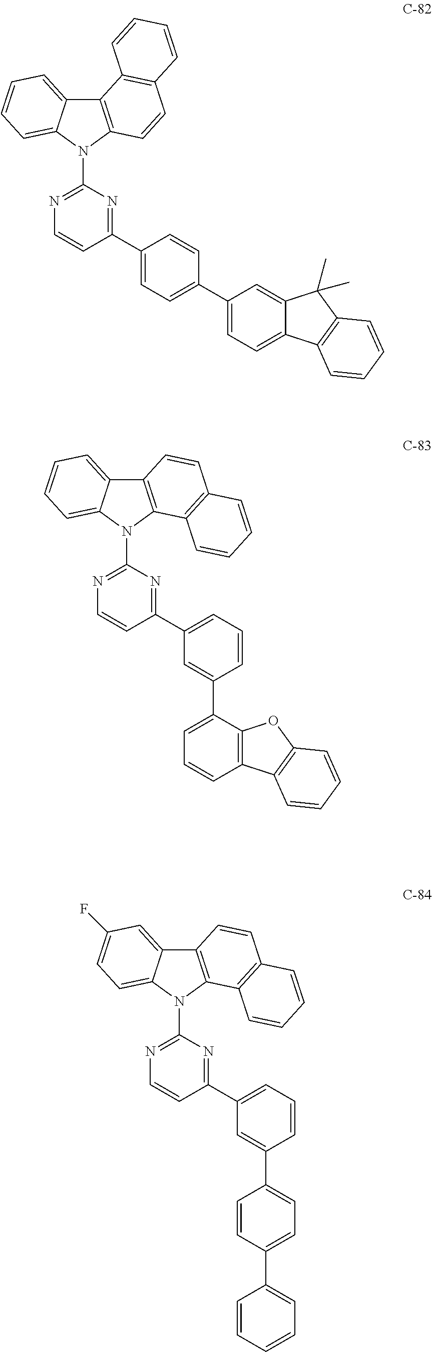 [SMILES: CC1(C)c2ccccc2-c2ccc(-c3ccc(-c4ccnc(-n5c6ccccc6c6c7ccccc7ccc65)n4)cc3)cc21 ; c1cc(-c2ccnc(-n3c4ccccc4c4ccc5ccccc5c43)n2)cc(-c2cccc3c2oc2ccccc23)c1 ; Fc1ccc2c(c1)c1ccc3ccccc3c1n2-c1nccc(-c2cccc(-c3ccc(-c4ccccc4)cc3)c2)n1]

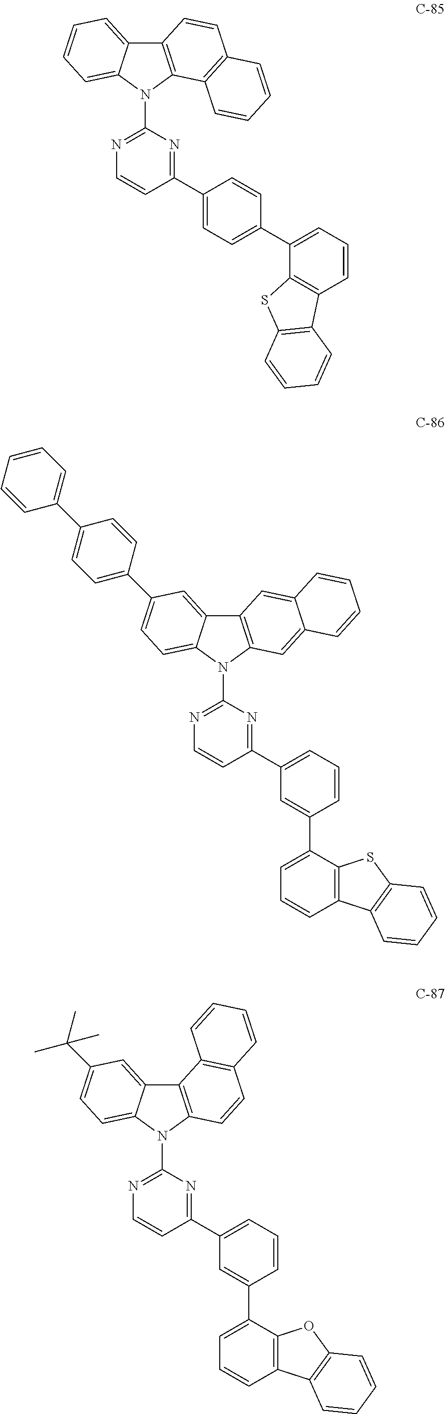 [SMILES: c1ccc2c(c1)ccc1c3ccccc3n(-c3nccc(-c4ccc(-c5cccc6c5sc5ccccc56)cc4)n3)c21 ; c1ccc(-c2ccc(-c3ccc4c(c3)c3cc5ccccc5cc3n4-c3nccc(-c4cccc(-c5cccc6c5sc5ccccc56)c4)n3)cc2)cc1 ; CC(C)(C)c1ccc2c(c1)c1c3ccccc3ccc1n2-c1nccc(-c2cccc(-c3cccc4c3oc3ccccc34)c2)n1]

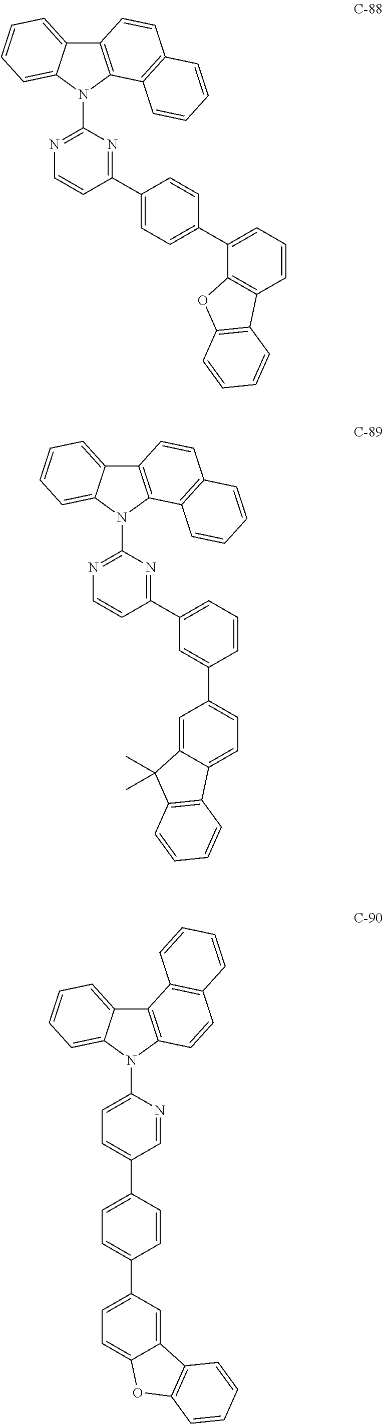 [SMILES: c1ccc2c(c1)ccc1c3ccccc3n(-c3nccc(-c4ccc(-c5cccc6c5oc5ccccc56)cc4)n3)c21 ; CC1(C)c2ccccc2-c2ccc(-c3cccc(-c4ccnc(-n5c6ccccc6c6ccc7ccccc7c65)n4)c3)cc21 ; c1ccc2c(c1)ccc1c2c2ccccc2n1-c1ccc(-c2ccc(-c3ccc4oc5ccccc5c4c3)cc2)cn1]

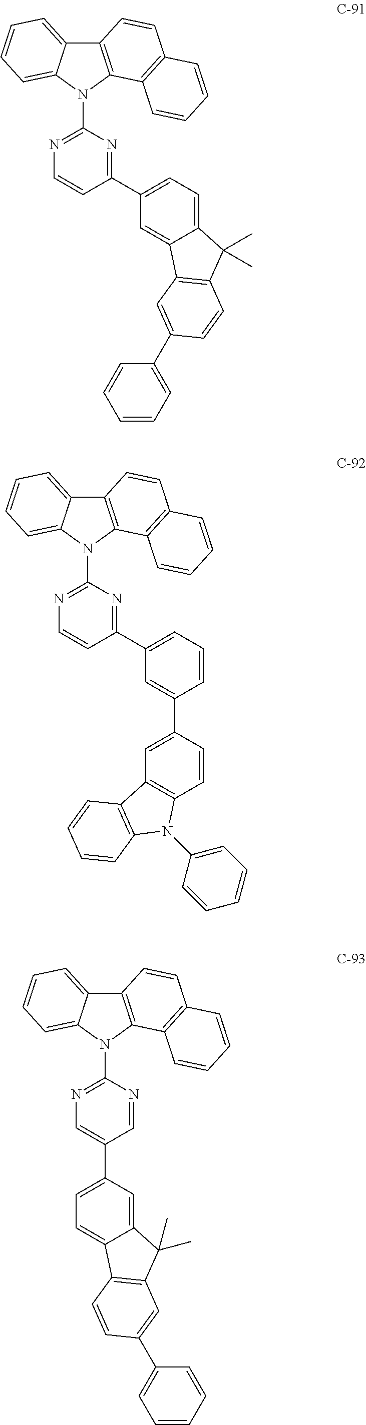 [SMILES: CC1(C)c2ccc(-c3ccccc3)cc2-c2cc(-c3ccnc(-n4c5ccccc5c5ccc6ccccc6c54)n3)ccc21 ; c1ccc(-n2c3ccccc3c3cc(-c4cccc(-c5ccnc(-n6c7ccccc7c7ccc8ccccc8c76)n5)c4)ccc32)cc1 ; CC1(C)c2cc(-c3ccccc3)ccc2-c2ccc(-c3cnc(-n4c5ccccc5c5ccc6ccccc6c54)nc3)cc21]

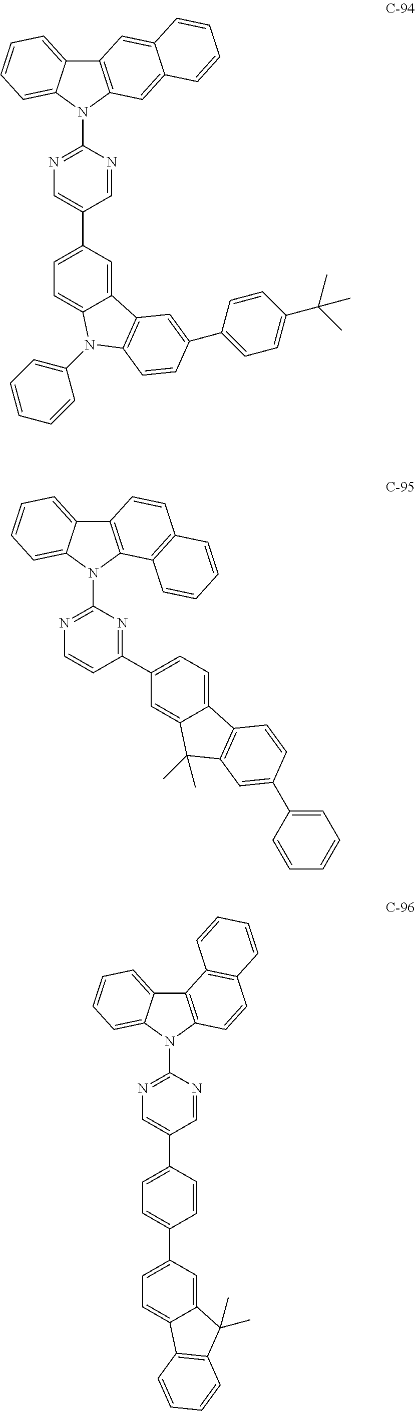 [SMILES: CC(C)(C)c1ccc(-c2ccc3c(c2)c2cc(-c4cnc(-n5c6ccccc6c6cc7ccccc7cc65)nc4)ccc2n3-c2ccccc2)cc1 ; CC1(C)c2cc(-c3ccccc3)ccc2-c2ccc(-c3ccnc(-n4c5ccccc5c5ccc6ccccc6c54)n3)cc21 ; CC1(C)c2ccccc2-c2ccc(-c3ccc(-c4cnc(-n5c6ccccc6c6c7ccccc7ccc65)nc4)cc3)cc21]

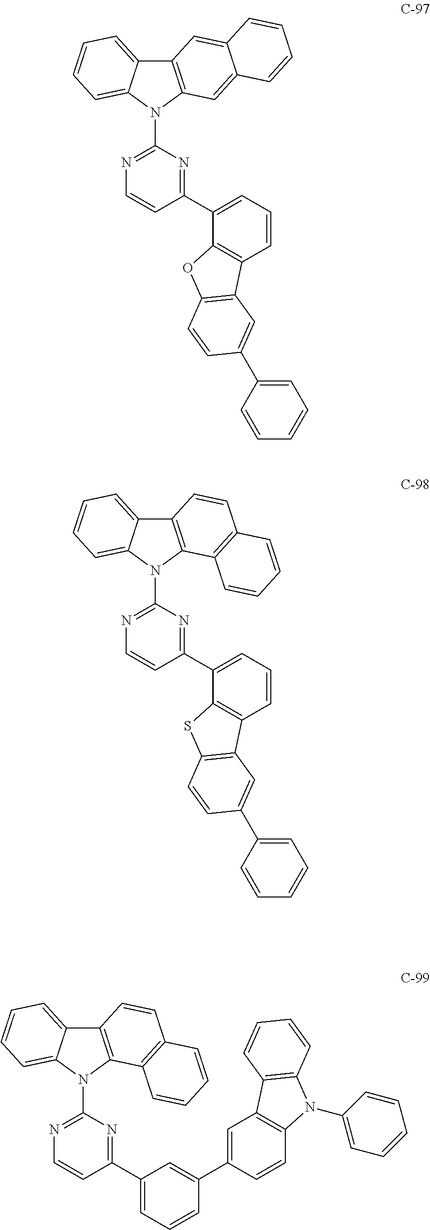 [SMILES: c1ccc(-c2ccc3oc4c(-c5ccnc(-n6c7ccccc7c7cc8ccccc8cc76)n5)cccc4c3c2)cc1 ; c1ccc(-c2ccc3sc4c(-c5ccnc(-n6c7ccccc7c7ccc8ccccc8c76)n5)cccc4c3c2)cc1 ; c1ccc(-n2c3ccccc3c3cc(-c4cccc(-c5ccnc(-n6c7ccccc7c7ccc8ccccc8c76)n5)c4)ccc32)cc1]

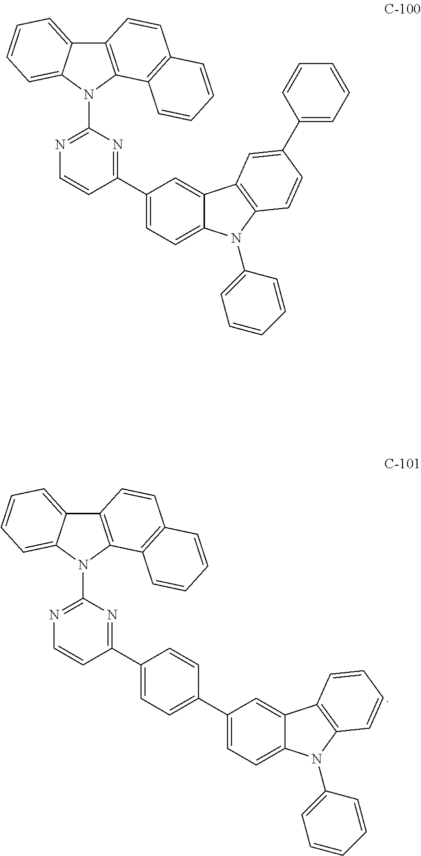 [SMILES: c1ccc(-c2ccc3c(c2)c2cc(-c4ccnc(-n5c6ccccc6c6ccc7ccccc7c65)n4)ccc2n3-c2ccccc2)cc1 ; c1ccc(-n2c3ccccc3c3cc(-c4ccc(-c5ccnc(-n6c7ccccc7c7ccc8ccccc8c76)n5)cc4)ccc32)cc1]

The organic electroluminescence compounds according to the present invention can be prepared according to the following reaction scheme.

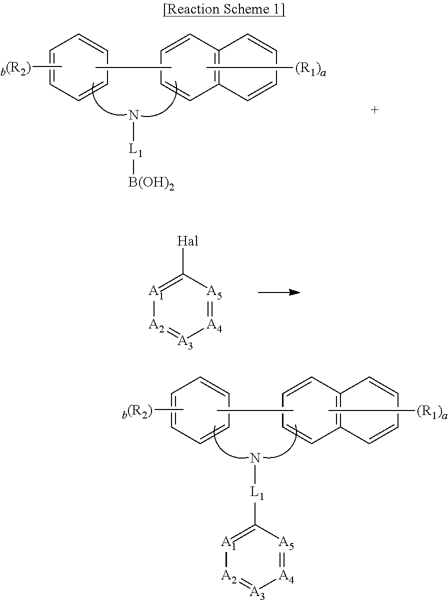

wherein R₁, R₂, a, b, L₁ and Ar₁ to Ar₅ are as defined in formula 1 above, and Hal represents a halogen.

In addition, the present invention provides an organic electroluminescence material comprising the organic electroluminescence compound of formula 1, and an organic electroluminescence device comprising the material. Said material can be comprised of the organic electroluminescence compound according to the present invention alone, or can further include conventional materials generally used in organic electroluminescence materials.

The organic electroluminescence device according to the present invention comprises a first electrode, a second electrode, and at least one organic layer between said first and second electrodes. Said organic layer comprises at least one organic electroluminescence compound of formula 1. Further, said organic layer comprises a light-emitting layer in which the organic electroluminescence compound of formula 1 may be used as a host material.

One of the first electrodes and the second electrodes is an anode and the other is a cathode. The organic layer further comprises a light-emitting layer, and at least one layer selected from the group consisting of a hole injection layer, a hole transport layer, an electron transport layer, an electron injection layer, an interlayer and a hole blocking layer.

The organic electroluminescence compound of formula 1 of the present invention can be comprised of in the light-emitting layer. When used in the light-emitting layer, the organic electroluminescence compounds of formula 1 of the present invention can be included as a host material. Preferably, the light-emitting layer may comprise at least one dopant. If necessary, other compounds in addition to the organic electroluminescence compound of formula 1 of the present invention may be further included as a second host material.

The second host material can be from any of the known phosphorescent hosts. The hosts selected from the group consisting of compounds represented by the formulae 2 to 6 is particularly preferable in view of the luminous efficiency:

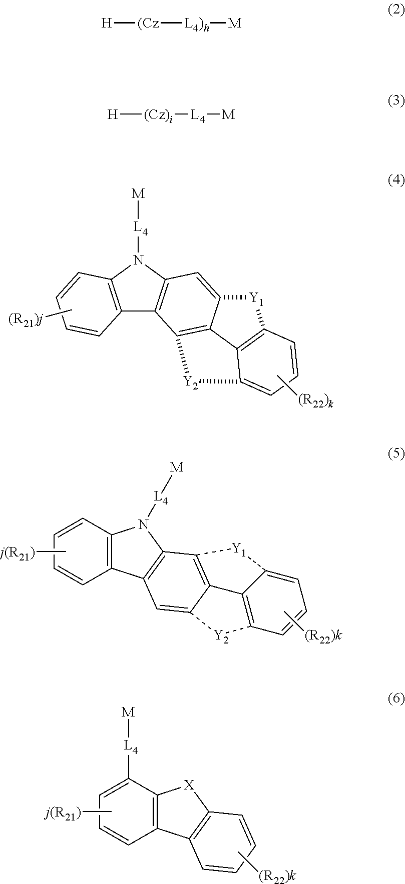

wherein

Cz represents the following structure:

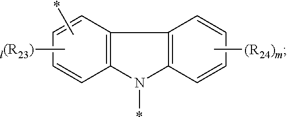

X presents O or S;

R₂₁ to R₂₄ each independently represent hydrogen, deuterium, a halogen, a substituted or unsubstituted (C1-C30)alkyl group, a substituted or unsubstituted (C6-C30)aryl group, a substituted or unsubstituted 5- or 30-membered heteroaryl group or R₂₅R₂₆R₂₇Si—; R₂₅ to R₂₇ each independently represent a substituted or unsubstituted (C1-C30)alkyl group, or a substituted or unsubstituted (C6-C30)aryl group; L₄ represents a single bond, a substituted or unsubstituted (C6-C30)arylene group, or a substituted or unsubstituted 5- or 30-membered heteroarylene group; M represents a substituted or unsubstituted (C6-C30)aryl group, or a substituted or unsubstituted 5- or 30-membered heteroaryl group; Y₁ and Y₂ represent —O—, —S—, —N(R₃₁)— or —C(R₃₂)(R₃₃)—, proviso that Y₁ and Y₂ are not simultaneously present; R₃₁ to R₃₃ each independently represent a substituted or unsubstituted (C1-C30)alkyl group, a substituted or unsubstituted (C6-C30)aryl group, a substituted or unsubstituted 5- or 30-membered heteroaryl group, and R₃₂ and R₃₃ may be the same or different; h and i each independently represent an integer of 1 to 3; j, k, l and m each independently represent an integer of 0 to 4; where h, I, j, k, l or m is an integer of 2 or more, each of (Cz-L₄), each of (Cz), each of R₂₁, each of R₂₂, each of R₂₃ or each of R₂₄ may be the same or different;

Specifically, the second host material includes the following:

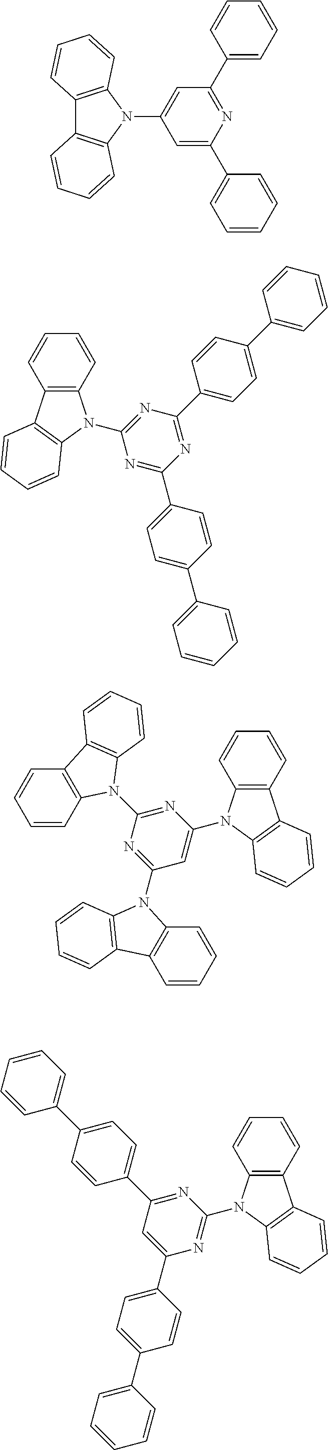

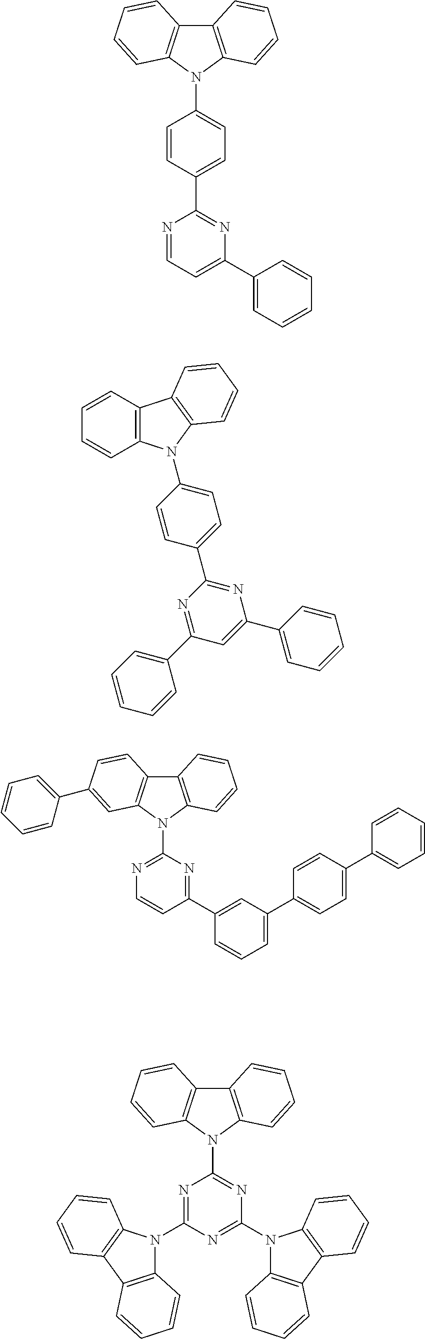

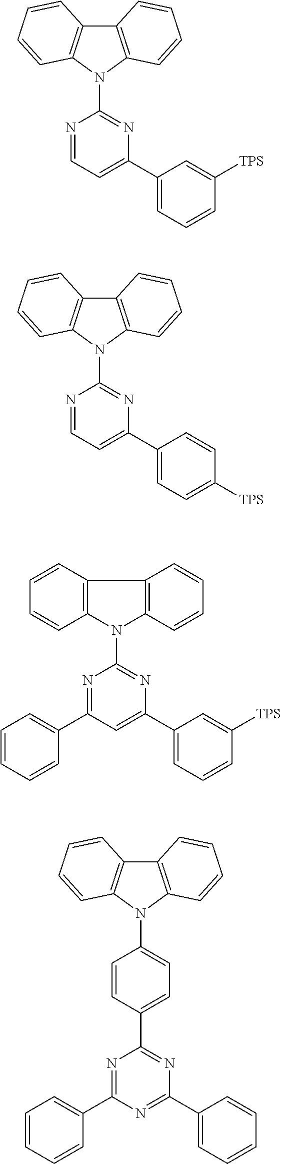

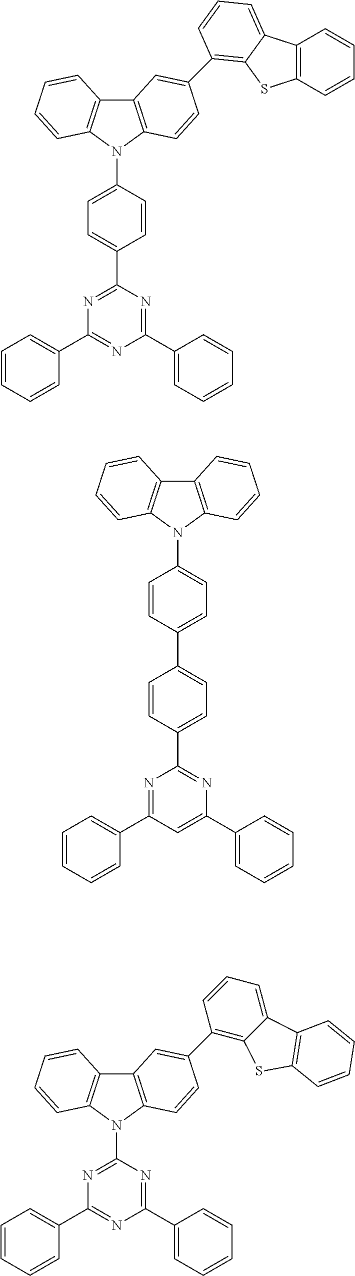 [SMILES: c1ccc(-c2nc(-c3ccccc3)nc(-c3ccc(-n4c5ccccc5c5cc(-c6cccc7c6sc6ccccc67)ccc54)cc3)n2)cc1 ; c1ccc(-c2cc(-c3ccccc3)nc(-c3ccc(-c4ccc(-n5c6ccccc6c6ccccc65)cc4)cc3)n2)cc1 ; c1ccc(-c2nc(-c3ccccc3)nc(-n3c4ccccc4c4cc(-c5cccc6c5sc5ccccc56)ccc43)n2)cc1]

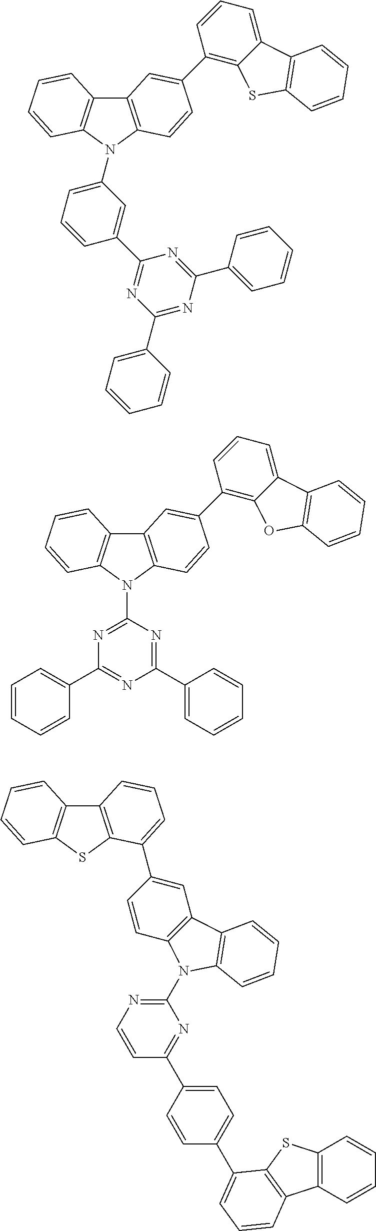

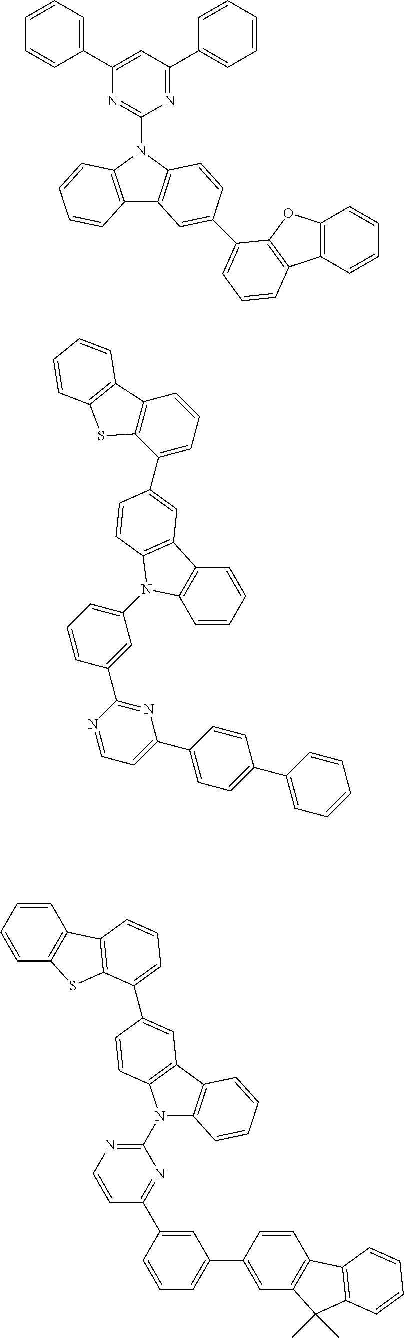 [SMILES: c1ccc(-c2cc(-c3ccccc3)nc(-n3c4ccccc4c4cc(-c5cccc6c5oc5ccccc56)ccc43)n2)cc1 ; c1ccc(-c2ccc(-c3ccnc(-c4cccc(-n5c6ccccc6c6cc(-c7cccc8c7sc7ccccc78)ccc65)c4)n3)cc2)cc1 ; CC1(C)c2ccccc2-c2ccc(-c3cccc(-c4ccnc(-n5c6ccccc6c6cc(-c7cccc8c7sc7ccccc78)ccc65)n4)c3)cc21]

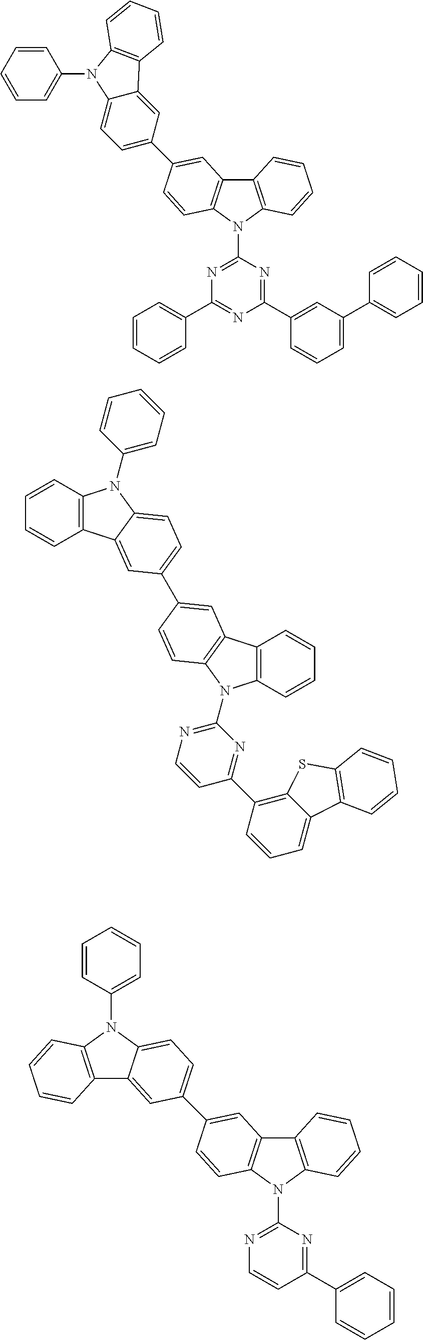

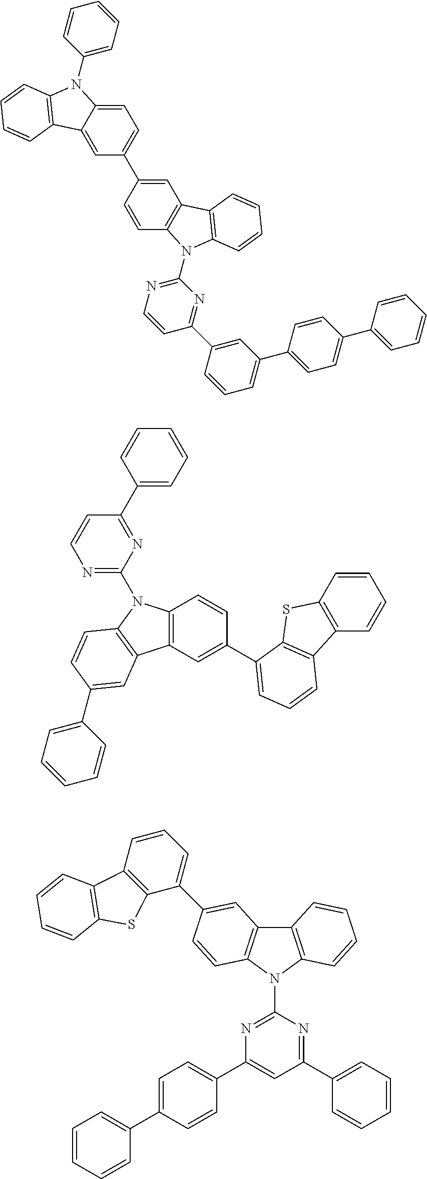 [SMILES: c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1 ; c1ccc(-c2ccc3c(c2)c2cc(-c4cccc5c4sc4ccccc45)ccc2n3-c2nccc(-c3ccccc3)n2)cc1 ; c1ccc(-c2ccc(-c3cc(-c4ccccc4)nc(-n4c5ccccc5c5cc(-c6cccc7c6sc6ccccc67)ccc54)n3)cc2)cc1]

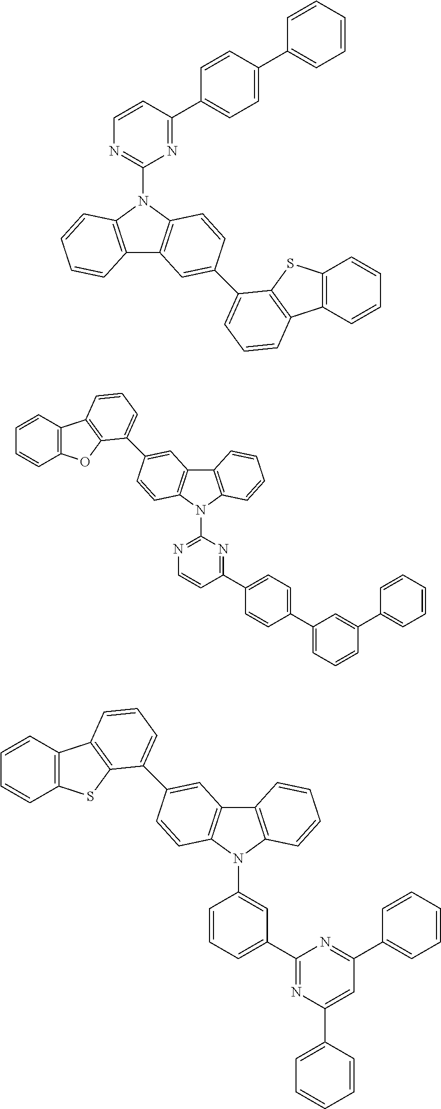 [SMILES: c1ccc(-c2ccc(-c3ccnc(-n4c5ccccc5c5cc(-c6cccc7c6sc6ccccc67)ccc54)n3)cc2)cc1 ; c1ccc(-c2cccc(-c3ccc(-c4ccnc(-n5c6ccccc6c6cc(-c7cccc8c7oc7ccccc78)ccc65)n4)cc3)c2)cc1 ; c1ccc(-c2cc(-c3ccccc3)nc(-c3cccc(-n4c5ccccc5c5cc(-c6cccc7c6sc6ccccc67)ccc54)c3)n2)cc1]

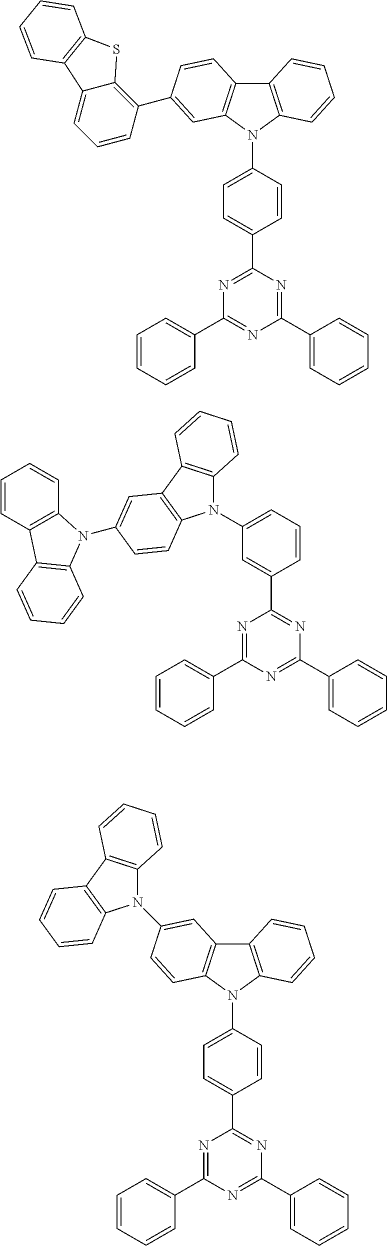

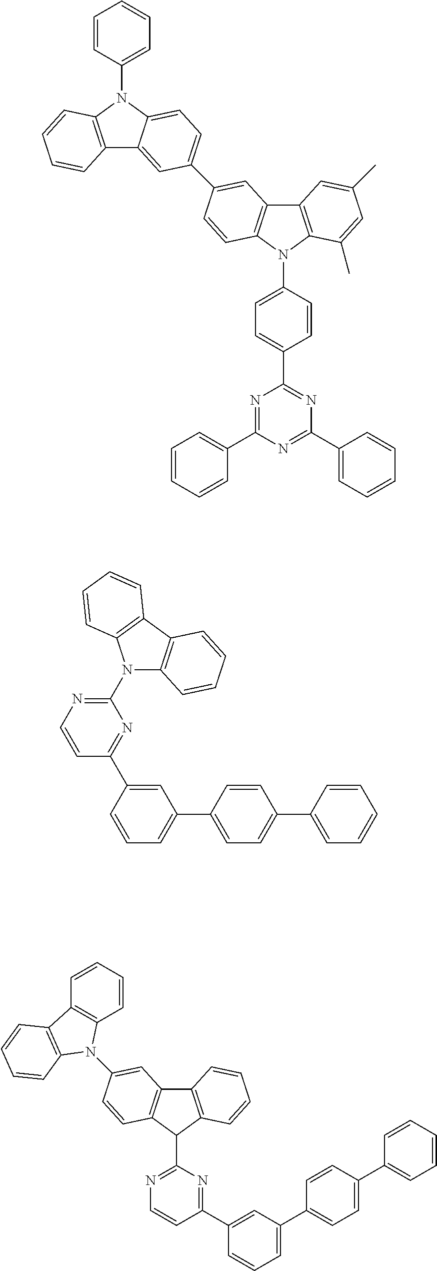 [SMILES: Cc1cc(C)c2c(c1)c1cc(-c3ccc4c(c3)c3ccccc3n4-c3ccccc3)ccc1n2-c1ccc(-c2nc(-c3ccccc3)nc(-c3ccccc3)n2)cc1 ; c1ccc(-c2ccc(-c3cccc(-c4ccnc(-n5c6ccccc6c6ccccc65)n4)c3)cc2)cc1 ; c1ccc(-c2ccc(-c3cccc(-c4ccnc(C5c6ccccc6-c6cc(-n7c8ccccc8c8ccccc87)ccc65)n4)c3)cc2)cc1]

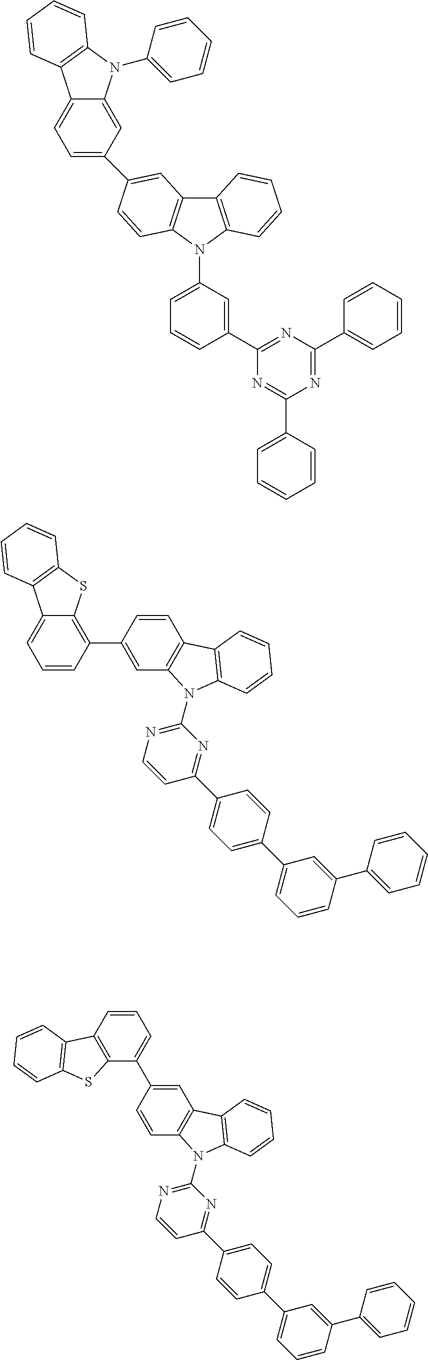 [SMILES: c1ccc(-c2nc(-c3ccccc3)nc(-c3cccc(-n4c5ccccc5c5cc(-c6ccc7c8ccccc8n(-c8ccccc8)c7c6)ccc54)c3)n2)cc1 ; c1ccc(-c2cccc(-c3ccc(-c4ccnc(-n5c6ccccc6c6ccc(-c7cccc8c7sc7ccccc78)cc65)n4)cc3)c2)cc1 ; c1ccc(-c2cccc(-c3ccc(-c4ccnc(-n5c6ccccc6c6cc(-c7cccc8c7sc7ccccc78)ccc65)n4)cc3)c2)cc1]

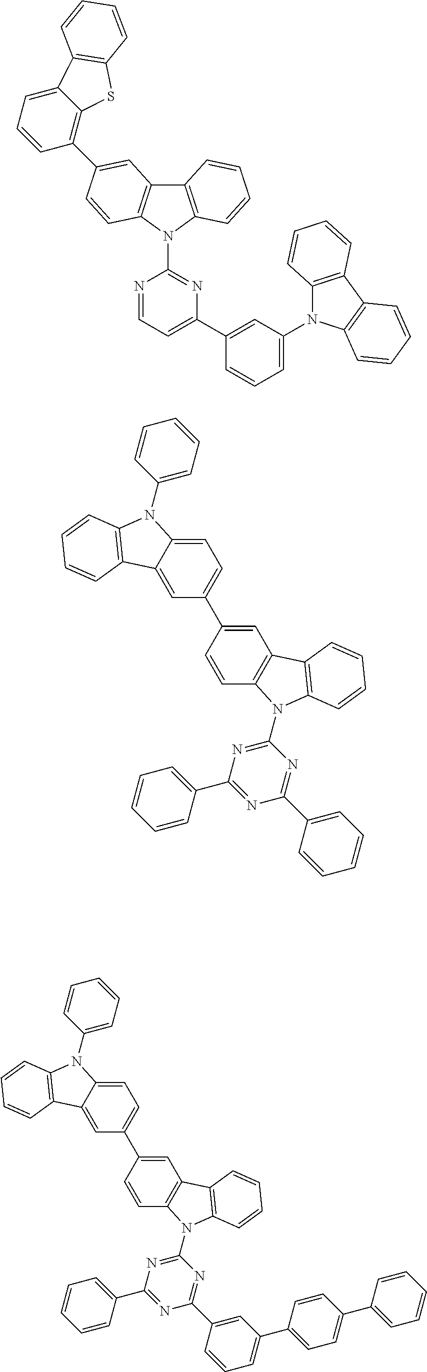 [SMILES: c1cc(-c2ccnc(-n3c4ccccc4c4cc(-c5cccc6c5sc5ccccc56)ccc43)n2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2ccc(-c3cccc(-c4nc(-c5ccccc5)nc(-n5c6ccccc6c6cc(-c7ccc8c(c7)c7ccccc7n8-c7ccccc7)ccc65)n4)c3)cc2)cc1]

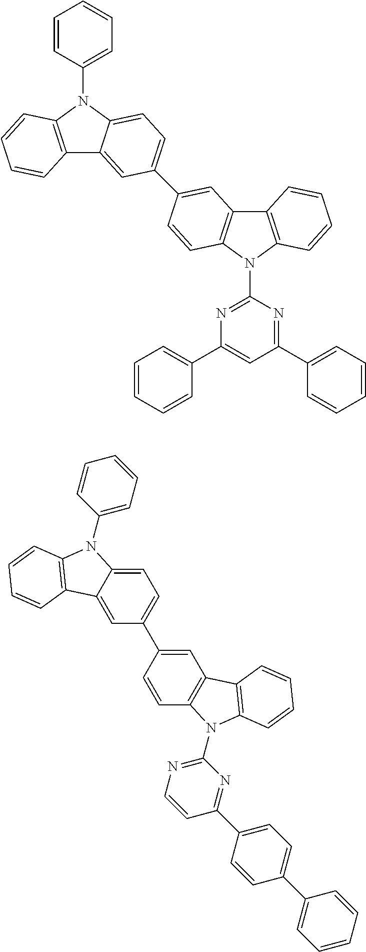 [SMILES: c1ccc(-c2cc(-c3ccccc3)nc(-n3c4ccccc4c4cc(-c5ccc6c(c5)c5ccccc5n6-c5ccccc5)ccc43)n2)cc1 ; c1ccc(-c2ccc(-c3ccnc(-n4c5ccccc5c5cc(-c6ccc7c(c6)c6ccccc6n7-c6ccccc6)ccc54)n3)cc2)cc1]

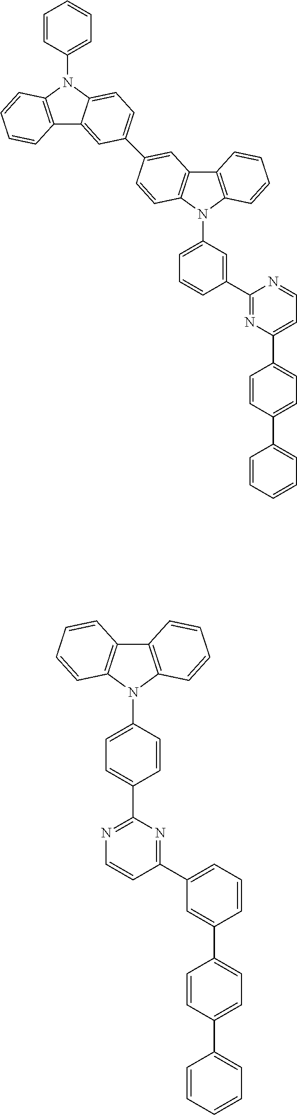 [SMILES: c1ccc(-c2ccc(-c3ccnc(-c4cccc(-n5c6ccccc6c6cc(-c7ccc8c(c7)c7ccccc7n8-c7ccccc7)ccc65)c4)n3)cc2)cc1 ; c1ccc(-c2ccc(-c3cccc(-c4ccnc(-c5ccc(-n6c7ccccc7c7ccccc76)cc5)n4)c3)cc2)cc1]

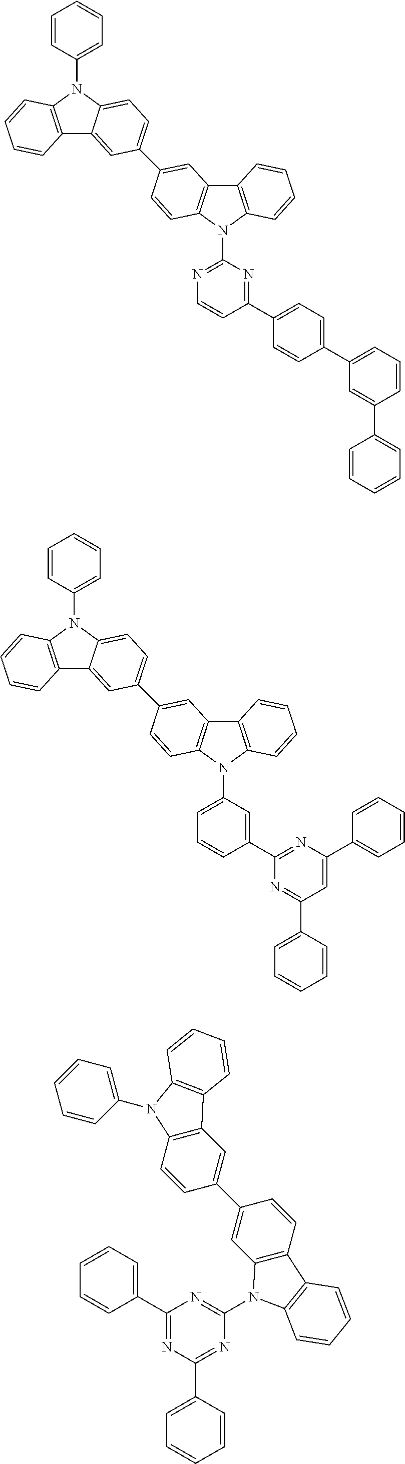 [SMILES: c1ccc(-c2cccc(-c3ccc(-c4ccnc(-n5c6ccccc6c6cc(-c7ccc8c(c7)c7ccccc7n8-c7ccccc7)ccc65)n4)cc3)c2)cc1 ; c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2nc(-c3ccccc3)nc(-n3c4ccccc4c4ccc(-c5ccc6c(c5)c5ccccc5n6-c5ccccc5)cc43)n2)cc1]

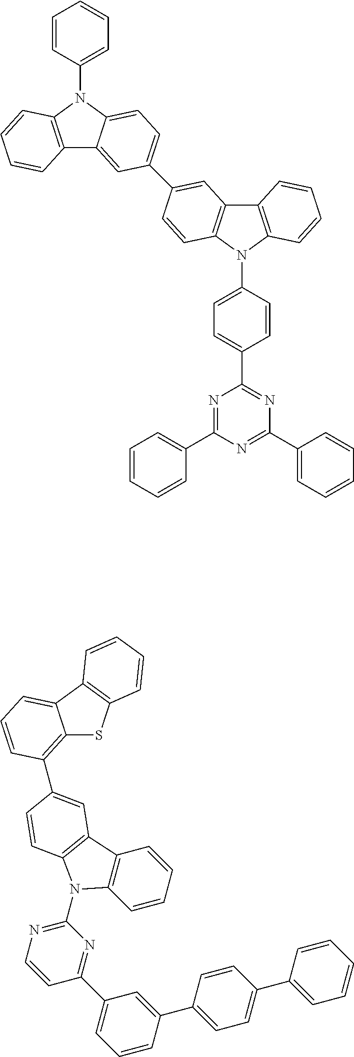 [SMILES: c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2ccc(-c3cccc(-c4ccnc(-n5c6ccccc6c6cc(-c7cccc8c7sc7ccccc78)ccc65)n4)c3)cc2)cc1]

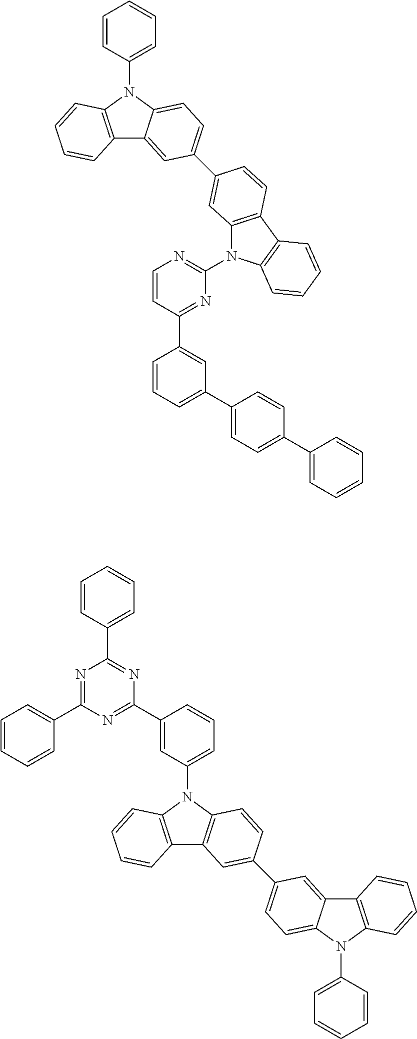 [SMILES: c1ccc(-c2ccc(-c3cccc(-c4ccnc(-n5c6ccccc6c6ccc(-c7ccc8c(c7)c7ccccc7n8-c7ccccc7)cc65)n4)c3)cc2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

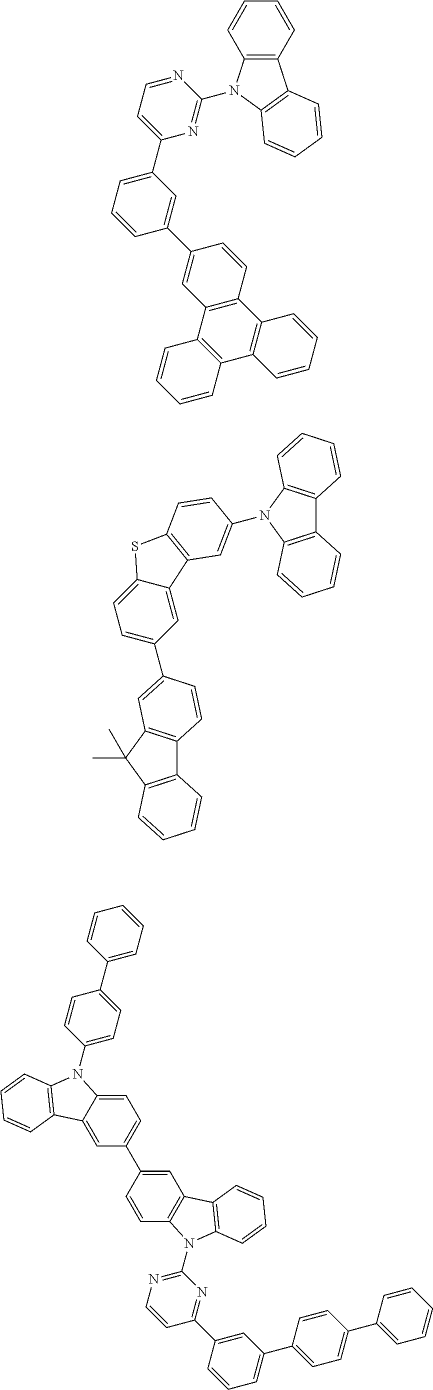 [SMILES: c1cc(-c2ccc3c4ccccc4c4ccccc4c3c2)cc(-c2ccnc(-n3c4ccccc4c4ccccc43)n2)c1 ; CC1(C)c2ccccc2-c2ccc(-c3ccc4sc5ccc(-n6c7ccccc7c7ccccc76)cc5c4c3)cc21 ; c1ccc(-c2ccc(-c3cccc(-c4ccnc(-n5c6ccccc6c6cc(-c7ccc8c(c7)c7ccccc7n8-c7ccc(-c8ccccc8)cc7)ccc65)n4)c3)cc2)cc1]

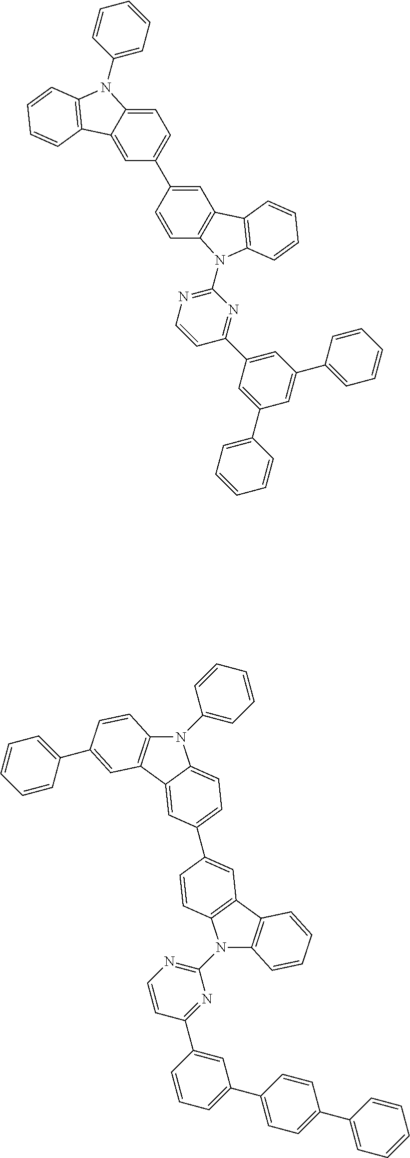 [SMILES: c1ccc(-c2cc(-c3ccccc3)cc(-c3ccnc(-n4c5ccccc5c5cc(-c6ccc7c(c6)c6ccccc6n7-c6ccccc6)ccc54)n3)c2)cc1 ; c1ccc(-c2ccc(-c3cccc(-c4ccnc(-n5c6ccccc6c6cc(-c7ccc8c(c7)c7cc(-c9ccccc9)ccc7n8-c7ccccc7)ccc65)n4)c3)cc2)cc1]

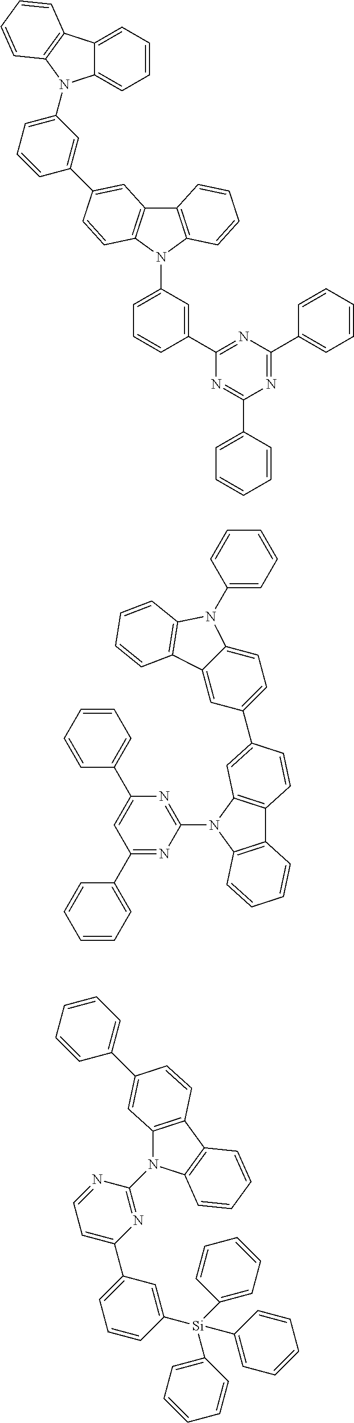

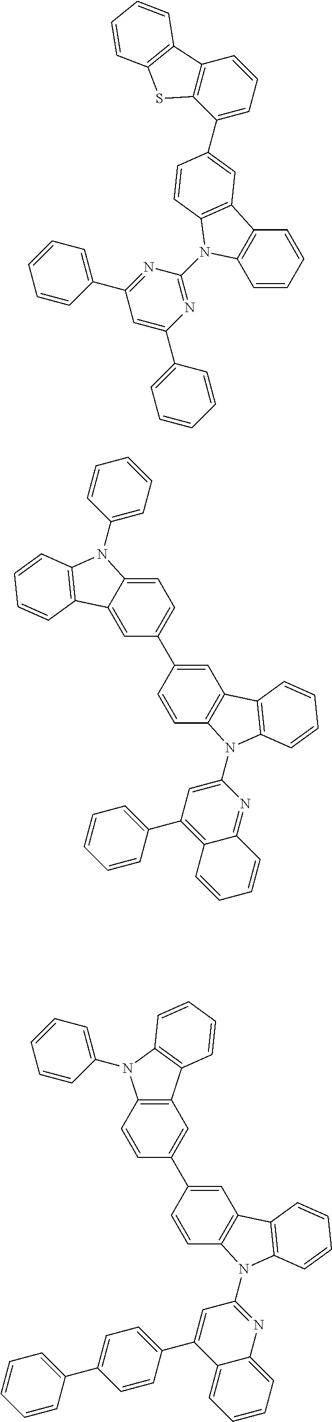 [SMILES: c1ccc(-c2cc(-c3ccccc3)nc(-n3c4ccccc4c4cc(-c5cccc6c5sc5ccccc56)ccc43)n2)cc1 ; c1ccc(-c2cc(-n3c4ccccc4c4cc(-c5ccc6c(c5)c5ccccc5n6-c5ccccc5)ccc43)nc3ccccc23)cc1 ; c1ccc(-c2ccc(-c3cc(-n4c5ccccc5c5cc(-c6ccc7c(c6)c6ccccc6n7-c6ccccc6)ccc54)nc4ccccc34)cc2)cc1]

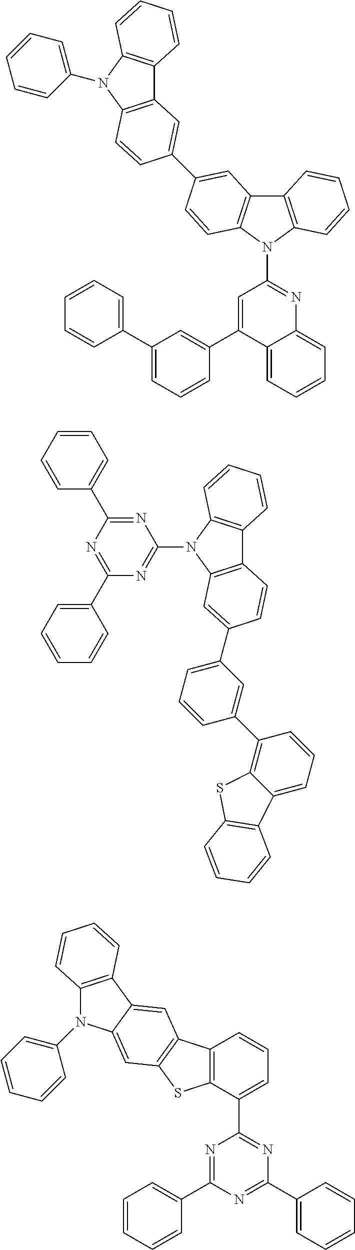 [SMILES: c1ccc(-c2cccc(-c3cc(-n4c5ccccc5c5cc(-c6ccc7c(c6)c6ccccc6n7-c6ccccc6)ccc54)nc4ccccc34)c2)cc1 ; c1ccc(-c2nc(-c3ccccc3)nc(-n3c4ccccc4c4ccc(-c5cccc(-c6cccc7c6sc6ccccc67)c5)cc43)n2)cc1 ; c1ccc(-c2nc(-c3ccccc3)nc(-c3cccc4c3sc3cc5c(cc34)c3ccccc3n5-c3ccccc3)n2)cc1]

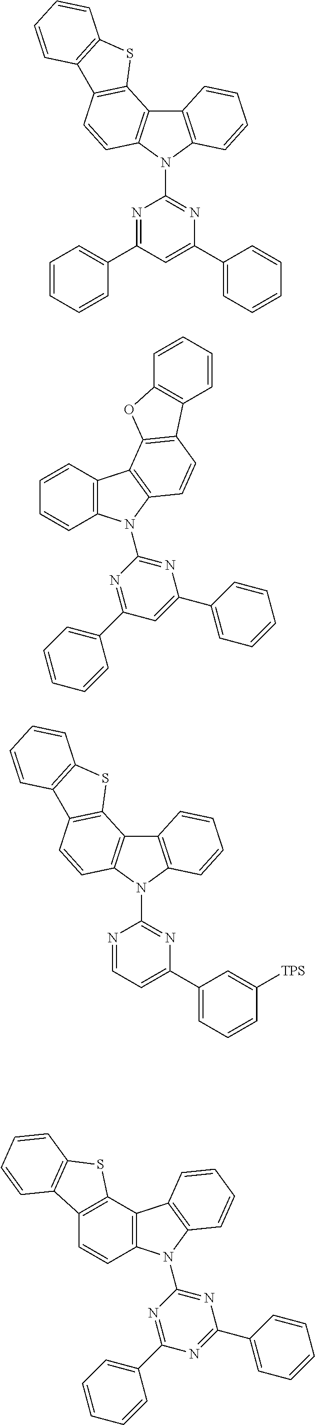

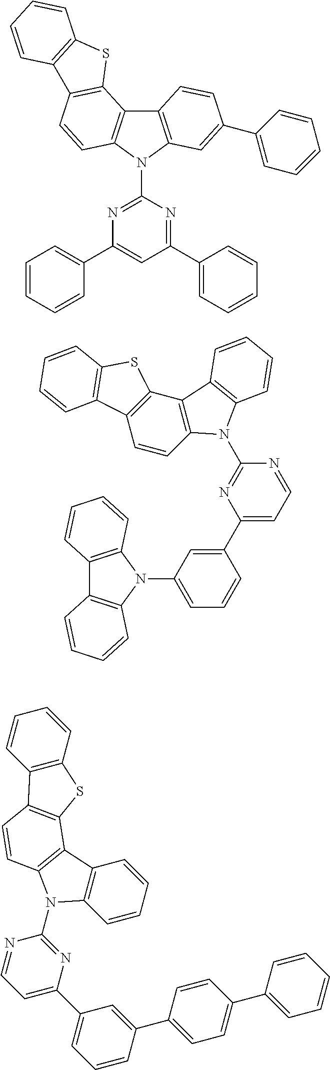

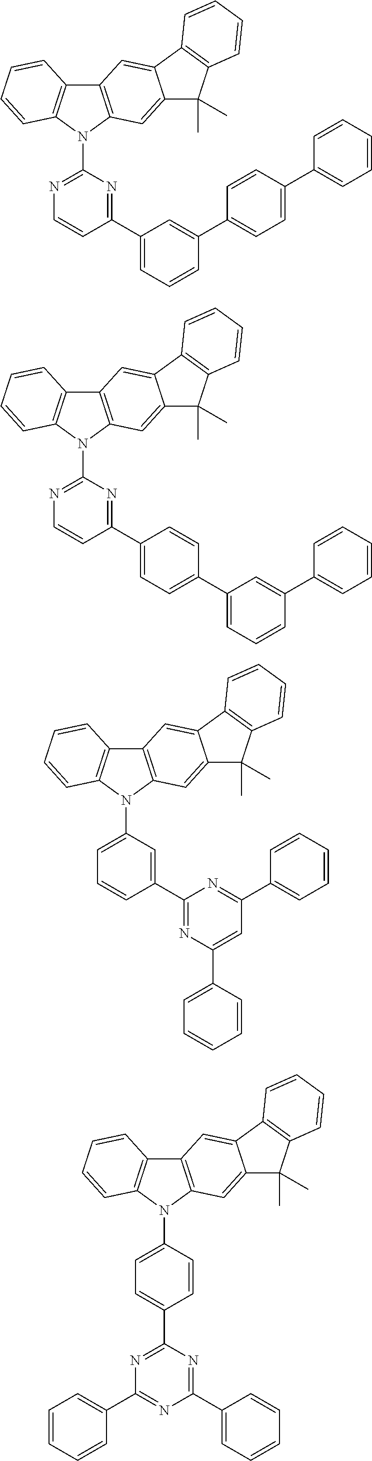

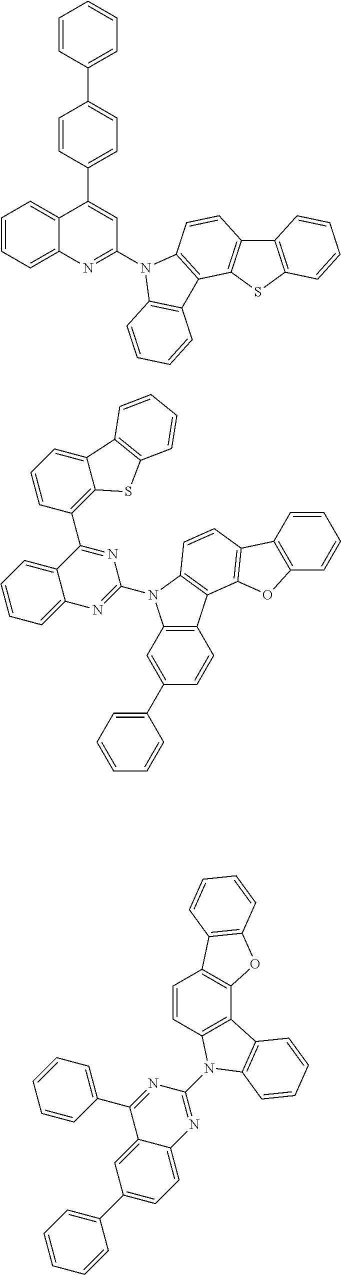

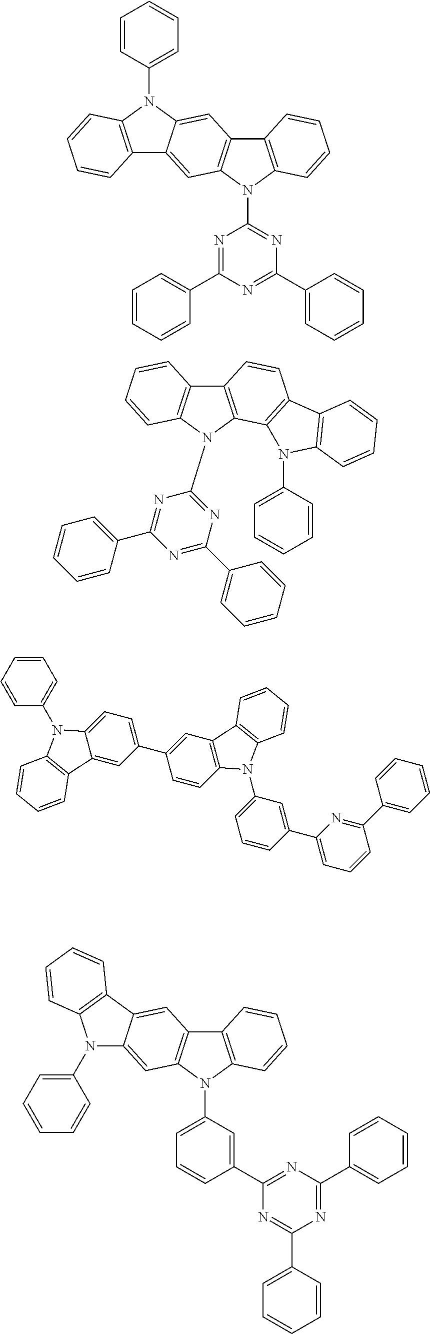

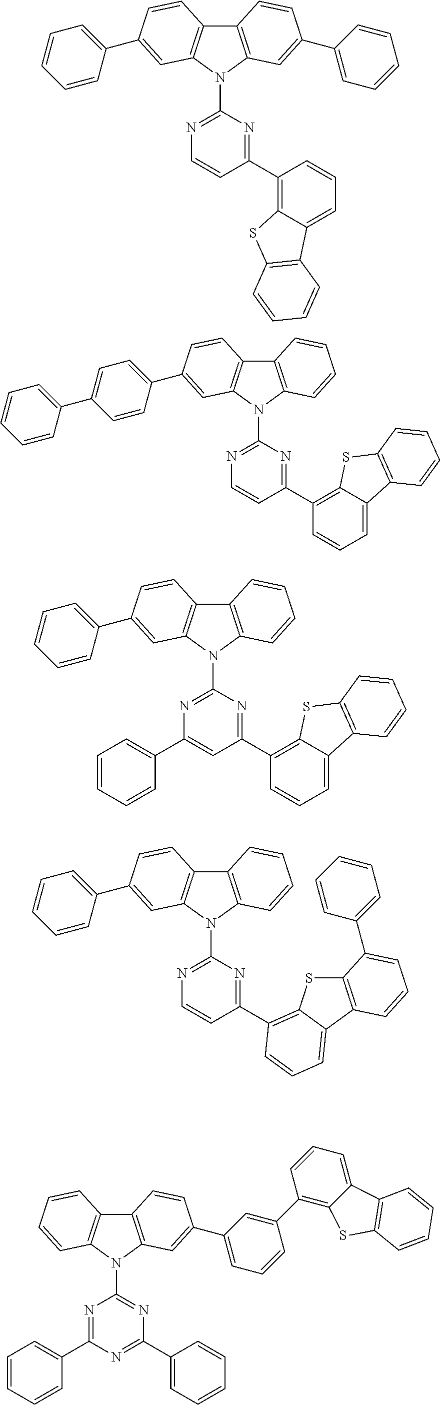

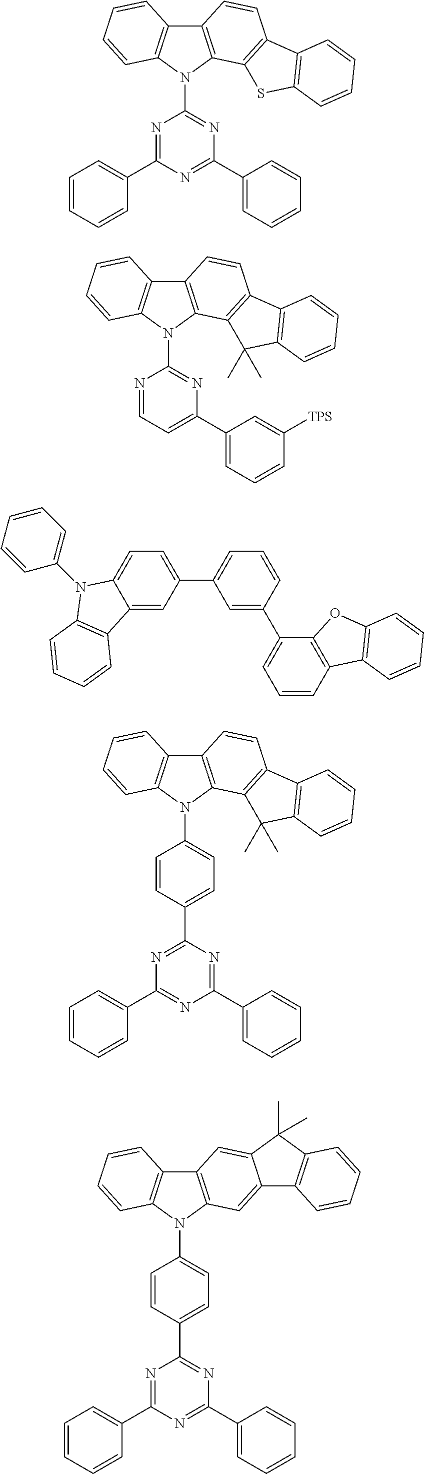

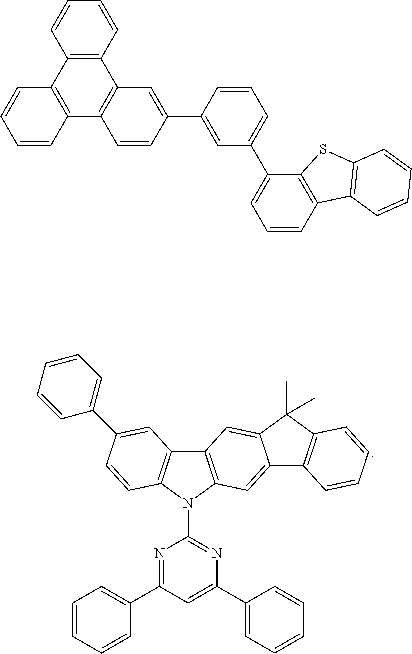 [SMILES: c1cc(-c2ccc3c4ccccc4c4ccccc4c3c2)cc(-c2cccc3c2sc2ccccc23)c1 ; CC1(C)c2ccccc2-c2cc3c(cc21)c1cc(-c2ccccc2)ccc1n3-c1nc(-c2ccccc2)cc(-c2ccccc2)n1]

According to the present invention, the dopant used in the manufacture of the organic electroluminescence device is preferably one or more phosphorescent dopants. The phosphorescent dopant material applied to the organic electroluminescence device of the present invention is not specifically limited, but preferably may be selected from complex compounds of iridium (Ir), osmium (Os), copper (Cu) and platinum (Pt), more preferably ortho metallated complex compounds of iridium, osmium, copper and platinum, and even more preferably ortho metallated iridium complex compounds,

According to the present invention, the dopant comprised in the organic electroluminescence device may be selected from compound represented by the following formulae 7 to 9:

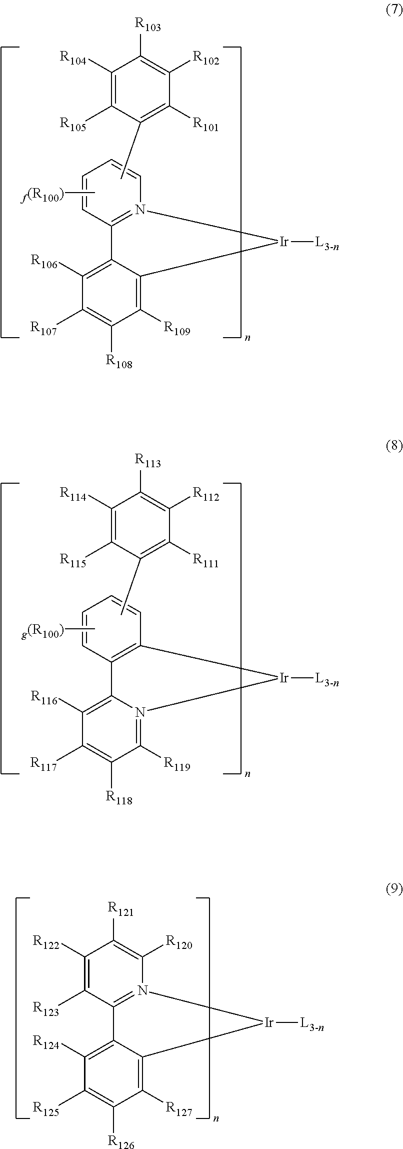

wherein

L is selected from the following structures:

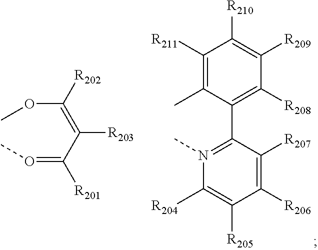

R₁₀₀ represents hydrogen, a substituted or unsubstituted (C1-C30)alkyl group, or a substituted or unsubstituted (C1-C30)cycloalkyl group; R₁₀₁ to R₁₀₉ and R₁₁₁ to R₁₂₃ each independently represent hydrogen, deuterium, a halogen; a (C1-C30)alkyl group unsubstituted or substituted with halogen(s); a substituted or unsubstituted (C1-C30)cycloalkyl group, a cyano group, or a substituted or unsubstituted (C1-C30)alkoxy group; R₁₂₀ to R₁₂₃ are linked to an adjacent substituent(s) to form a fused ring, for example, a quinoline ring; R₁₂₄ to R₁₂₇ each independently represent hydrogen, deuterium, a halogen, a substituted or unsubstituted (C1-C30)alkyl group, or a substituted or unsubstituted (C6-C30)aryl group; when R₁₂₄ to R₁₂₇ are aryl groups, they are linked to an adjacent substituent(s) to form a fused ring, for example, a fluorene ring; R₂₀₁ to R₂₁₁ each independently represent hydrogen, deuterium, a halogen, a (C1-C30)alkyl group unsubstituted or substituted with halogen(s), or a substituted or unsubstituted (C1-C30)cycloalkyl group; f and g each independently represent an integer of 1 to 3; where f or g is an integer of 2 or more, each of R₁₀₀ may be the same or different; and n represents an integer of 1 to 3.

The dopant material includes the following:

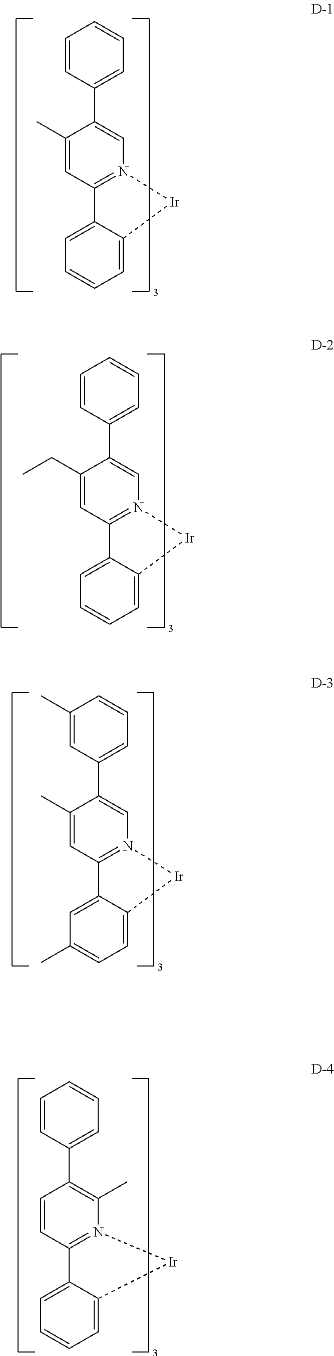

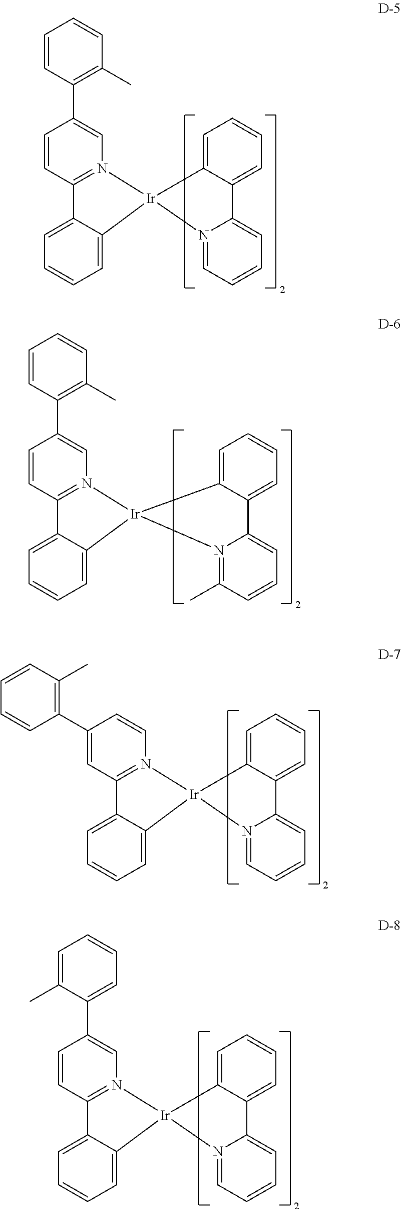

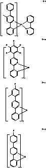

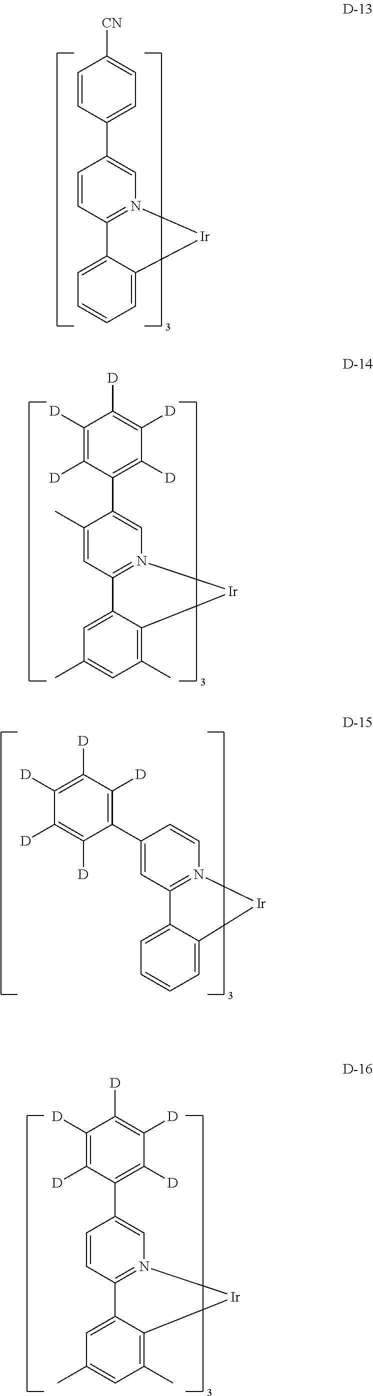

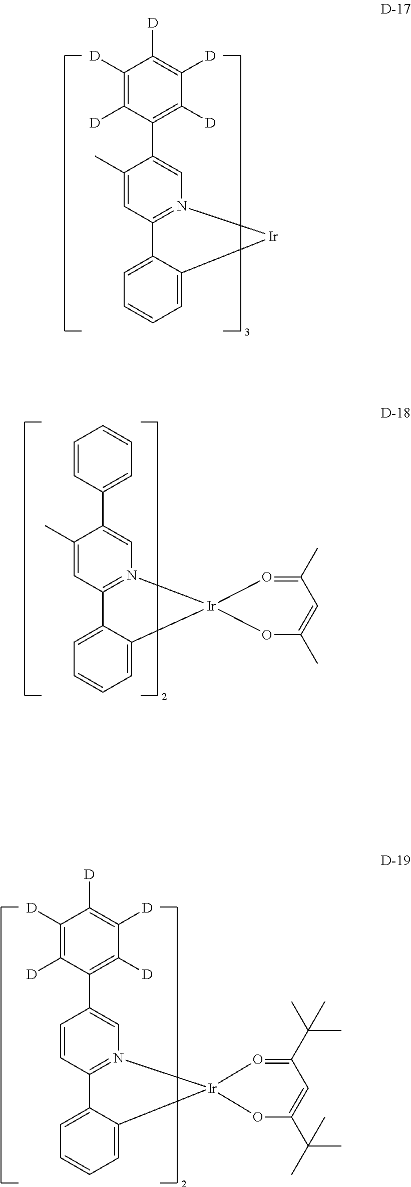

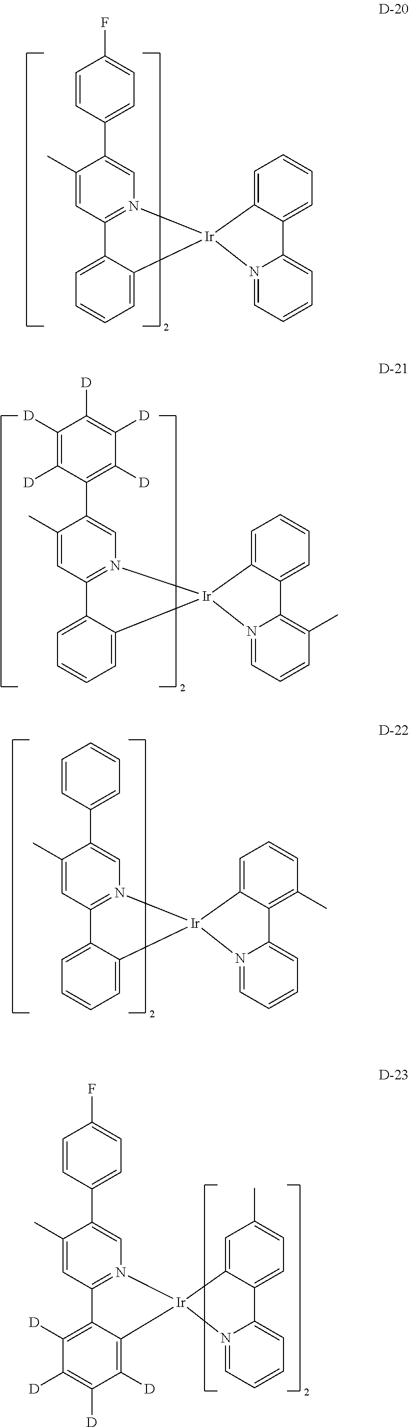

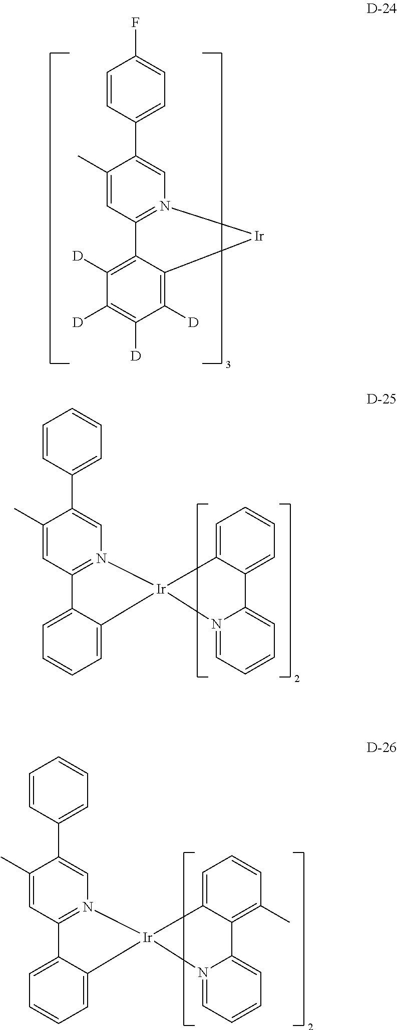

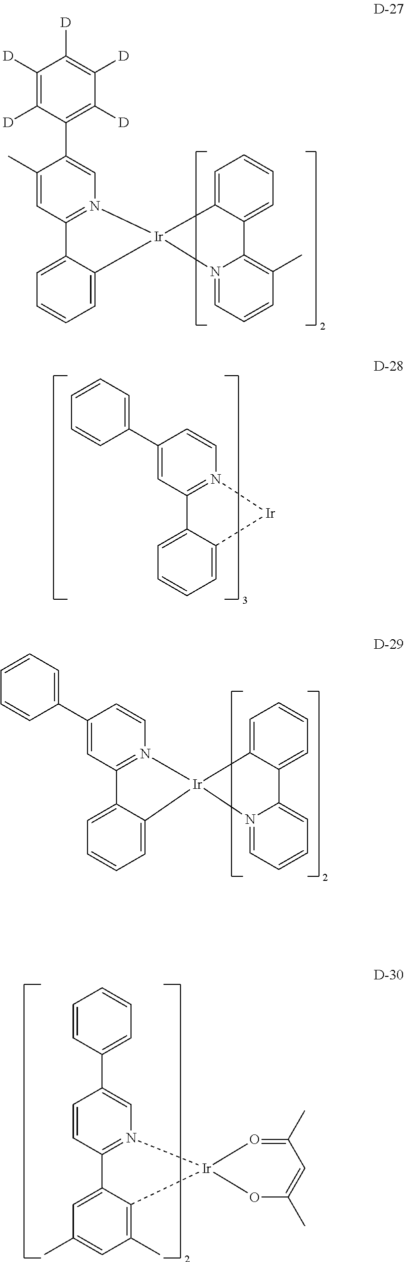

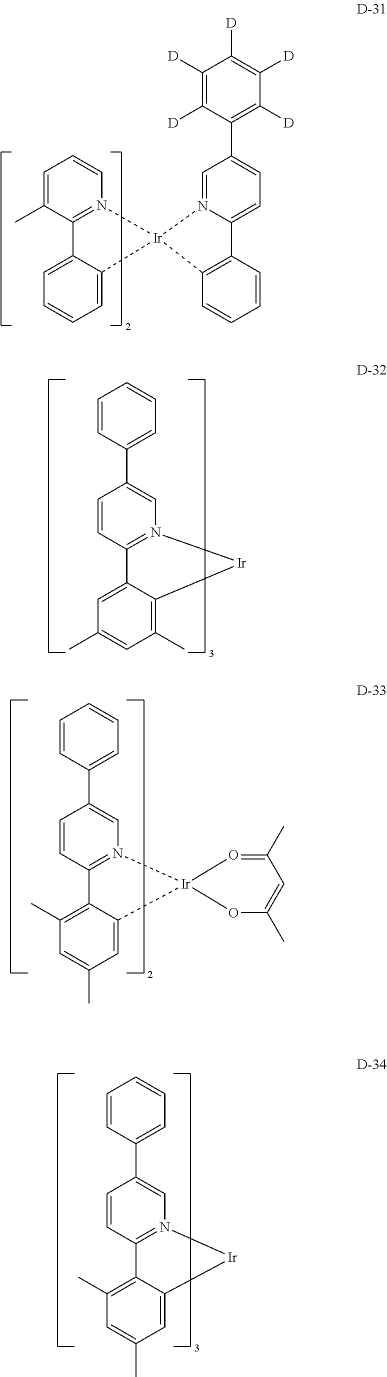

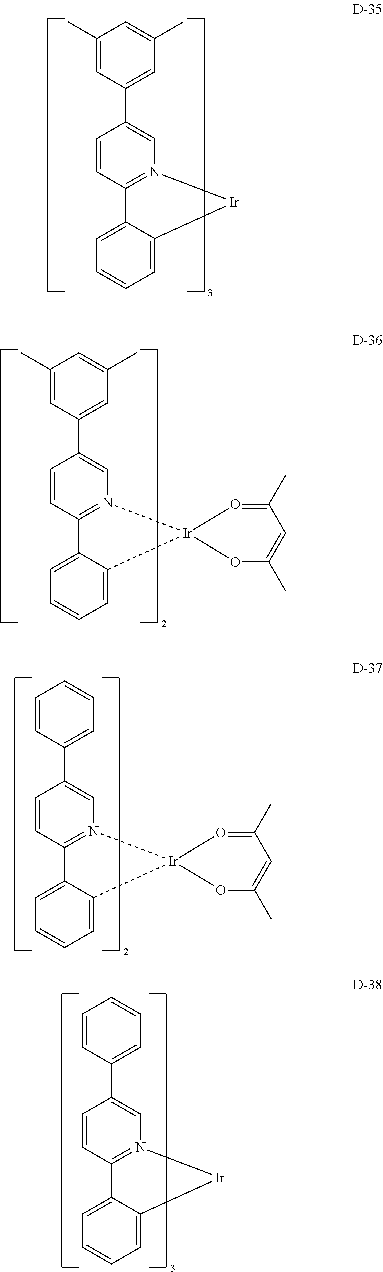

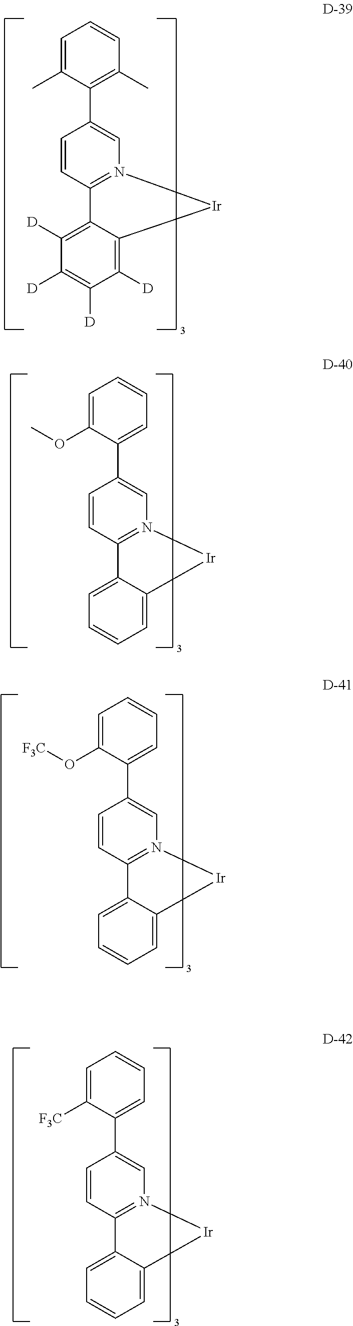

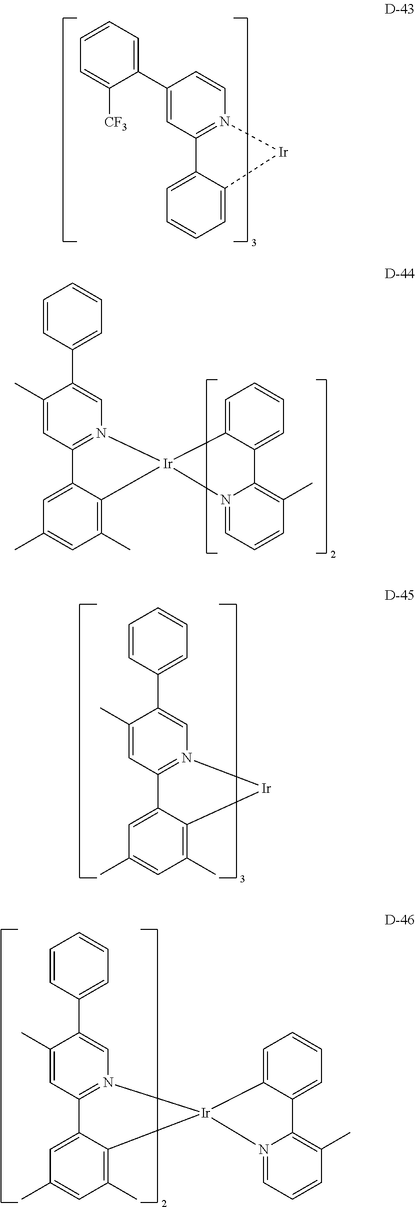

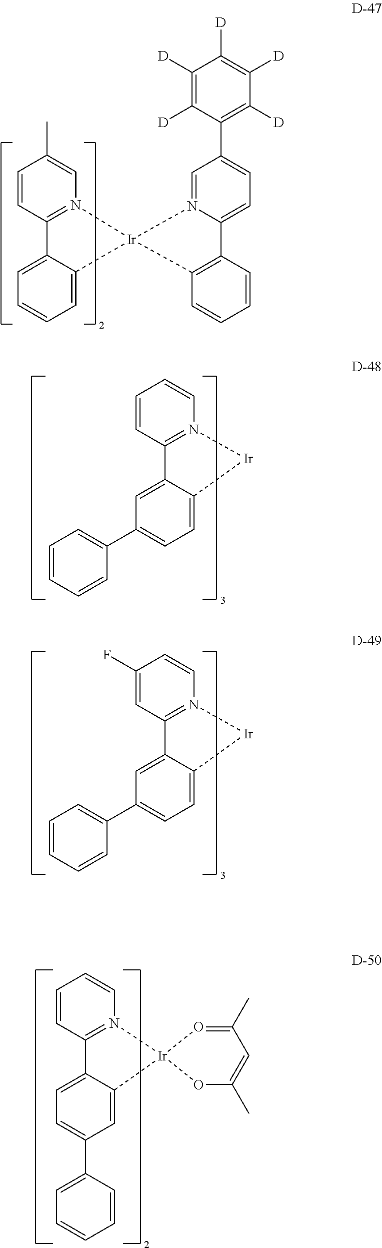

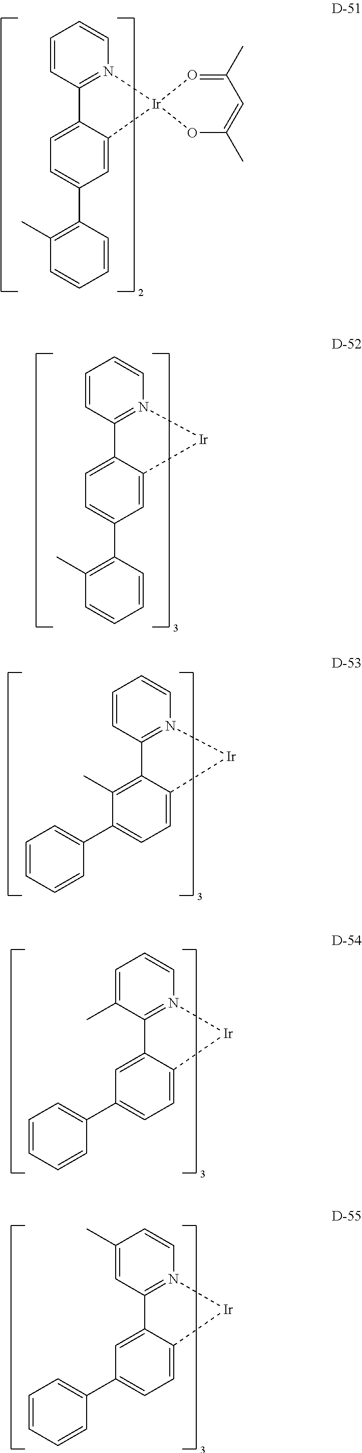

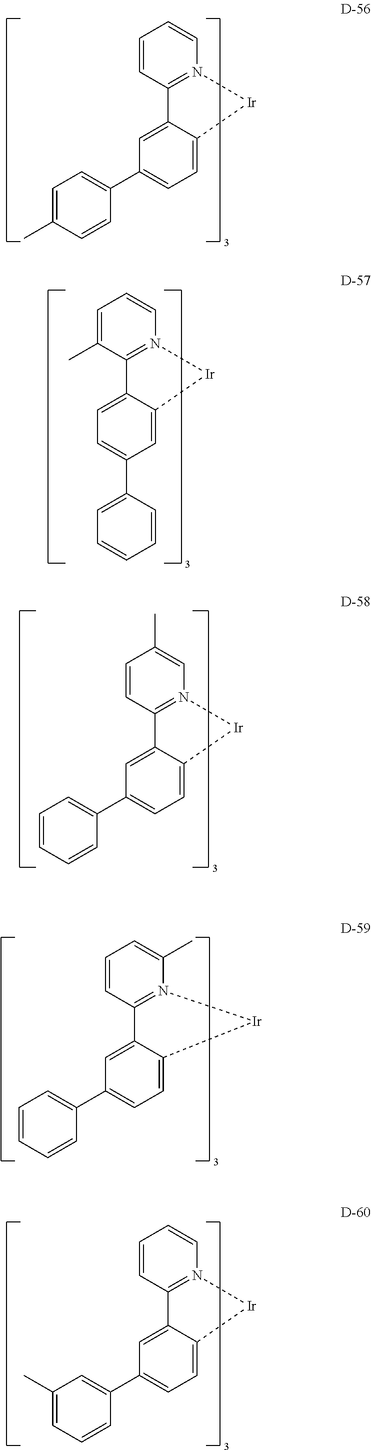

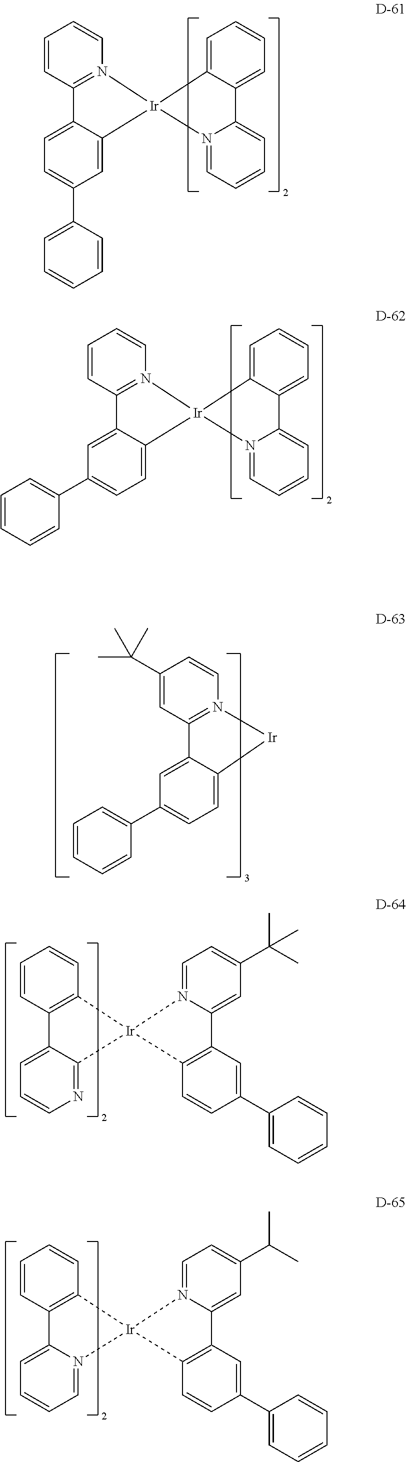

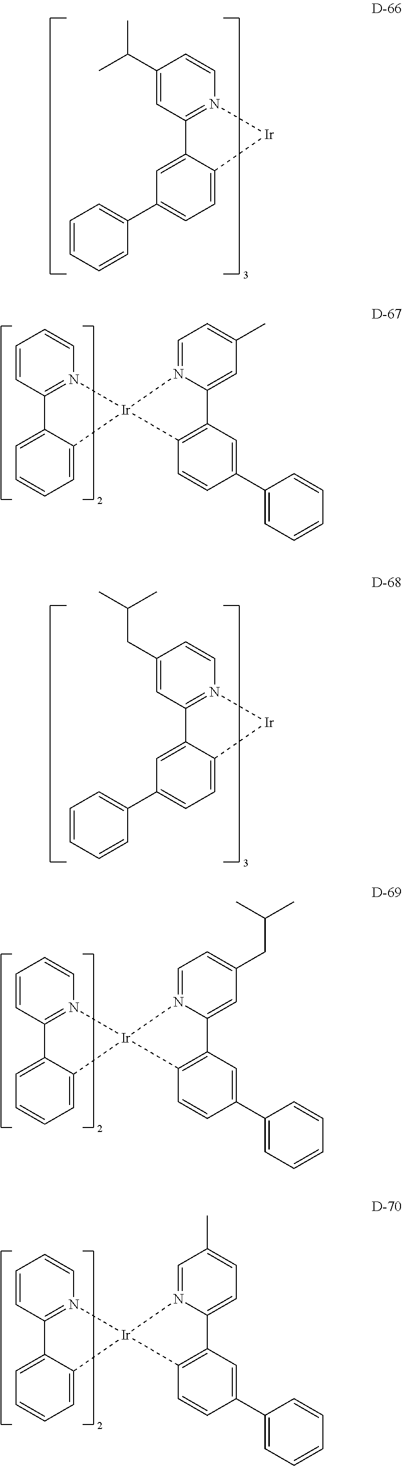

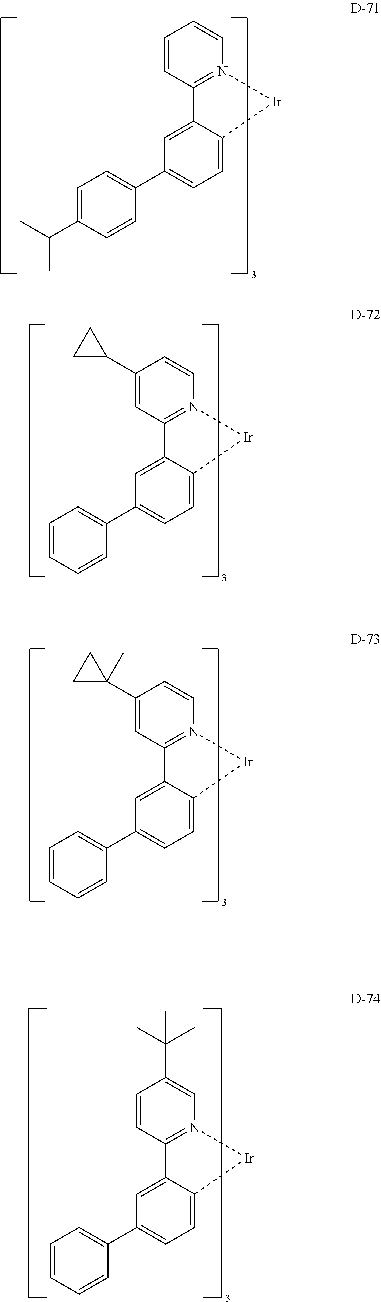

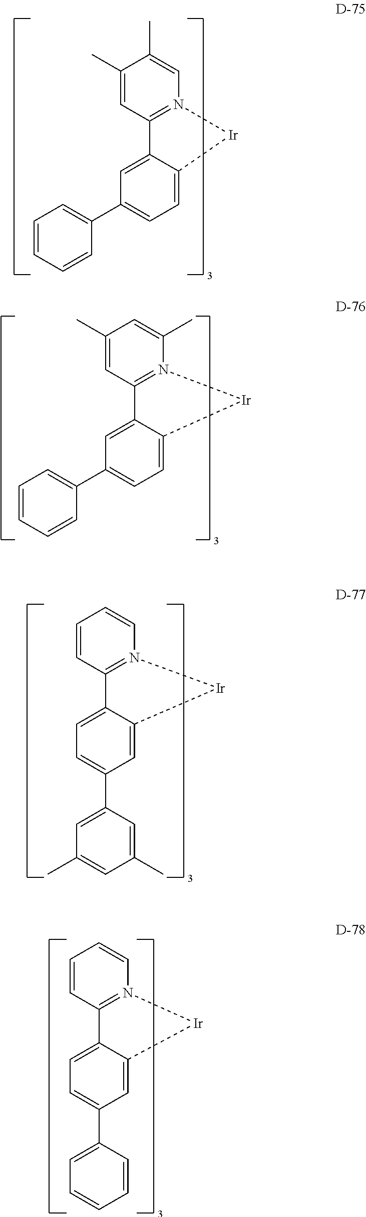

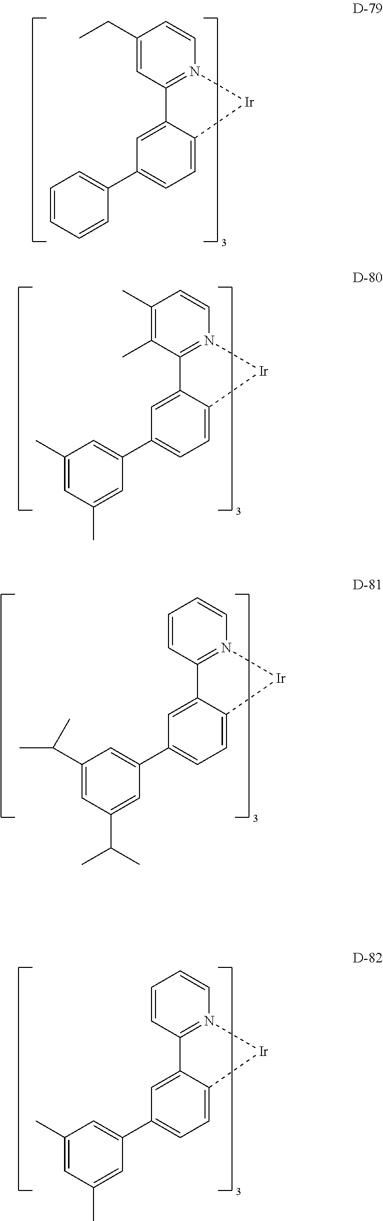

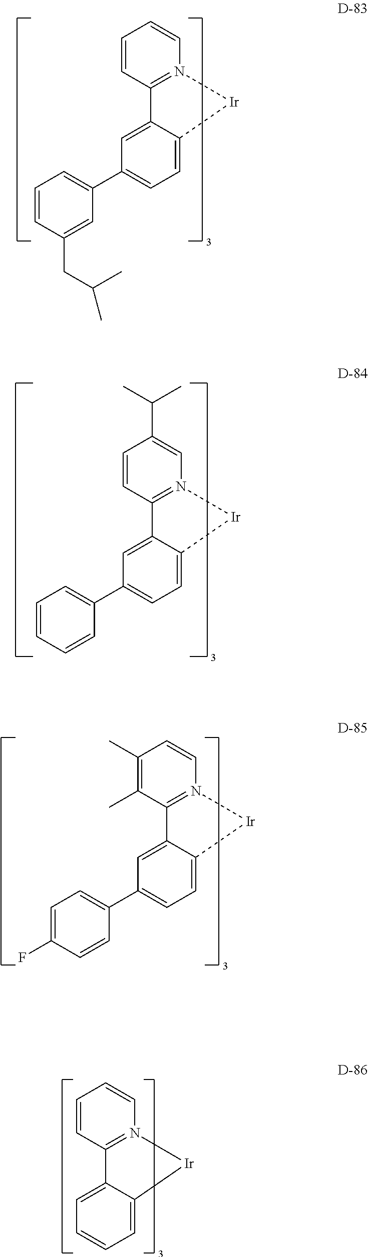

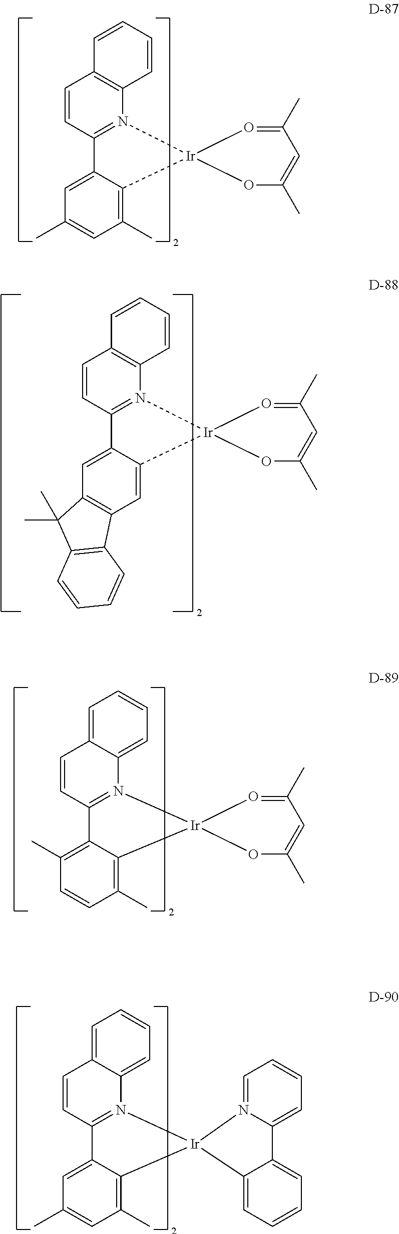

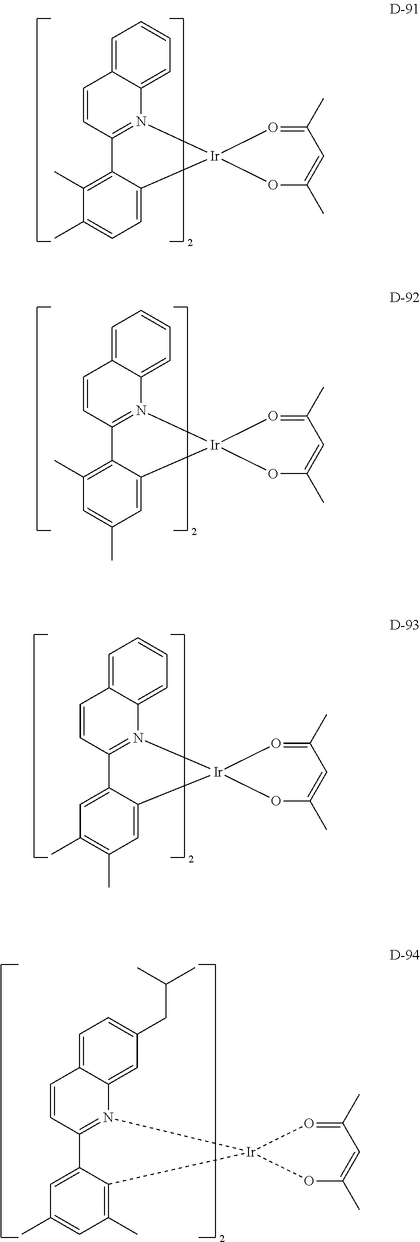

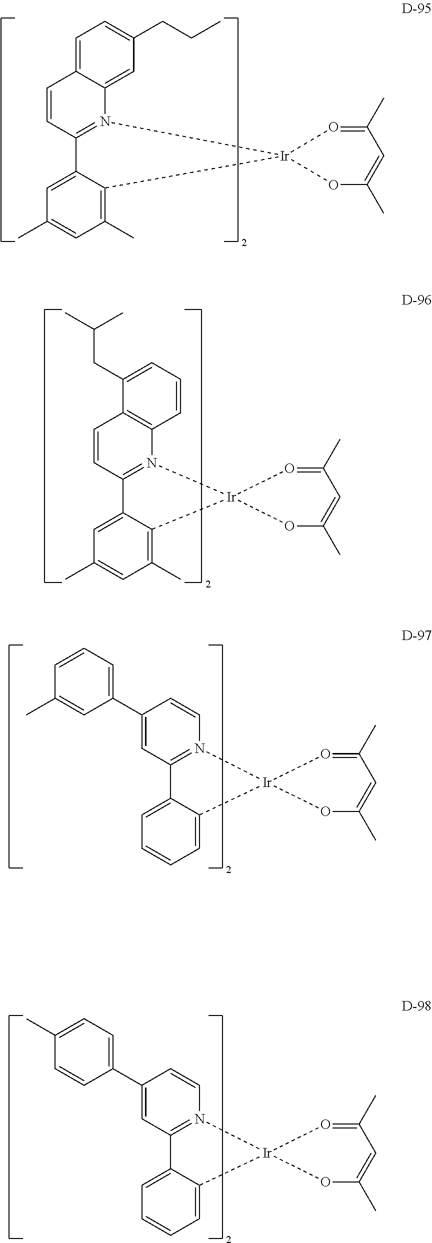

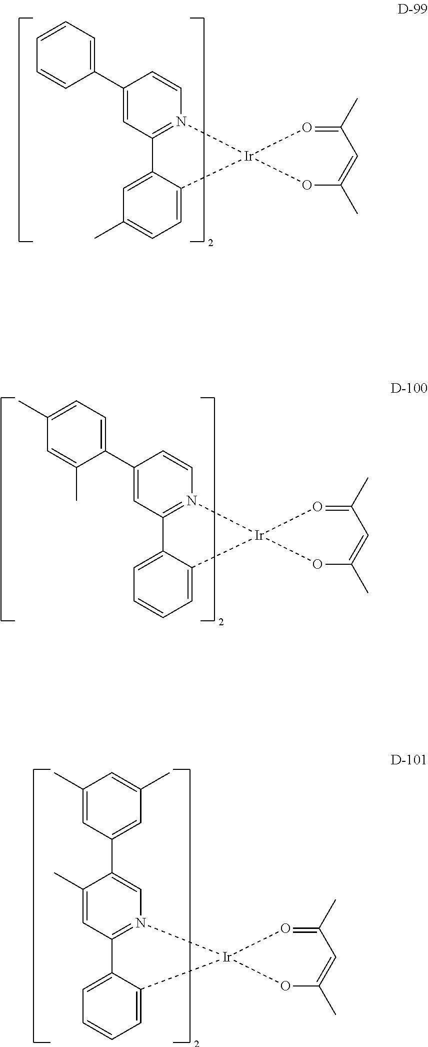

The present invention further provides the material for the organic electroluminescence device. Said material comprises a first host material and a second host material; and the first host material may comprise the organic electroluminescence compounds of the present invention. The first host material and the second host material may be in the range of 1:99 to 99:1 in a weight ratio.

Further, in the organic electroluminescence device of the present invention comprising a first electrode, a second electrode, and at least one organic layer between said first and second electrodes, said organic layer comprises a light-emitting layer, and the light-emitting layer comprises the material for the organic electroluminescence device according to the present invention and phosphorescent dopant material. The material for the organic electroluminescence device is used as a host material.

The organic electroluminescence device according to the present invention comprises the organic electroluminescence compounds represented by formula 1 and may further include at least one compound selected from the group consisting of arylamine-based compounds and styrylarylamine-based compounds.

In the organic electroluminescence device according to the present invention, the organic layer may further comprise, in addition to the organic electroluminescence compounds represented by formula 1, at least one metal selected from the group consisting of metals of Group 1, metals of Group 2, transition metals of the 4^{th} period, transition metals of the 5^{th} period, lanthanides and organic metals of d-transition elements of the Periodic Table, or at least one complex compound comprising said metal. The organic layer may comprise a light-emitting layer and a charge generating layer.

In addition, the organic electroluminescence device may emit white light by further comprising at least one light-emitting layer which comprises a blue electroluminescent compound, a red electroluminescent compound or a green electroluminescent compound, besides the organic electroluminescence compound according to the present invention.

According to the present invention, at least one layer (hereinafter, “a surface layer”) of the organic electroluminescence device preferably selected from a chalcogenide layer, a metal halide layer and a metal oxide layer, may be placed on an inner surface(s) of one or both electrode(s). Specifically, a chalcogenide (includes oxides) layer of silicon or aluminum is preferably placed on an anode surface of an electroluminescent medium layer, and a metal halide layer or metal oxide layer is placed on a cathode surface of an electroluminescent medium layer. Such a surface layer provides operation stability for the organic electroluminescence device. Preferably, said chalcogenide includes SiO_{X}(1≦X≦2), AlO_{X}(1≦X≦1.5), SiON, SiAlON, etc.; said metal halide includes LiF, MgF₂, CaF₂, a rare earth metal fluoride, etc.; and said metal oxide includes Cs₂O, Li₂O, MgO, SrO, BaO, CaO, etc.

Preferably, in the organic electroluminescence device according to the present invention, a mixed region of an electron transport compound and an reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Further, the hole transport compound is oxidized to a cation, and thus it becomes easier to inject and transport holes from the mixed region to the electroluminescent medium. Preferably, the oxidative dopant includes various Lewis acids and acceptor compounds; and the reductive dopant includes alkali metals, alkali metal compounds, alkaline earth metals, rare-earth metals, and mixtures thereof. A reductive dopant layer may be employed as a charge generating layer to prepare an electroluminescence device having two or more electroluminescent layers and emitting white light.

As for the formation of the layers constituting the organic electroluminescence device according to the present invention, dry film-forming methods, such as vacume evaporation, sputtering, plasma, ion plating methods, etc., or wet film-forming methods, such as spin coating, dipping, flow coating methods, etc., can be used.

When applying a wet film-forming method, a thin film is formed by dissolving or dispersing the material constituting each layer in suitable solvents, such as ethanol, chloroform, tetrahydrofuran, dioxane, etc. The solvents are not specifically limited.

Hereinafter, the organic electroluminescence compound, the preparation method of the compound, and the luminescent properties of the device comprising the compound of the present invention will be explained in detail with reference to the representative compounds of the present invention:

### Example 1

### Preparation of Compound C-31

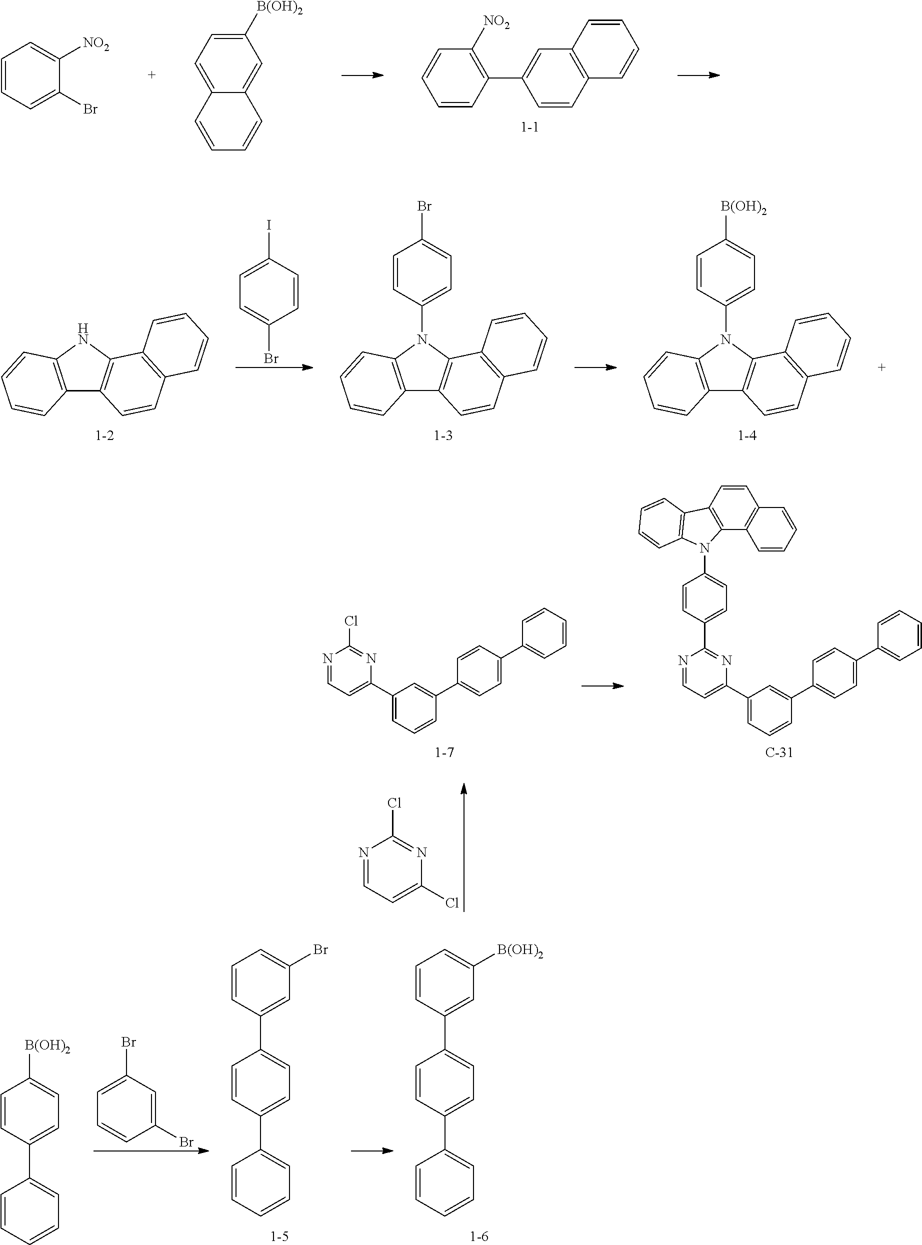

### Preparation of Compound 1-1

After adding 1-bromo-2-nitrobenzene (50.0 g, 0.247 mol), naphthalene-2-yl boronic acid (64.0 g, 0.37 mol), tetrakis(triphenylphosphine)palladium(O) [Pd(PPh₃)₄] (14.0 g, 0.012 mol), Na₂CO₃ (81.0 g, 0.60 mol), toluene (1000 mL), EtOH (500 mL) and H₂O (200 mL) to a 2000 mL round bottom flask, the reaction mixture was stirred for 12 hours at 60° C. After completing the reaction, the reaction mixture was extracted with ethyl acetate. The obtained organic layer was dried over MgSO₄ and was filtered, and the solvent was removed from the layer under the reduced pressure. The organic layer was separated through column to obtain white solid compound 1-1 (37 g, 60%).

### Preparation of Compound 1-2

After adding compound 1-1 (37 g, 0.14 mol) and triethyl phosphite [P(OEt)₃] (180 mL) to a dry 250 mL round bottom flask, the reaction mixture was stirred for 19 hours. After completing the reaction, the reaction mixture was distilled to remove P(OEt)₃, and was separated through column to obtain yellow solid compound 1-2 (17 g, 52%).

### Preparation of Compound 1-3

After adding compound 1-2 (17.4 g, 1 mol), 1-bromo-4-iodobenzene (45.3 g, 2 mol), CuI (7.63 g, 0.5 mol), ethylenediamine (EDA) (5.4 mL, 2 mol), K₂CO₃ (51 g, 3 mol) and toluene (400 mL) to a 2000 ml round bottom flask, the reaction mixture was stirred for 12 hours at 110° C. After completing the reaction, the reaction mixture was extracted with methylene chloride. The obtained organic layer was dried over MgSO₄ and was filtered, and the solvent was removed from the layer under the reduced pressure. The organic layer was separated through column to obtain white solid compound 1-3 (17.3 g, 58%).

### Preparation of Compound 1-4

After adding tetrahydrofuran (THF) (350 mL) and compound 1-3 (17.3 g, 1 mol) to a dry 3000 mL round bottom flask, the reaction mixture was stirred under N₂ and was cooled to −78° C. N-butyl lithium (n-BuLi) (28 mL, 2.5 M solution in hexane) was slowly added to the reaction mixture. The reaction mixture was stirred for one hour at −78° C., boron tri-isopropoxide [B(O-iPr)₃](21 mL, 2 mol) was slowly added to the reaction mixture at −78° C., and the reaction mixture was stirred for 12 hours at room temperature. After completing the reaction, the reaction mixture was extracted with ethyl acetate. The obtained organic layer was dried over MgSO₄ and was filtered, and the solvent was removed from the layer under the reduced pressure. The organic layer was recrystallized with methylene chloride and haxane to obtain white solid compound 1-4 (10 g, 64%).

### Preparation of Compound 1-5

After adding (1,1′-biphenyl)-4-yl boronic acid (1.3 kg, 6.5 mol), 1,3-dibromobenzene (2 L, 16.4 mol), dichlorobis(triphenylphosphine)palladium(II)[PdCl₂(PPh₃)₂] (138 g, 0.20 mol), Na₂CO₃ (1.74 kg, 16.41 mol), toluene (12 L), EtOH (2 L) and H₂O (8 L) to a 20 L round bottom flask, the reaction mixture was stirred for 12 hours at 120° C. After completing the reaction, the reaction mixture was extracted with ethyl acetate. The obtained organic layer was dried over MgSO₄ and was filtered, and the solvent was removed from the layer under the reduced pressure. The organic layer was recrystallized with ethyl acetate to obtain white solid compound 1-5 (820 g, 40%).

### Preparation of Compound 1-6

After adding THF (16 L) and compound 1-5 (820 g, 2.66 mol) to a dry 20 L round bottom flask, the reaction mixture was stirred under N₂ and was cooled to −78° C. N-BuLi (1.28 L, 2.5 M solution in hexane) was slowly added to the reaction mixture. The reaction mixture was stirred for one hour at −78° C., trimethoxyborane [B(OMe)₃](444 mL, 3.99 mol) was slowly added to the reaction mixture at −78° C., and the reaction mixture was stirred for 12 hours at room temperature. After completing the reaction, the reaction mixture was extracted with ethyl acetate. The obtained organic layer was dried over MgSO₄ and was filtered, and the solvent was removed from the layer under the reduced pressure. The organic layer was recrystallized with hexane to obtain white solid compound 1-6 (587 g, 81%).

### Preparation of Compound 1-7

After adding 2,4-dichloropyrimidine (478 g, 3.2 mol), compound 1-6 (587 g, 2.14 mol), Pd(PPh₃)₄ (99 g, 0.08 mol), Na₂CO₃ (567 g, 5.35 mol), toluene (8 L), EtOH (2.7 L) and H₂O (2.7 L) to a 20 L round bottom flask, the reaction mixture was stirred for 12 hours at 120° C. After completing the reaction, the reaction mixture was extracted and was recrystallized with dimethylformamide (DMF) to obtain compound 1-7 (535 g, 73%).

### Preparation of Compound C-31

After adding compound 1-7 (9.8 g, 0.028 mol), compound 1-4 (8 g, 0.024 mol), Pd(PPh₃)₄ (1.37 g, 0.001 mol), K₂CO₃ (9.83 g, 0.07 mol), toluene (120 mL), EtOH (30 mL) and H₂O (36 mL) to a 500 mL round bottom flask, the reaction mixture was stirred for 12 hours at 120° C. After completing the reaction, the reaction mixture was recrystallized with hexane to obtain compound C-31 (4.5 g, 26%).

MS/FAB found 599.72; calculated 599.24

### Device Example 1

### Production of an OLED Device Using the Organic Electroluminescence Compound According to the Present Invention

An OLED device was produced using the compound according to the present invention. A transparent electrode indium tin oxide (ITO) thin film (15 Ω/sq) on a glass substrate for an organic light-emitting diode (OLED) device (Samsung Corning, Republic of Korea) was subjected to an ultrasonic washing with trichloroethylene, acetone, ethanol and distilled water, sequentially, and then was stored in isopropanol. Then, the ITO substrate was mounted on a substrate holder of a vacuum vapor depositing apparatus. N⁴,N⁴-bis(4-naphthalen-2-y(N-phenyl)annino)phenyl)-N¹-(naphthalen-2-yl)-N¹-phenylbenzene-1,4-diamine was introduced into a cell of said vacuum vapor depositing apparatus, and then the pressure in the chamber of said apparatus was controlled to 10⁻⁶ torr. Thereafter, an electric current was applied to the cell to evaporate the above introduced material, thereby forming a hole injection layer having a thickness of 60 nm on the ITO substrate. Then, N,N′-di(4-biphenyl)-N,N′-di(4-biphenyl)-4,4′-diaminobiphenyl was introduced into another cell of said vacuum vapor depositing apparatus, and was evaporated by applying electric current to the cell, thereby forming a hole transport layer having a thickness of 20 nm on the hole injection layer. The hole injection layer and the hole transport layer were formed, and then a light-emitting layer was vapor deposited thereon. Thereafter, compound C-31 was introduced into one cell of the vacuum vapor depositing apparatus, as a host material, and compound D-1 was introduced into another cell as a dopant. The two materials were evaporated at different rates and deposited in a doping amount of 15 wt % of the dopant, based on the total weight of the host and dopant, to form a light-emitting layer having a thickness of 30 nm on the hole transport layer. Then, 2-(4-(9,10-di(naphthalen-2-yl)anthracen-2-yl)phenyl)-1-phenyl-1H-benzo[d]imidazole was introduced into one cell and lithium quinolate (Liq) was introduced into another cell. The two materials were evaporated at the same rate and were respectively deposited in a doping amount of 50 wt % to form an electron transport layer having a thickness of 30 nm on the light-emitting layer. Then, after depositing lithium quinolate as an electron injection layer having a thickness of 2 nm on the electron transport layer, an Al cathode having a thickness of 150 nm was deposited by another vacuum vapor deposition apparatus on the electron injection layer. Thus, an OLED device was produced. All the materials used for producing the OLED device were purified by vacuum sublimation at 10⁻⁶ torr prior to use.

The produced OLED device showed green emission having a luminance of 1000 cd/m² and a current density of 2.38 mA/cm² at a driving voltage of 3.3 V.

### Device Example 2

### Production of an OLED Device Using the Organic Electroluminescence Compound According to the Present Invention

An OLED device was produced in the same manner as in Device Example 1, except for using compound C-31 as a host material and compound D-28 as a dopant.

The produced OLED device showed orange emission having a luminance of 1000 cd/m² and a current density of 2.44 mA/cm² at a driving voltage of 3.5 V.

### Comparative Example 1

### Production of an OLED Device Using Conventional Electroluminescence Compounds

An OLED device was produced in the same manner as in Device Example 1, except that a light-emitting layer having a thickness of 30 nm was deposited on the hole transport layer by using 4,4′-N,N′-dicarbazol-biphenyl (CBP) as a host material and compound D-1 as a dopant, and a hole blocking layer having a thickness of 10 nm was deposited by using bis(2-methyl-8-quinolinato)(4-phenylphenolato)aluminum(III) (Balq).

The produced OLED device showed green emission having a luminance of 1000 cd/m² and a current density of 2.86 mA/cm² at a driving voltage of 4.9 V.

### Comparative Example 2

### Production of an OLED Device Using Conventional Electroluminescence Compounds

An OLED device was produced in the same manner as in Device Example 1, except that a light-emitting layer having a thickness of 30 nm was deposited on the hole transport layer by using 4,4′-bis(carbazol-9-yl)biphenyl (CBP) as a host material and compound D-28 as a dopant, and a hole blocking layer having a thickness of 10 nm was deposited by using bis(2-methyl-8-quinolinato)(4-phenylphenolato)aluminum(III) (Balq).

The produced OLED device showed orange emission having a luminance of 1000 cd/m² and a current density of 3.04 mA/cm² at a driving voltage of 4.6 V.

The organic electroluminescence compounds of the present invention have a superior luminous efficacy over conventional materials. In addition, an organic electroluminescence device using the organic electroluminescence compounds of the present invention as a host material has high power efficiency due to low driving voltage and improved power consumption.

1. An organic electroluminescence compound represented by the following formula 1: 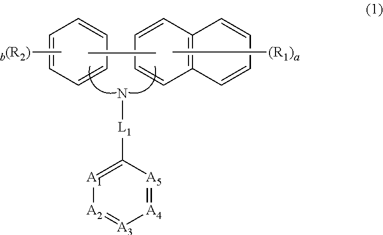
wherein
L₁ represents a single bond, a substituted or unsubstituted (C6-C30)arylene group, or a substituted or unsubstituted 3- to 30-membered heteroarylene group;
Ar₁ to Ar₅ each independently represent CR₁₀, C-L₂-(L₃)ₘ-Ar₁ or N, proviso that at least one of Ar₁ to Ar₅ represents C-L₂-(L₃)ₘ-Ar₁;
L₂ and L₃ each independently represent a substituted or unsubstituted (C6-C30)arylene group, or a substituted or unsubstituted 3- to 30-membered heteroarylene group,
R₁, R₂, R₁₀, and Ar₁ each independently represent hydrogen, deuterium, a halogen, a substituted or unsubstituted (C1-C30)alkyl group, a substituted or unsubstituted (C3-C30)cycloalkyl group, a substituted or unsubstituted 5- to 7-membered heterocycloalkyl group, a substituted or unsubstituted (C2-C30)alkenyl group, a substituted or unsubstituted (C2-C30)alkynyl group, a substituted or unsubstituted (C6-C30)aryl group, a substituted or unsubstituted 3- to 30-membered heteroaryl group, —NR₁₁R₁₂, —SiR₁₃R₁₄R₁₅, —SR₁₆, —OR₁₇, a cyano group or a nitro group;
R₁₁ to R₁₇ each independently represent hydrogen, deuterium, a halogen, a substituted or unsubstituted (C1-C30)alkyl group, a substituted or unsubstituted (C6-C30)aryl group, or a substituted or unsubstituted 3- to 30-membered heteroaryl group;
a represents an integer of 1 to 6; where a is an integer of 2 or more, each of R₁ is the same or different;
b represents an integer of 1 to 4; where b is an integer of 2 or more, each of R₂ is the same or different;
m represents an integer of 1 or 2; where m is an integer of 2 or more, each of L₃ is the same or different;
the heteroarylene group, the heterocycloalkyl group and the heteroaryl group contain at least one hetero atom selected from the group consisting of B, N, O, S, P(═O), Si and P;
proviso that R₂ is not 2-carbazole group or 3-carbazole group.

2. The organic electroluminescence compound according to claim 1, which is selected from the group consisting of following formulae 2 to 4: 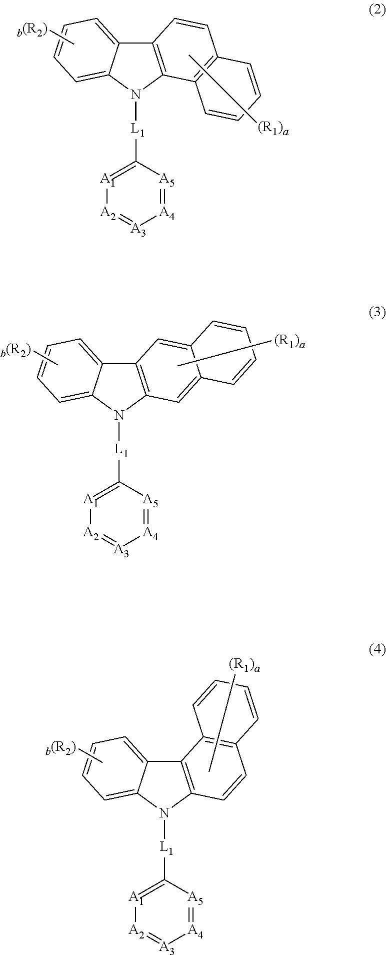
wherein
R₁, R₂, a, b, L₁ and A₁ to A₅ are as defined in claim 1.

3. The organic electroluminescence compound according to claim 1, wherein the substituents of the substituted alkyl group, the substituted alkenyl group, the substituted alkynyl group, the substituted aryl(ene) group, the substituted heteroaryl(ene) group, the substituted cycloalkyl(ene) group and the substituted heterocycloalkyl group in L₁, L₂, L₃, R₁, R₂, R₁₀, Ar₁ and R₁₁ to R₁₇ groups of formula 1, each independently are at least one selected from the group consisting of deuterium; a halogen; a (C1-C30)alkyl group; a halo(C1-C30)alkyl group; a (C1-C30)alkoxy group; a (C6-C30)aryloxy group; a (C6-C30)aryl group; a 3- to 30-membered heteroaryl group; a 3- to 30-membered heteroaryl group substituted with a (C6-C30)aryl group; a 3- to 30-membered heteroaryl group substituted with a (C1-C30)alkyl and a (C6-C30)aryl; a (C3-C30)cycloalkyl group; a 5- to 7-membered heterocycloalkyl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a (C2-C30)alkenyl group; a (C2-C30)alkynyl group; a cyano group; a (C1-C30)alkylthio group; a (C6-C30)arylthio group; an N-carbazolyl group; a mono- or di(C1-C30)alkylamino group; a mono- or di(C6-C30)arylamino group; a (C1-C30)alkyl(C6-C30)arylamino group; a di(C6-C30)arylboronyl group; a di(C1-C30)alkylboronyl group; a (C1-C30)alkyl(C6-C30)arylboronyl group; a (C6-C30)aryl(C1-C30)alkyl group; a (C1-C30)alkyl(C6-C30)aryl group; a carboxyl group; a nitro group; and a hydroxyl group.

4. The organic electroluminescence compound according to claim 1, wherein L₁ is a single bond or a (C6-C30)arylene group; and 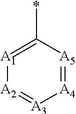
is selected from the following groups: 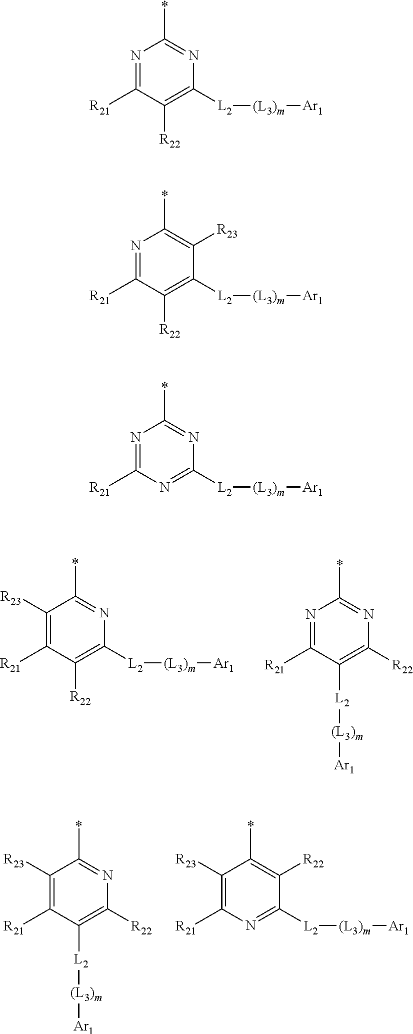
wherein
L₂ and L₃ each independently represent a (C6-C30)arylene group or a 3- to 30-membered heteroarylene group;
R₁ and R₂ each independently represent hydrogen, deuterium, a halogen, a (C1-C30)alkyl group, a (C6-C30)aryl group or a 3- to 30-membered heteroaryl group;
R₁₀ and Ar₁ each independently represent hydrogen, deuterium, a halogen, a (C1-C30)alkyl group, a (C3-C30)cycloalkyl group, a (C6-C30)aryl group, a 3- to 30-membered heteroaryl group or —SiR₁₃R₁₄R₁₅;
R₁₃ to R₁₅ each independently represent a (C1-C30)alkyl group or a (C6-C30)aryl group;
a represents an integer of 0 to 6;
b represents an integer of 0 to 4;
m represents an integer of 1 or 2; and
the arylene group in L₁, the arylene and heteroarylene groups in L₂ and L₃, the alkyl, aryl and heteroaryl groups in R₁ and R₂, the alkyl, cycloalkyl, aryl and heteroaryl groups in R₁₀ and Ar₁, and the alkyl and aryl groups in R₁₃ to R₁₅ each independently can be further substituted with at least one selected from the group consisting of deuterium, a halogen, a (C1-C30)alkyl group, a halo(C1-C30)alkyl group, a (C1-C30)alkoxy group, a (C6-C30)aryloxy group, a (C6-C30)aryl group, a 3- to 30-membered heteroaryl group; a 3- to 30-membered heteroaryl group substituted with a (C6-C30)aryl group; a 3- to 30-membered heteroaryl group substituted with a (C6-C30)aryl group and a (C1-C30)alkyl group; a (C3-C30)cycloalkyl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a cyano group; a (C1-C30)alkylthio group; a (C6-C30)arylthio group; a (C6-C30)aryl(C1-C30)alkyl group; and a (C1-C30)alkyl(C6-C30)aryl group.

5. The organic electroluminescence compound according to claim 1, wherein L₂ represents phenylene, pyridinylene, fluorenylene, carbazolylene, dibenzofuranylene or dibenzothiophenylene; L₃ represents phenylene, biphenylene, terphenylene, naphthylene, pyridinylene, pyrimidinylene, fluorenylene, dibenzofuranylene, dibenzothiophenylene, carbazolylene, 5H-pyrido[3,2-b]indolylene or 5H-indeno[1,2-b]pyridinylene; Ar₁ represents hydrogen, a halogen, a (C1-C30)alkyl group, a (C3-C30)cycloalkyl group, a (C6-C30)aryl group, a 3- to 30-membered heteroaryl group or —SiR₁₃R₁₄R₁₅; R₁₀ represents hydrogen or a (C6-C30)aryl group; R₁ and R₂ each independently represent hydrogen, a halogen, a (C1-C30)alkyl group, a (C6-C30)aryl group or a 3- to 30-membered heteroaryl group; the phenylene, pyridinylene, fluorenylene, carbazolylene, dibenzofuranylene and dibenzothiophenylene in L₂, the phenylene, biphenylene, terphenylene, naphthylene, pyridinylene, pyrimidinylene, fluorenylene, dibenzofuranylene, dibenzothiophenylene, carbazolylene, 5H-pyrido[3,2-b]indolylene and 5H-indeno[1,2-b]pyridinylene in L₃, the alkyl, cycloalkyl, aryl and heteroaryl in Ar₁, the aryl in R₁₀, and the alkyl, aryl and heteroaryl in R₁ and R₂ each independently can be further substituted with at least one selected from the group consisting of deuterium, a halogen, a (C1-C30)alkyl group, a halo(C1-C30)alkyl group, a (C1-C30)alkoxy group, a (C6-C30)aryloxy group, a (C6-C30)aryl group, a 3- to 30-membered heteroaryl group; a 3- to 30-membered heteroaryl group substituted with a (C6-C30)aryl group; a (C1-C30)alkylthio group; a (C6-C30)arylthio group; a (C6-C30)aryl(C1-C30)alkyl group; and a (C1-C30)alkyl(C6-C30)aryl group.

6. The organic electroluminescence compound according to claim 1, wherein the compound represented by formula 1 is selected from the group consisting of:

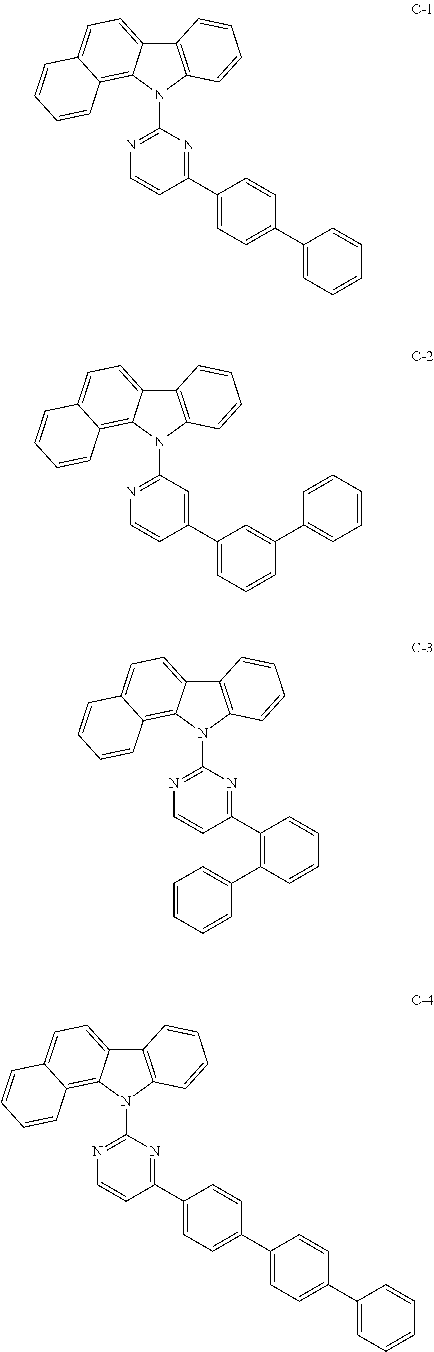 [SMILES: c1ccc(-c2ccc(-c3ccnc(-n4c5ccccc5c5ccc6ccccc6c54)n3)cc2)cc1 ; c1ccc(-c2cccc(-c3ccnc(-n4c5ccccc5c5ccc6ccccc6c54)c3)c2)cc1 ; c1ccc(-c2ccccc2-c2ccnc(-n3c4ccccc4c4ccc5ccccc5c43)n2)cc1 ; c1ccc(-c2ccc(-c3ccc(-c4ccnc(-n5c6ccccc6c6ccc7ccccc7c65)n4)cc3)cc2)cc1]

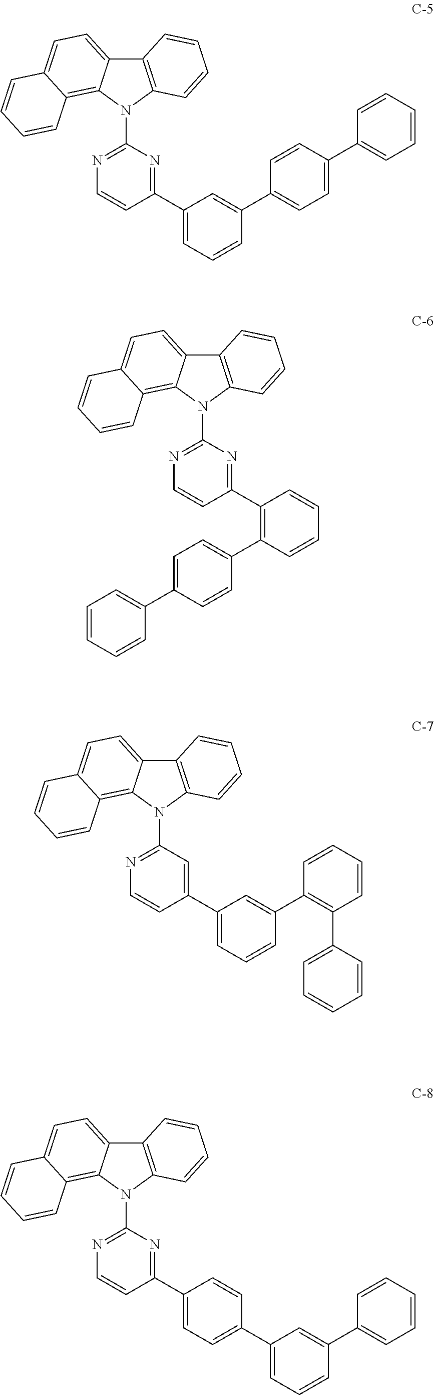 [SMILES: c1ccc(-c2ccc(-c3cccc(-c4ccnc(-n5c6ccccc6c6ccc7ccccc7c65)n4)c3)cc2)cc1 ; c1ccc(-c2ccc(-c3ccccc3-c3ccnc(-n4c5ccccc5c5ccc6ccccc6c54)n3)cc2)cc1 ; c1ccc(-c2ccccc2-c2cccc(-c3ccnc(-n4c5ccccc5c5ccc6ccccc6c54)c3)c2)cc1 ; c1ccc(-c2cccc(-c3ccc(-c4ccnc(-n5c6ccccc6c6ccc7ccccc7c65)n4)cc3)c2)cc1]

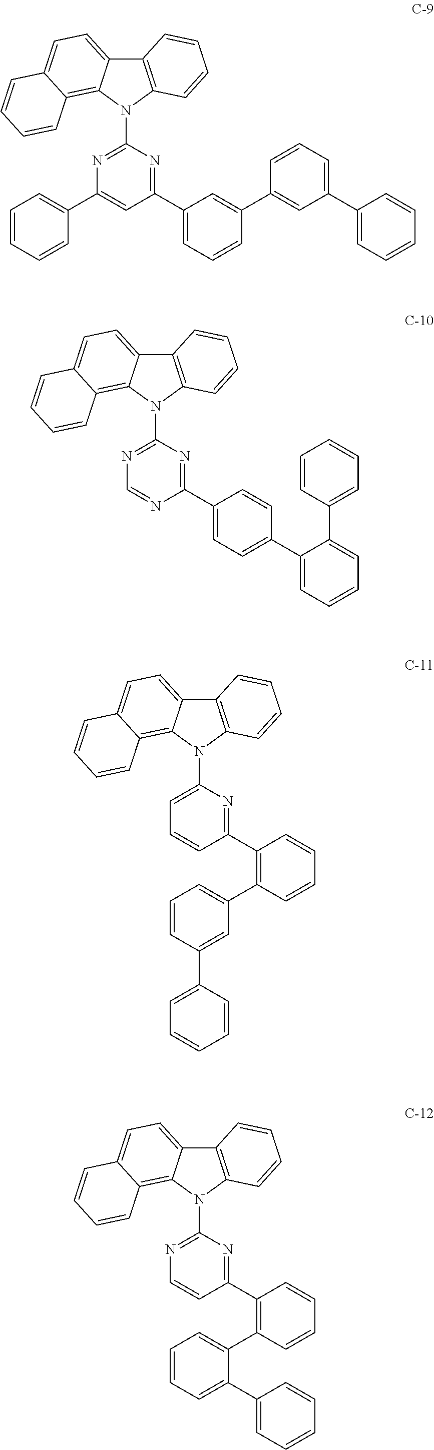 [SMILES: c1ccc(-c2cccc(-c3cccc(-c4cc(-c5ccccc5)nc(-n5c6ccccc6c6ccc7ccccc7c65)n4)c3)c2)cc1 ; c1ccc(-c2ccccc2-c2ccc(-c3ncnc(-n4c5ccccc5c5ccc6ccccc6c54)n3)cc2)cc1 ; c1ccc(-c2cccc(-c3ccccc3-c3cccc(-n4c5ccccc5c5ccc6ccccc6c54)n3)c2)cc1 ; c1ccc(-c2ccccc2-c2ccccc2-c2ccnc(-n3c4ccccc4c4ccc5ccccc5c43)n2)cc1]

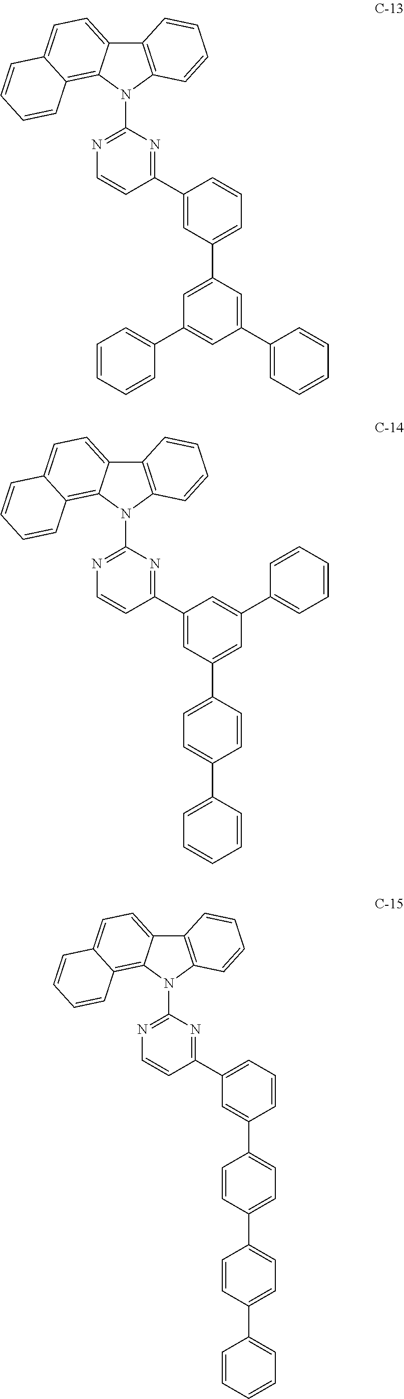 [SMILES: c1ccc(-c2cc(-c3ccccc3)cc(-c3cccc(-c4ccnc(-n5c6ccccc6c6ccc7ccccc7c65)n4)c3)c2)cc1 ; c1ccc(-c2ccc(-c3cc(-c4ccccc4)cc(-c4ccnc(-n5c6ccccc6c6ccc7ccccc7c65)n4)c3)cc2)cc1 ; c1ccc(-c2ccc(-c3ccc(-c4cccc(-c5ccnc(-n6c7ccccc7c7ccc8ccccc8c76)n5)c4)cc3)cc2)cc1]

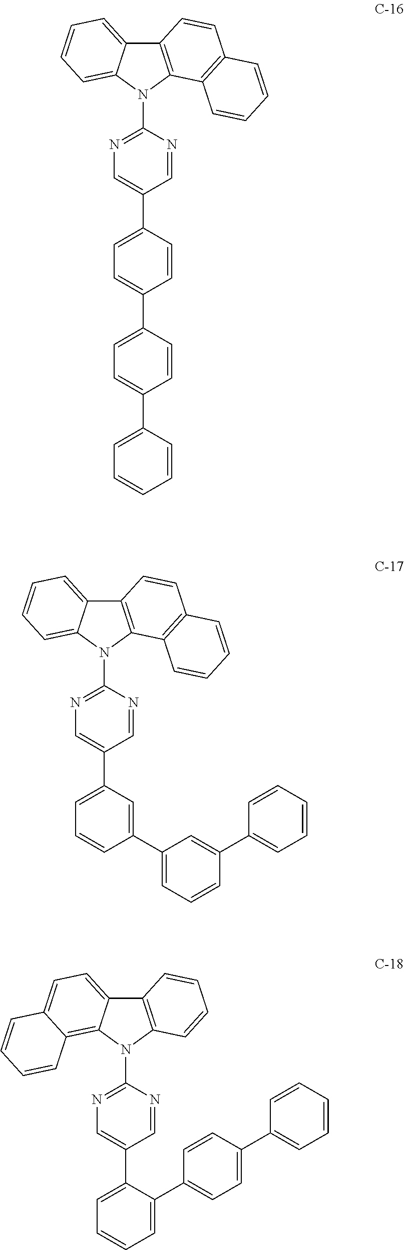 [SMILES: c1ccc(-c2ccc(-c3ccc(-c4cnc(-n5c6ccccc6c6ccc7ccccc7c65)nc4)cc3)cc2)cc1 ; c1ccc(-c2cccc(-c3cccc(-c4cnc(-n5c6ccccc6c6ccc7ccccc7c65)nc4)c3)c2)cc1 ; c1ccc(-c2ccc(-c3ccccc3-c3cnc(-n4c5ccccc5c5ccc6ccccc6c54)nc3)cc2)cc1]

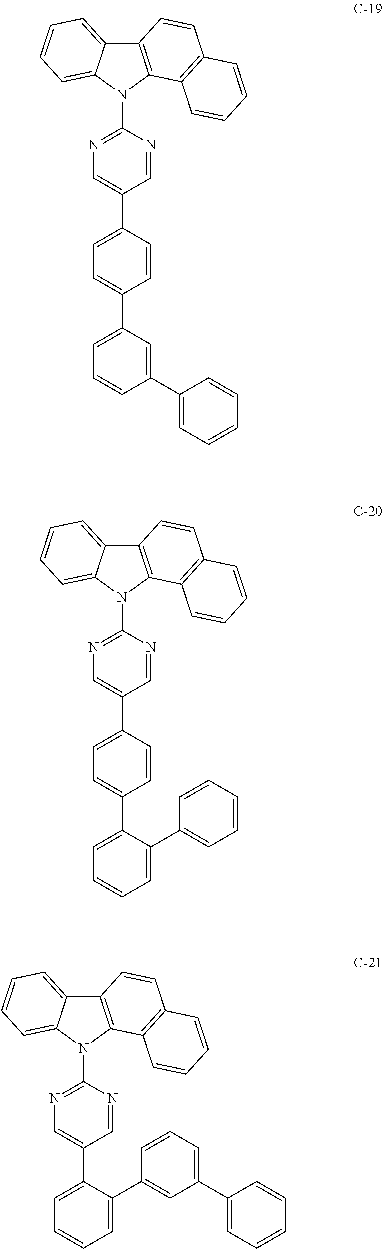 [SMILES: c1ccc(-c2cccc(-c3ccc(-c4cnc(-n5c6ccccc6c6ccc7ccccc7c65)nc4)cc3)c2)cc1 ; c1ccc(-c2ccccc2-c2ccc(-c3cnc(-n4c5ccccc5c5ccc6ccccc6c54)nc3)cc2)cc1 ; c1ccc(-c2cccc(-c3ccccc3-c3cnc(-n4c5ccccc5c5ccc6ccccc6c54)nc3)c2)cc1]

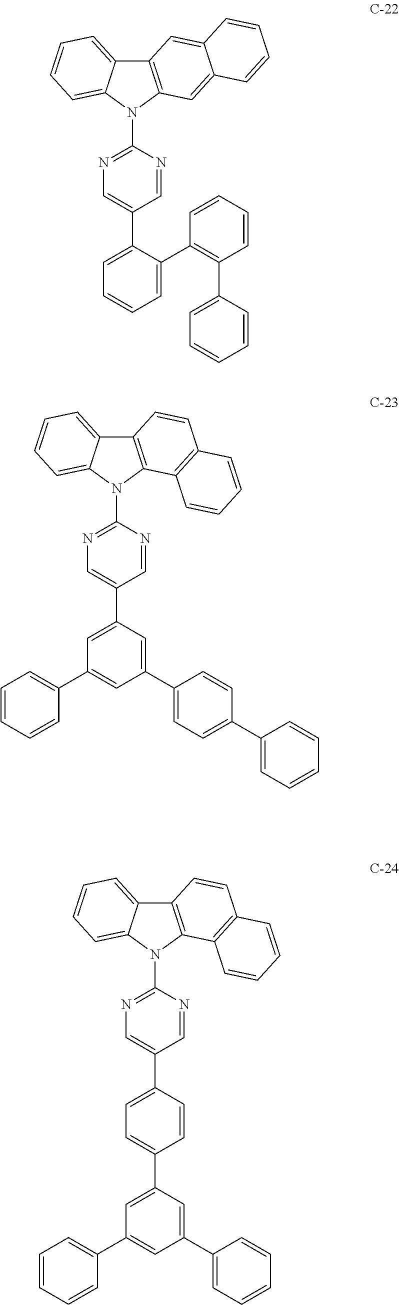 [SMILES: c1ccc(-c2ccccc2-c2ccccc2-c2cnc(-n3c4ccccc4c4cc5ccccc5cc43)nc2)cc1 ; c1ccc(-c2ccc(-c3cc(-c4ccccc4)cc(-c4cnc(-n5c6ccccc6c6ccc7ccccc7c65)nc4)c3)cc2)cc1 ; c1ccc(-c2cc(-c3ccccc3)cc(-c3ccc(-c4cnc(-n5c6ccccc6c6ccc7ccccc7c65)nc4)cc3)c2)cc1]

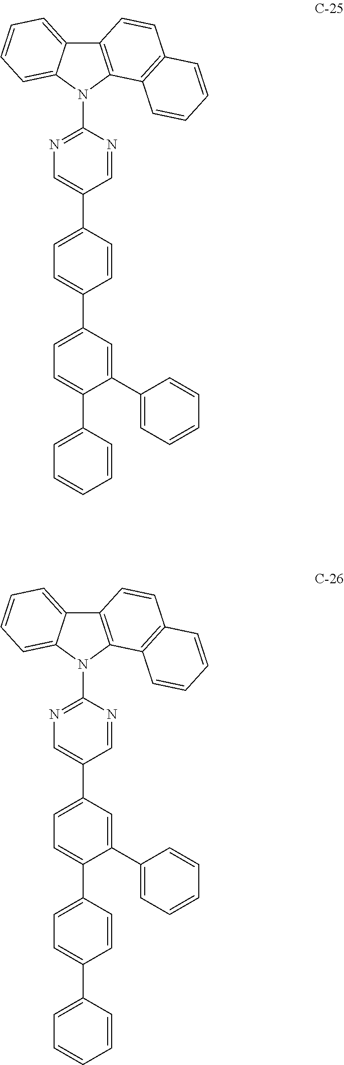 [SMILES: c1ccc(-c2ccc(-c3ccc(-c4cnc(-n5c6ccccc6c6ccc7ccccc7c65)nc4)cc3)cc2-c2ccccc2)cc1 ; c1ccc(-c2ccc(-c3ccc(-c4cnc(-n5c6ccccc6c6ccc7ccccc7c65)nc4)cc3-c3ccccc3)cc2)cc1]

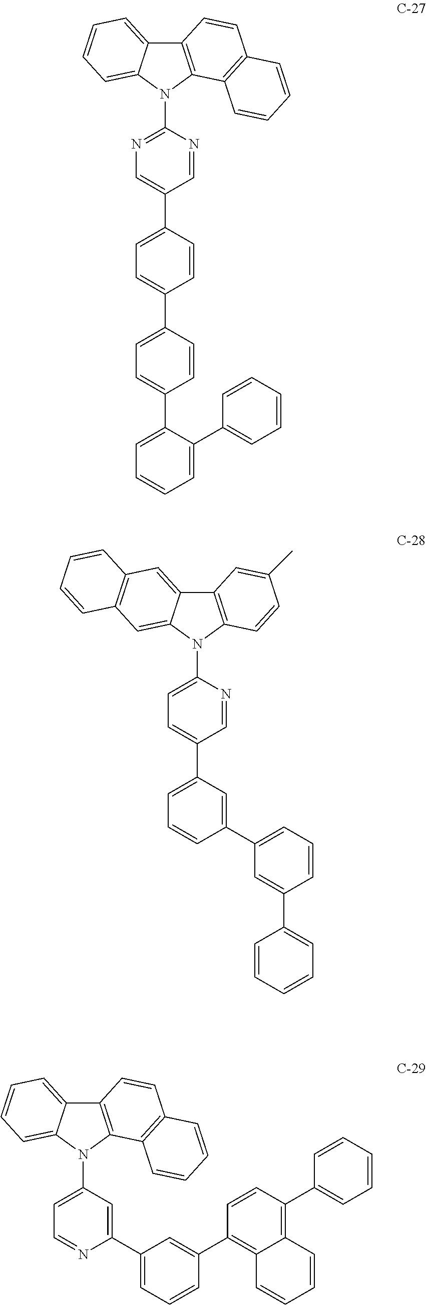 [SMILES: c1ccc(-c2ccccc2-c2ccc(-c3ccc(-c4cnc(-n5c6ccccc6c6ccc7ccccc7c65)nc4)cc3)cc2)cc1 ; Cc1ccc2c(c1)c1cc3ccccc3cc1n2-c1ccc(-c2cccc(-c3cccc(-c4ccccc4)c3)c2)cn1 ; c1ccc(-c2ccc(-c3cccc(-c4cc(-n5c6ccccc6c6ccc7ccccc7c65)ccn4)c3)c3ccccc23)cc1]

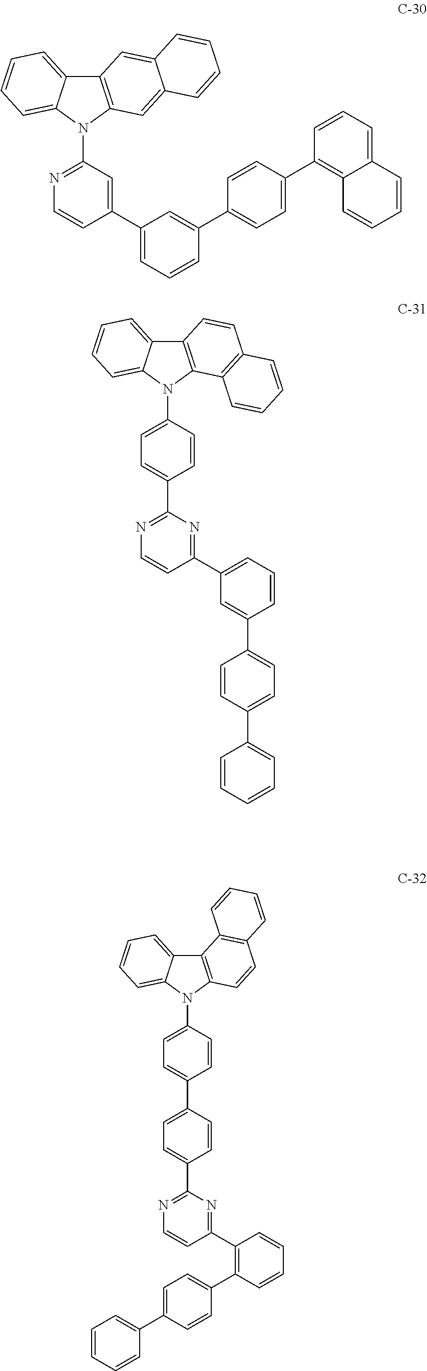 [SMILES: c1cc(-c2ccc(-c3cccc4ccccc34)cc2)cc(-c2ccnc(-n3c4ccccc4c4cc5ccccc5cc43)c2)c1 ; c1ccc(-c2ccc(-c3cccc(-c4ccnc(-c5ccc(-n6c7ccccc7c7ccc8ccccc8c76)cc5)n4)c3)cc2)cc1 ; c1ccc(-c2ccc(-c3ccccc3-c3ccnc(-c4ccc(-c5ccc(-n6c7ccccc7c7c8ccccc8ccc76)cc5)cc4)n3)cc2)cc1]

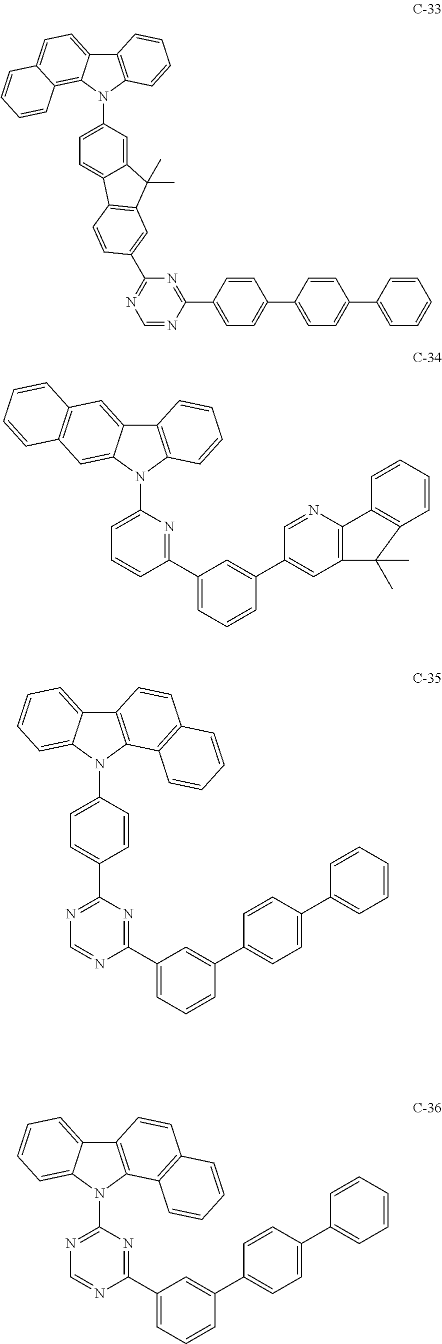 [SMILES: CC1(C)c2cc(-c3ncnc(-c4ccc(-c5ccc(-c6ccccc6)cc5)cc4)n3)ccc2-c2ccc(-n3c4ccccc4c4ccc5ccccc5c43)cc21 ; CC1(C)c2ccccc2-c2ncc(-c3cccc(-c4cccc(-n5c6ccccc6c6cc7ccccc7cc65)n4)c3)cc21 ; c1ccc(-c2ccc(-c3cccc(-c4ncnc(-c5ccc(-n6c7ccccc7c7ccc8ccccc8c76)cc5)n4)c3)cc2)cc1 ; c1ccc(-c2ccc(-c3cccc(-c4ncnc(-n5c6ccccc6c6ccc7ccccc7c65)n4)c3)cc2)cc1]

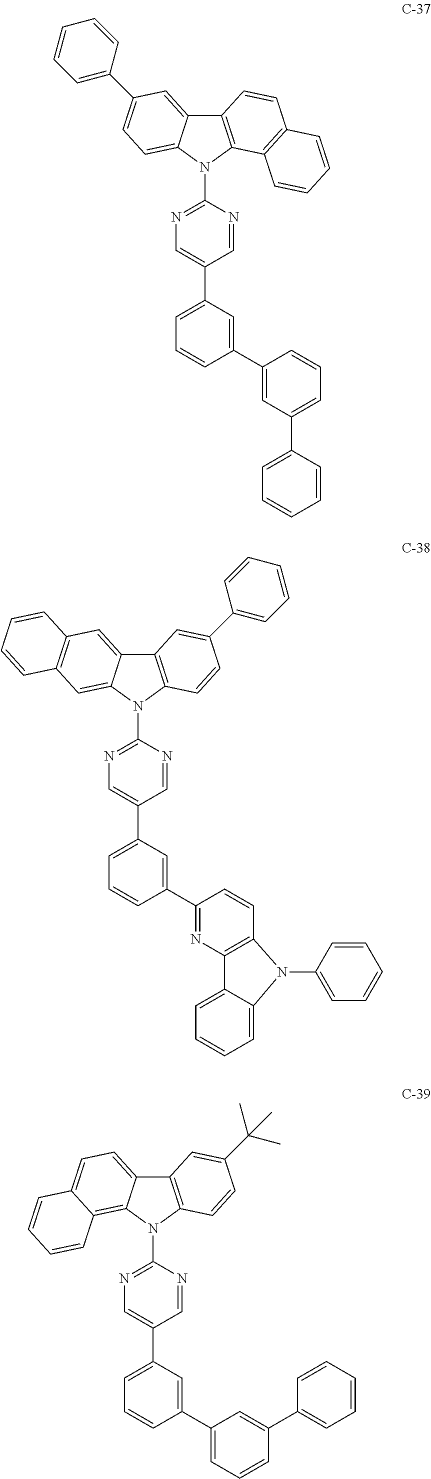 [SMILES: c1ccc(-c2cccc(-c3cccc(-c4cnc(-n5c6ccc(-c7ccccc7)cc6c6ccc7ccccc7c65)nc4)c3)c2)cc1 ; c1ccc(-c2ccc3c(c2)c2cc4ccccc4cc2n3-c2ncc(-c3cccc(-c4ccc5c(n4)c4ccccc4n5-c4ccccc4)c3)cn2)cc1 ; CC(C)(C)c1ccc2c(c1)c1ccc3ccccc3c1n2-c1ncc(-c2cccc(-c3cccc(-c4ccccc4)c3)c2)cn1]

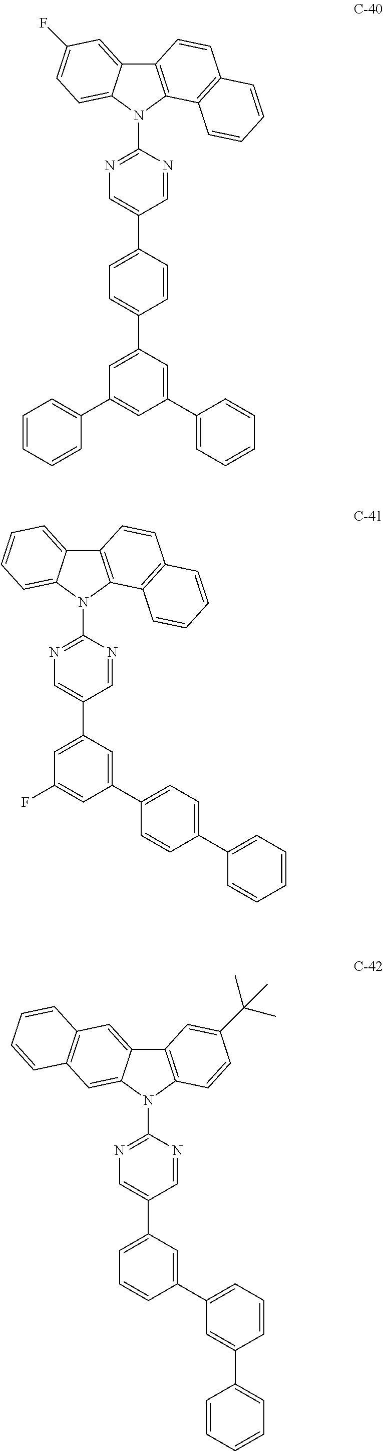 [SMILES: Fc1ccc2c(c1)c1ccc3ccccc3c1n2-c1ncc(-c2ccc(-c3cc(-c4ccccc4)cc(-c4ccccc4)c3)cc2)cn1 ; Fc1cc(-c2ccc(-c3ccccc3)cc2)cc(-c2cnc(-n3c4ccccc4c4ccc5ccccc5c43)nc2)c1 ; CC(C)(C)c1ccc2c(c1)c1cc3ccccc3cc1n2-c1ncc(-c2cccc(-c3cccc(-c4ccccc4)c3)c2)cn1]

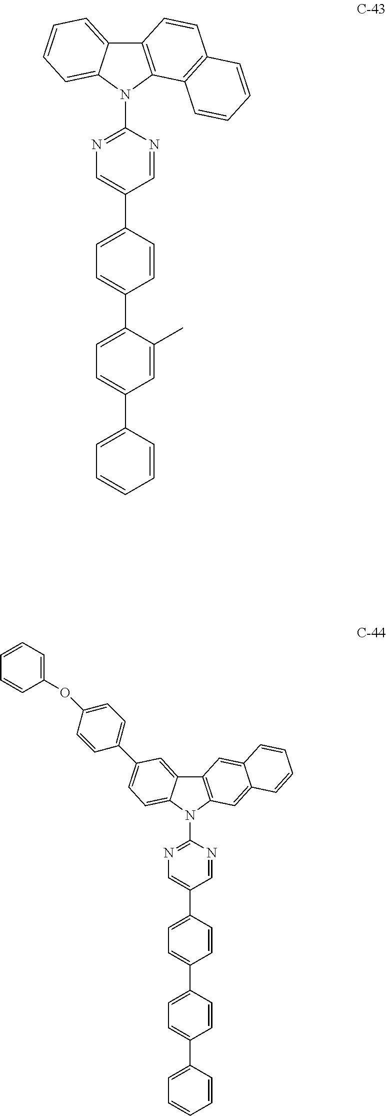 [SMILES: Cc1cc(-c2ccccc2)ccc1-c1ccc(-c2cnc(-n3c4ccccc4c4ccc5ccccc5c43)nc2)cc1 ; c1ccc(Oc2ccc(-c3ccc4c(c3)c3cc5ccccc5cc3n4-c3ncc(-c4ccc(-c5ccc(-c6ccccc6)cc5)cc4)cn3)cc2)cc1]

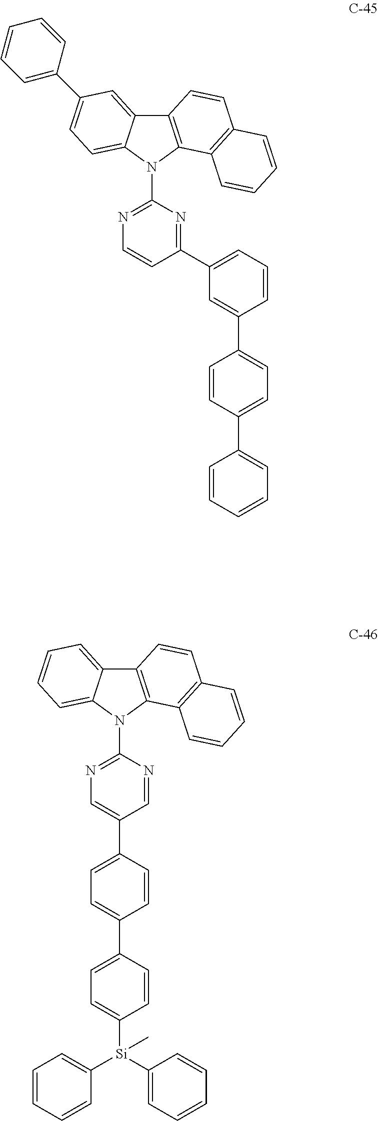 [SMILES: c1ccc(-c2ccc(-c3cccc(-c4ccnc(-n5c6ccc(-c7ccccc7)cc6c6ccc7ccccc7c65)n4)c3)cc2)cc1 ; C[Si](c1ccccc1)(c1ccccc1)c1ccc(-c2ccc(-c3cnc(-n4c5ccccc5c5ccc6ccccc6c54)nc3)cc2)cc1]

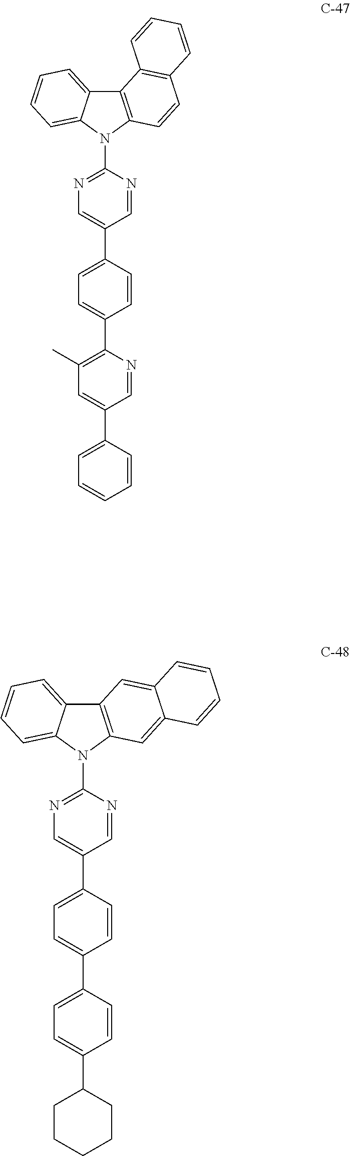 [SMILES: Cc1cc(-c2ccccc2)cnc1-c1ccc(-c2cnc(-n3c4ccccc4c4c5ccccc5ccc43)nc2)cc1 ; c1ccc2cc3c(cc2c1)c1ccccc1n3-c1ncc(-c2ccc(-c3ccc(C4CCCCC4)cc3)cc2)cn1]

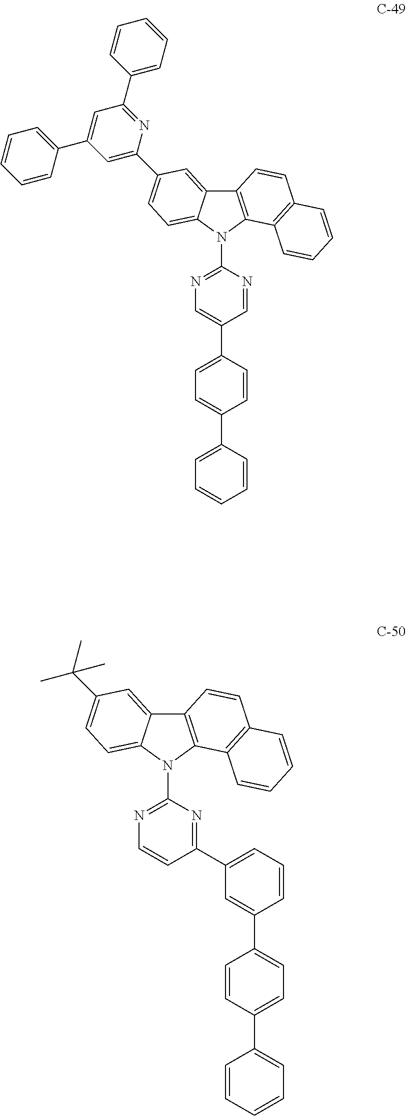 [SMILES: c1ccc(-c2ccc(-c3cnc(-n4c5ccc(-c6cc(-c7ccccc7)cc(-c7ccccc7)n6)cc5c5ccc6ccccc6c54)nc3)cc2)cc1 ; CC(C)(C)c1ccc2c(c1)c1ccc3ccccc3c1n2-c1nccc(-c2cccc(-c3ccc(-c4ccccc4)cc3)c2)n1]

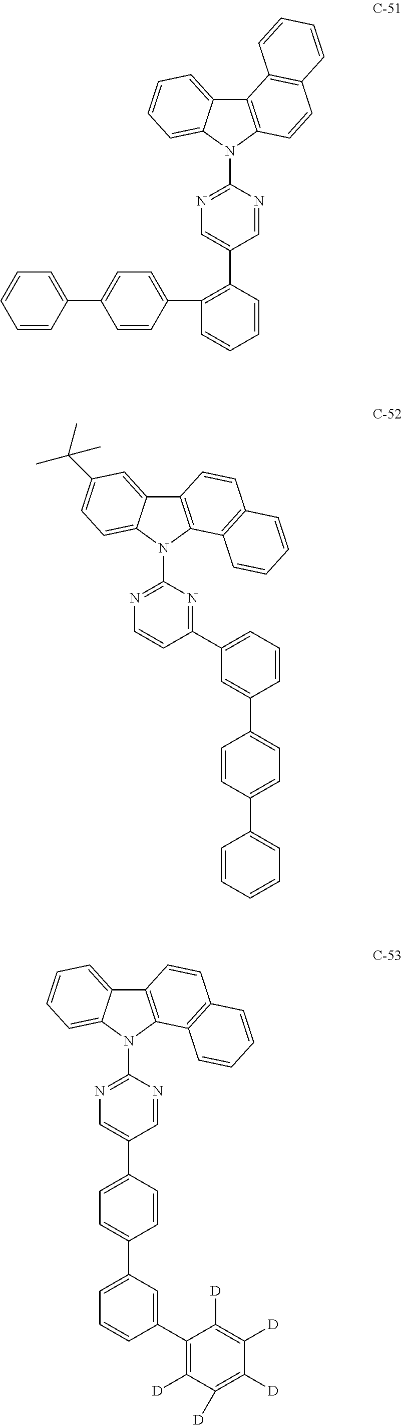 [SMILES: c1ccc(-c2ccc(-c3ccccc3-c3cnc(-n4c5ccccc5c5c6ccccc6ccc54)nc3)cc2)cc1 ; CC(C)(C)c1ccc2c(c1)c1ccc3ccccc3c1n2-c1nccc(-c2cccc(-c3ccc(-c4ccccc4)cc3)c2)n1 ; [2H]c1c([2H])c([2H])c(-c2cccc(-c3ccc(-c4cnc(-n5c6ccccc6c6ccc7ccccc7c65)nc4)cc3)c2)c([2H])c1[2H]]

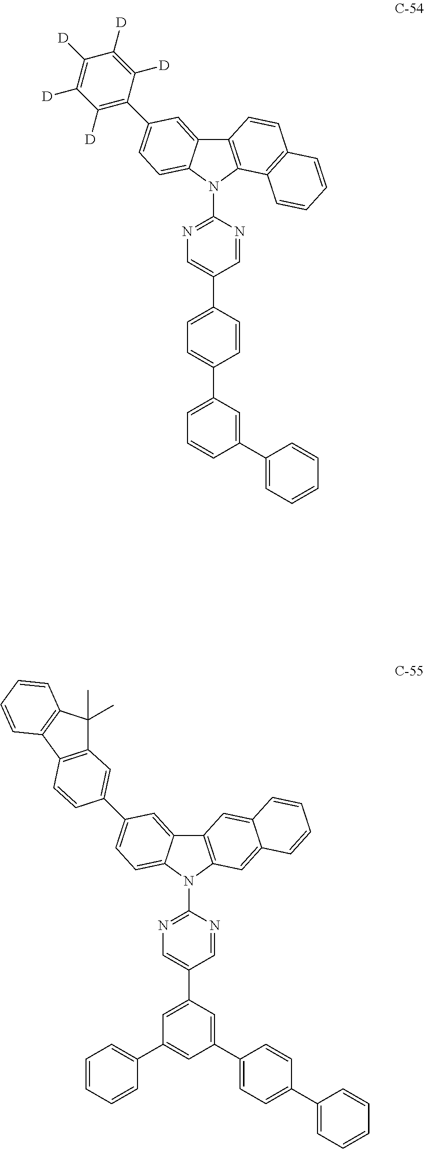 [SMILES: [2H]c1c([2H])c([2H])c(-c2ccc3c(c2)c2ccc4ccccc4c2n3-c2ncc(-c3ccc(-c4cccc(-c5ccccc5)c4)cc3)cn2)c([2H])c1[2H] ; CC1(C)c2ccccc2-c2ccc(-c3ccc4c(c3)c3cc5ccccc5cc3n4-c3ncc(-c4cc(-c5ccccc5)cc(-c5ccc(-c6ccccc6)cc5)c4)cn3)cc21]

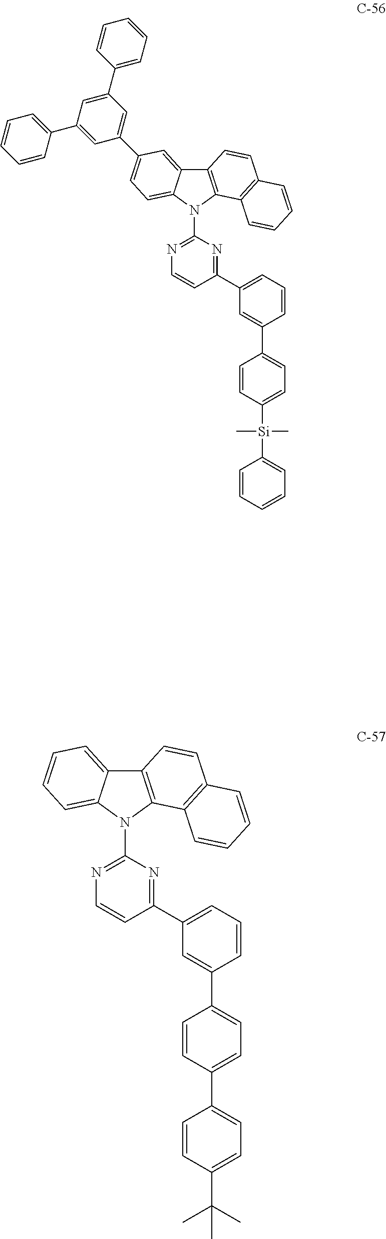 [SMILES: C[Si](C)(c1ccccc1)c1ccc(-c2cccc(-c3ccnc(-n4c5ccc(-c6cc(-c7ccccc7)cc(-c7ccccc7)c6)cc5c5ccc6ccccc6c54)n3)c2)cc1 ; CC(C)(C)c1ccc(-c2ccc(-c3cccc(-c4ccnc(-n5c6ccccc6c6ccc7ccccc7c65)n4)c3)cc2)cc1]

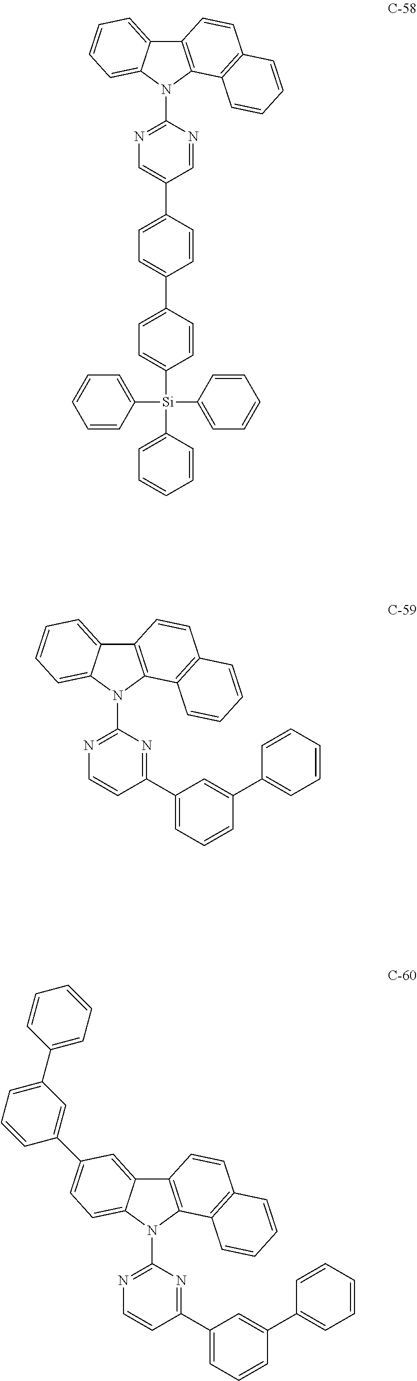 [SMILES: c1ccc([Si](c2ccccc2)(c2ccccc2)c2ccc(-c3ccc(-c4cnc(-n5c6ccccc6c6ccc7ccccc7c65)nc4)cc3)cc2)cc1 ; c1ccc(-c2cccc(-c3ccnc(-n4c5ccccc5c5ccc6ccccc6c54)n3)c2)cc1 ; c1ccc(-c2cccc(-c3ccc4c(c3)c3ccc5ccccc5c3n4-c3nccc(-c4cccc(-c5ccccc5)c4)n3)c2)cc1]

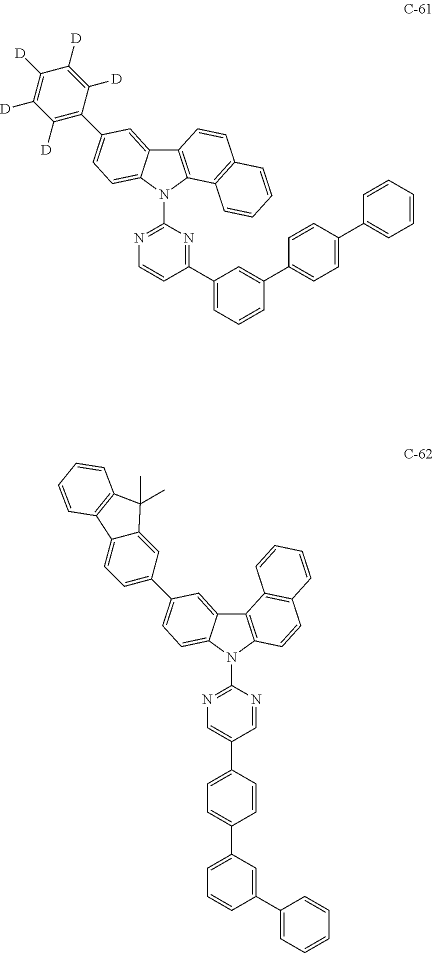 [SMILES: [2H]c1c([2H])c([2H])c(-c2ccc3c(c2)c2ccc4ccccc4c2n3-c2nccc(-c3cccc(-c4ccc(-c5ccccc5)cc4)c3)n2)c([2H])c1[2H] ; CC1(C)c2ccccc2-c2ccc(-c3ccc4c(c3)c3c5ccccc5ccc3n4-c3ncc(-c4ccc(-c5cccc(-c6ccccc6)c5)cc4)cn3)cc21]

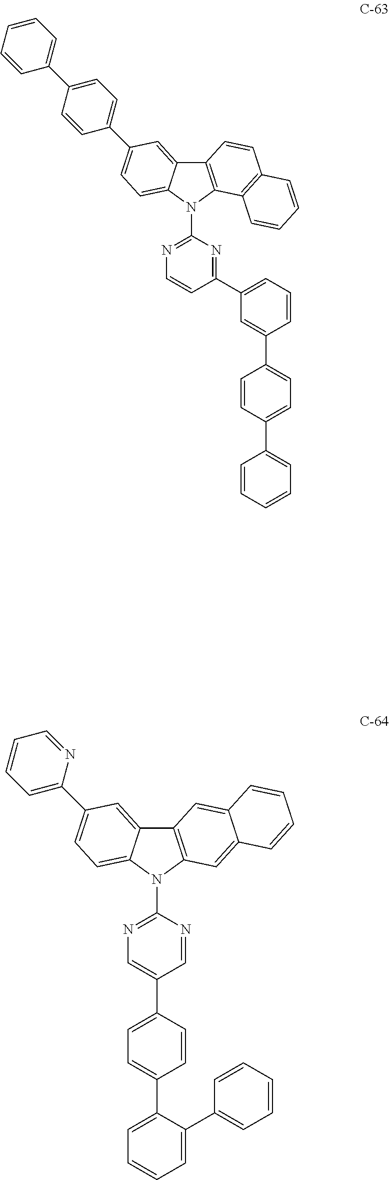 [SMILES: c1ccc(-c2ccc(-c3cccc(-c4ccnc(-n5c6ccc(-c7ccc(-c8ccccc8)cc7)cc6c6ccc7ccccc7c65)n4)c3)cc2)cc1 ; c1ccc(-c2ccccc2-c2ccc(-c3cnc(-n4c5ccc(-c6ccccn6)cc5c5cc6ccccc6cc54)nc3)cc2)cc1]

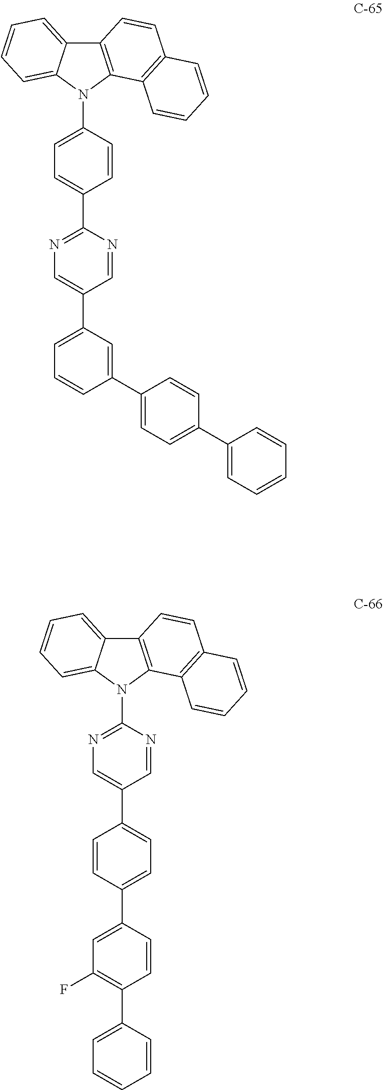 [SMILES: c1ccc(-c2ccc(-c3cccc(-c4cnc(-c5ccc(-n6c7ccccc7c7ccc8ccccc8c76)cc5)nc4)c3)cc2)cc1 ; Fc1cc(-c2ccc(-c3cnc(-n4c5ccccc5c5ccc6ccccc6c54)nc3)cc2)ccc1-c1ccccc1]

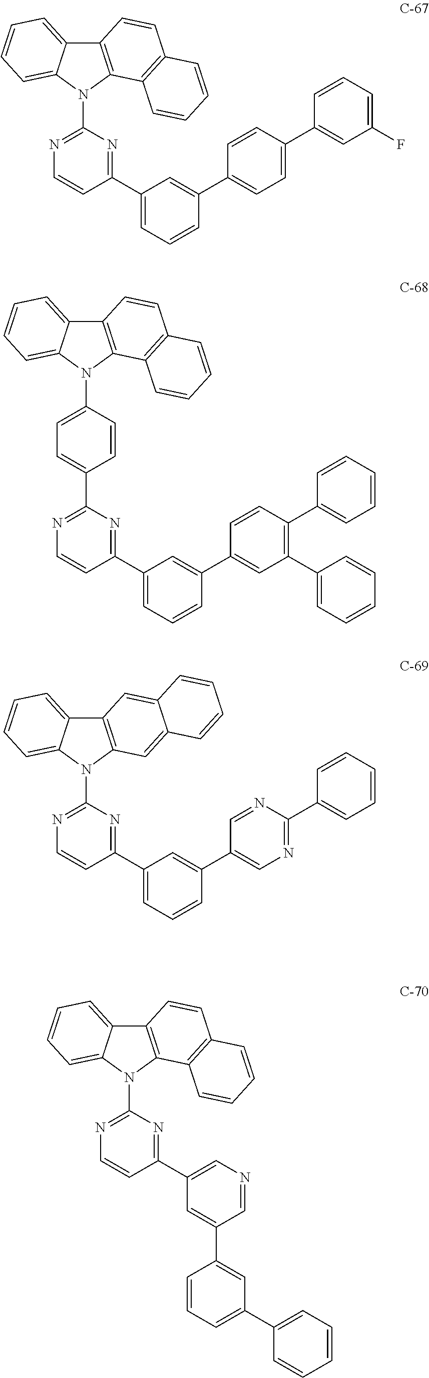 [SMILES: Fc1cccc(-c2ccc(-c3cccc(-c4ccnc(-n5c6ccccc6c6ccc7ccccc7c65)n4)c3)cc2)c1 ; c1ccc(-c2ccc(-c3cccc(-c4ccnc(-c5ccc(-n6c7ccccc7c7ccc8ccccc8c76)cc5)n4)c3)cc2-c2ccccc2)cc1 ; c1ccc(-c2ncc(-c3cccc(-c4ccnc(-n5c6ccccc6c6cc7ccccc7cc65)n4)c3)cn2)cc1 ; c1ccc(-c2cccc(-c3cncc(-c4ccnc(-n5c6ccccc6c6ccc7ccccc7c65)n4)c3)c2)cc1]

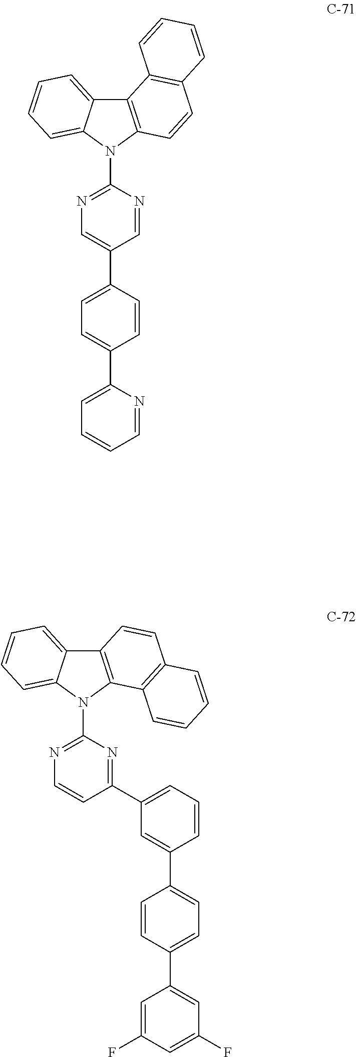 [SMILES: c1ccc(-c2ccc(-c3cnc(-n4c5ccccc5c5c6ccccc6ccc54)nc3)cc2)nc1 ; Fc1cc(F)cc(-c2ccc(-c3cccc(-c4ccnc(-n5c6ccccc6c6ccc7ccccc7c65)n4)c3)cc2)c1]

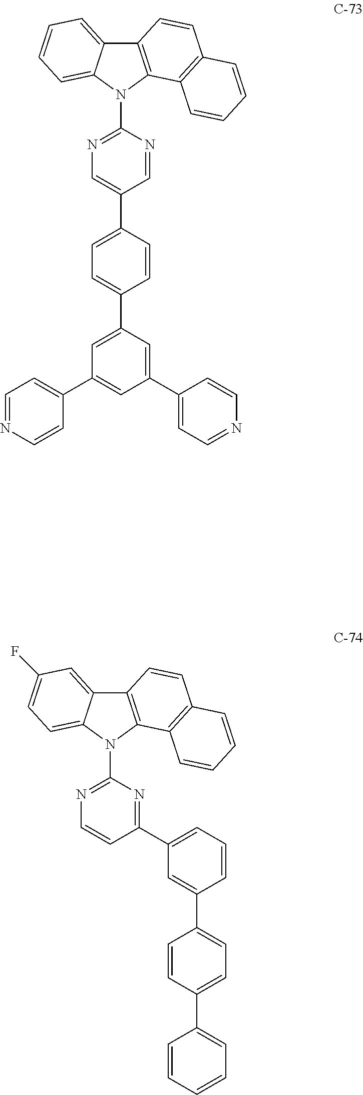 [SMILES: c1ccc2c(c1)ccc1c3ccccc3n(-c3ncc(-c4ccc(-c5cc(-c6ccncc6)cc(-c6ccncc6)c5)cc4)cn3)c21 ; Fc1ccc2c(c1)c1ccc3ccccc3c1n2-c1nccc(-c2cccc(-c3ccc(-c4ccccc4)cc3)c2)n1]

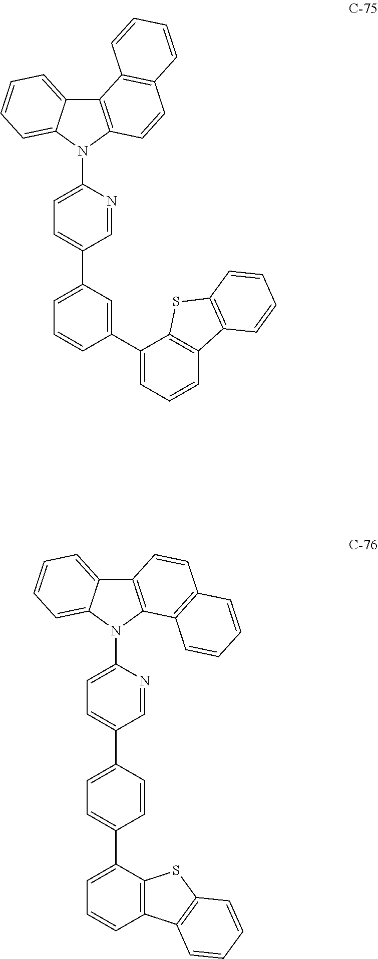 [SMILES: c1cc(-c2ccc(-n3c4ccccc4c4c5ccccc5ccc43)nc2)cc(-c2cccc3c2sc2ccccc23)c1 ; c1ccc2c(c1)ccc1c3ccccc3n(-c3ccc(-c4ccc(-c5cccc6c5sc5ccccc56)cc4)cn3)c21]

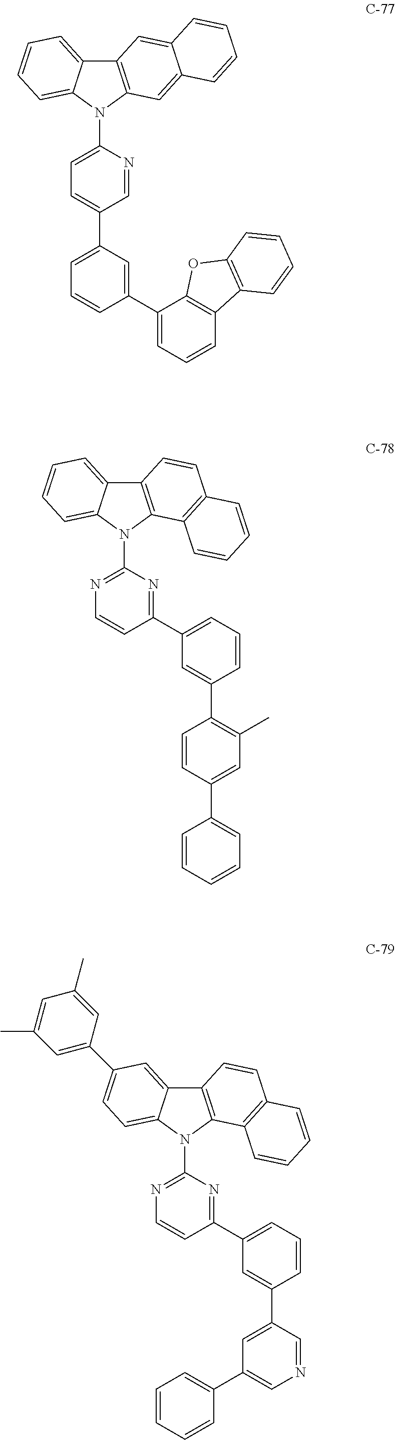

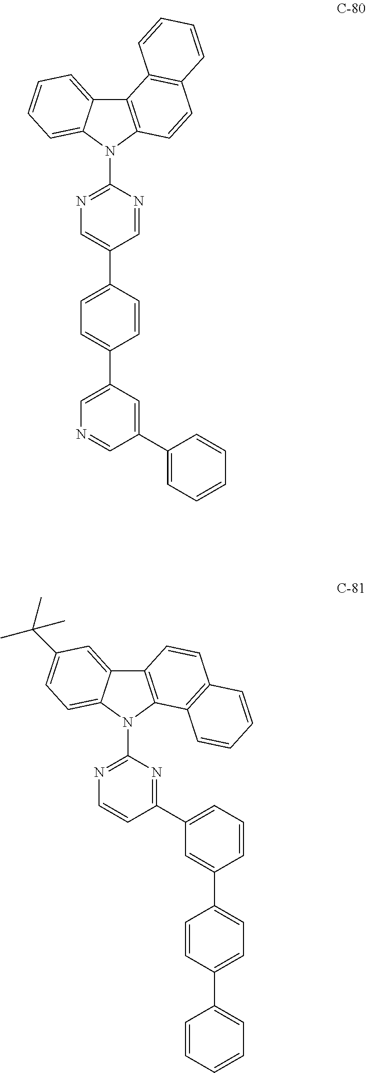 [SMILES: c1ccc(-c2cncc(-c3ccc(-c4cnc(-n5c6ccccc6c6c7ccccc7ccc65)nc4)cc3)c2)cc1 ; CC(C)(C)c1ccc2c(c1)c1ccc3ccccc3c1n2-c1nccc(-c2cccc(-c3ccc(-c4ccccc4)cc3)c2)n1]

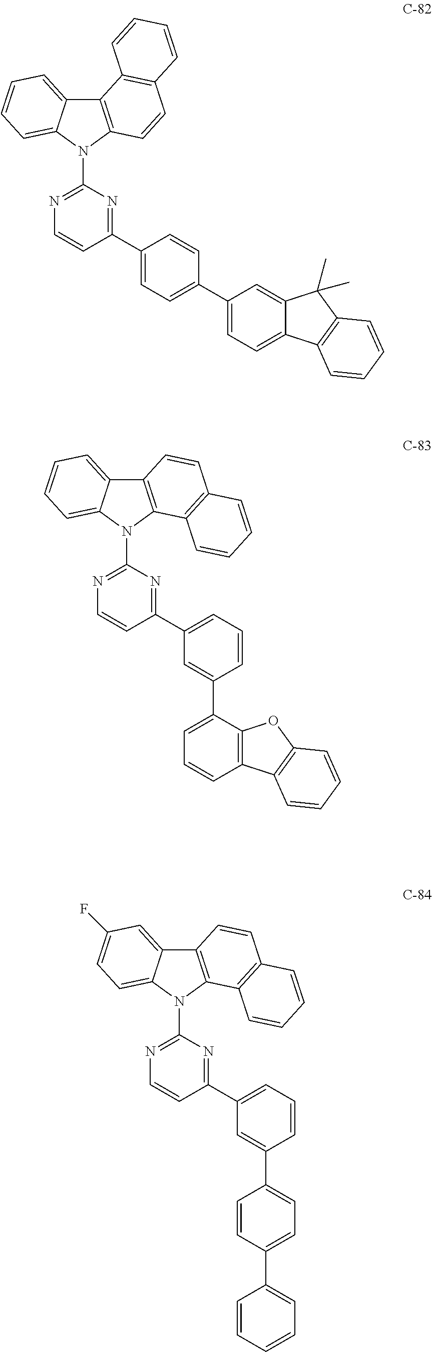 [SMILES: CC1(C)c2ccccc2-c2ccc(-c3ccc(-c4ccnc(-n5c6ccccc6c6c7ccccc7ccc65)n4)cc3)cc21 ; c1cc(-c2ccnc(-n3c4ccccc4c4ccc5ccccc5c43)n2)cc(-c2cccc3c2oc2ccccc23)c1 ; Fc1ccc2c(c1)c1ccc3ccccc3c1n2-c1nccc(-c2cccc(-c3ccc(-c4ccccc4)cc3)c2)n1]

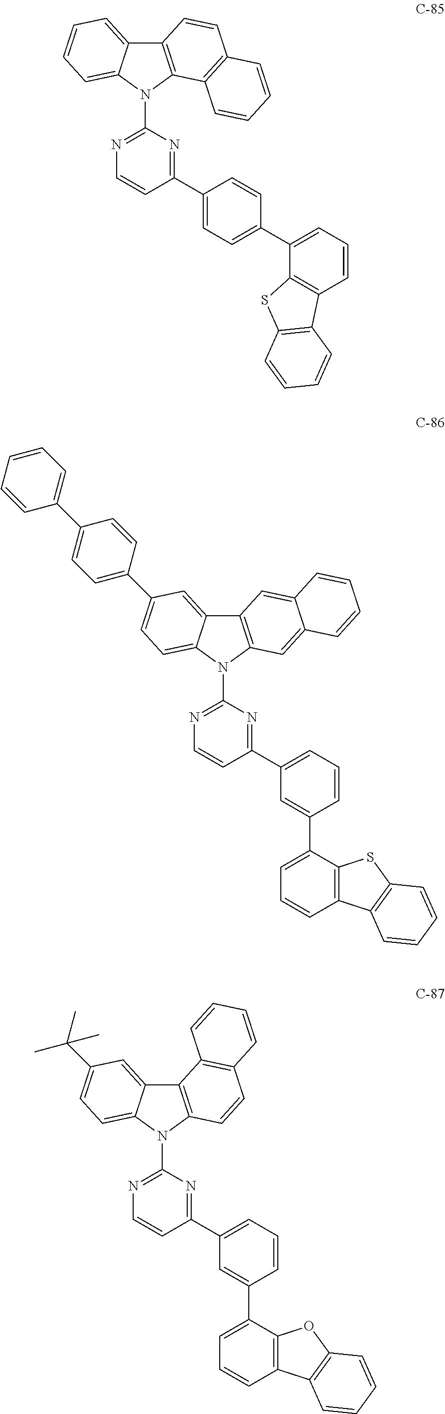 [SMILES: c1ccc2c(c1)ccc1c3ccccc3n(-c3nccc(-c4ccc(-c5cccc6c5sc5ccccc56)cc4)n3)c21 ; c1ccc(-c2ccc(-c3ccc4c(c3)c3cc5ccccc5cc3n4-c3nccc(-c4cccc(-c5cccc6c5sc5ccccc56)c4)n3)cc2)cc1 ; CC(C)(C)c1ccc2c(c1)c1c3ccccc3ccc1n2-c1nccc(-c2cccc(-c3cccc4c3oc3ccccc34)c2)n1]

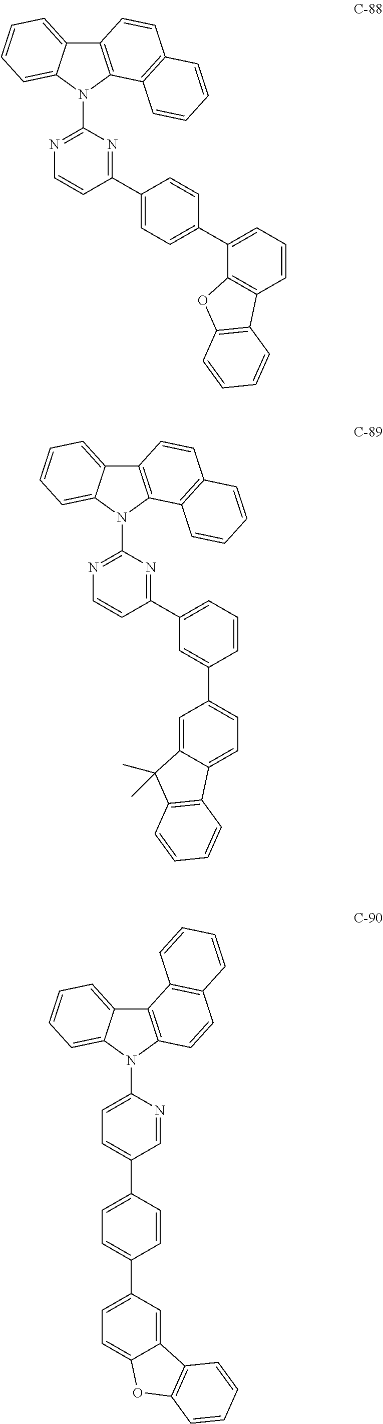 [SMILES: c1ccc2c(c1)ccc1c3ccccc3n(-c3nccc(-c4ccc(-c5cccc6c5oc5ccccc56)cc4)n3)c21 ; CC1(C)c2ccccc2-c2ccc(-c3cccc(-c4ccnc(-n5c6ccccc6c6ccc7ccccc7c65)n4)c3)cc21 ; c1ccc2c(c1)ccc1c2c2ccccc2n1-c1ccc(-c2ccc(-c3ccc4oc5ccccc5c4c3)cc2)cn1]

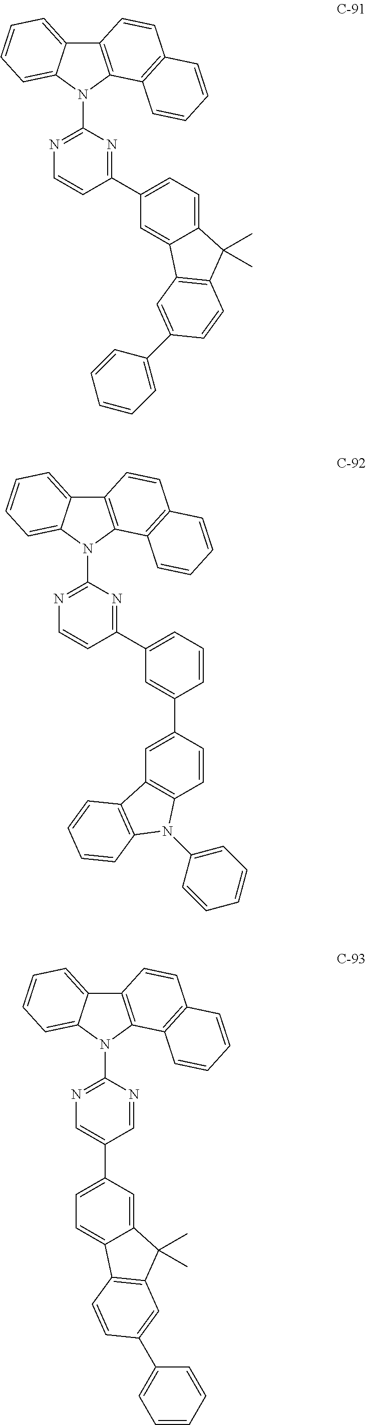 [SMILES: CC1(C)c2ccc(-c3ccccc3)cc2-c2cc(-c3ccnc(-n4c5ccccc5c5ccc6ccccc6c54)n3)ccc21 ; c1ccc(-n2c3ccccc3c3cc(-c4cccc(-c5ccnc(-n6c7ccccc7c7ccc8ccccc8c76)n5)c4)ccc32)cc1 ; CC1(C)c2cc(-c3ccccc3)ccc2-c2ccc(-c3cnc(-n4c5ccccc5c5ccc6ccccc6c54)nc3)cc21]

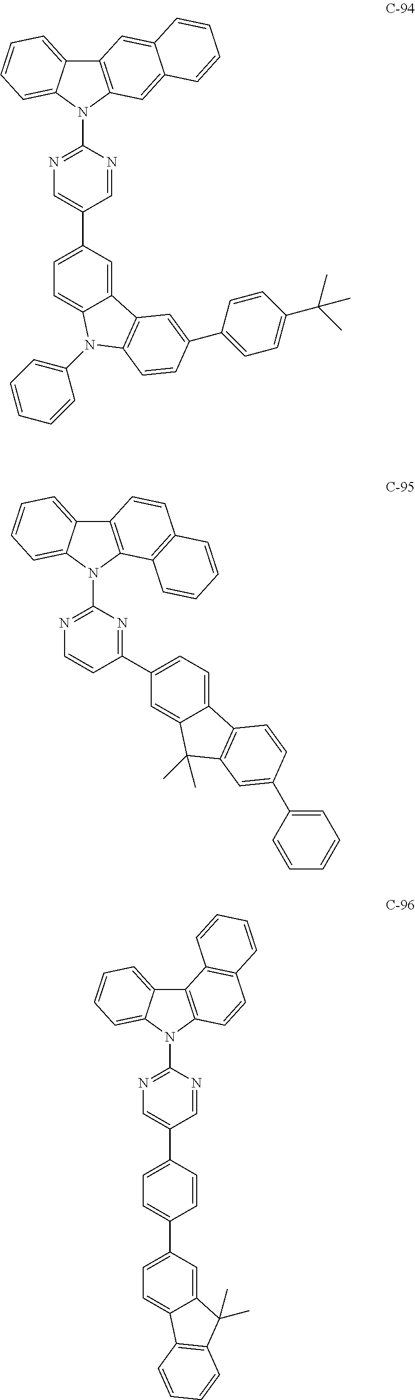 [SMILES: CC(C)(C)c1ccc(-c2ccc3c(c2)c2cc(-c4cnc(-n5c6ccccc6c6cc7ccccc7cc65)nc4)ccc2n3-c2ccccc2)cc1 ; CC1(C)c2cc(-c3ccccc3)ccc2-c2ccc(-c3ccnc(-n4c5ccccc5c5ccc6ccccc6c54)n3)cc21 ; CC1(C)c2ccccc2-c2ccc(-c3ccc(-c4cnc(-n5c6ccccc6c6c7ccccc7ccc65)nc4)cc3)cc21]

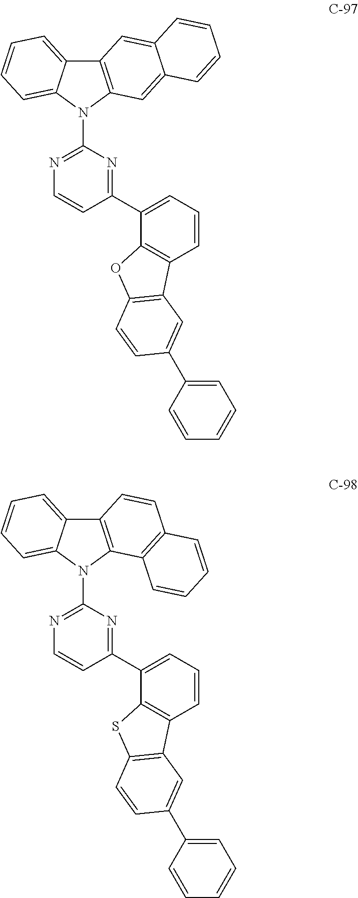 [SMILES: c1ccc(-c2ccc3oc4c(-c5ccnc(-n6c7ccccc7c7cc8ccccc8cc76)n5)cccc4c3c2)cc1 ; c1ccc(-c2ccc3sc4c(-c5ccnc(-n6c7ccccc7c7ccc8ccccc8c76)n5)cccc4c3c2)cc1]

7. An organic electroluminescence device comprising the organic electroluminescence compound according to claim 1.
